(19) United States
(12) Patent Application Publication
(10) Pub. No.: US 2023/0017832 A1
(43) Pub. Date: Jan. 19, 2023

(54) TREATMENT LIQUID AND TREATMENT LIQUID CONTAINER

(71) Applicant: FUJIFILM Corporation, Tokyo (JP)

(72) Inventor: Nobuaki SUGIMURA, Haibara-gun (JP)

(73) Assignee: FUJIFILM Corporation, Tokyo (JP)

(21) Appl. No.: 17/899,862

(22) Filed: Aug. 31, 2022

Related U.S. Application Data
(63) Continuation of application No. PCT/JP2021/003521, filed on Feb. 1, 2021.

(30) Foreign Application Priority Data
Mar. 4, 2020 (JP) 2020-036719

(51) Int. Cl. C09K 13/10

(52) U.S. Cl. CPC C09K 13/10

(57) ABSTRACT

The present invention provides a treatment liquid that allows a treated portion to have excellent smoothness in a case where SiGe is etched with the treatment liquid. The present invention also provides a treatment liquid container relating to the treatment liquid.

The treatment liquid according to an embodiment of the present invention contains a fluoride ion source, an oxidant, and an additive, in which the additive is one or more kinds of substances selected from the group consisting of predetermined compounds.

### CROSS-REFERENCE TO RELATED APPLICATIONS

This application is a Continuation of PCT International Application No. PCT/JP2021/003521 filed on Feb. 1, 2021, which claims priority under 35 U.S.C. § 119(a) to Japanese Patent Application No. 2020-036719 filed on Mar. 4, 2020. The above application is hereby expressly incorporated by reference, in its entirety, into the present application.

### BACKGROUND OF THE INVENTION

### 1. Field of the Invention

The present invention relates to a treatment liquid and a treatment liquid container.

### 2. Description of the Related Art

With the progress of miniaturization of semiconductor devices, the treatment in the semiconductor device manufacturing process, such as etching or washing using treatment liquids, is increasingly required to be more accurately performed with high efficiency.

For example, JP2019-50365A discloses “an etchant that contains water, an oxidant, a water-miscible organic solvent, a fluoride ion source, and a surfactant as an optional component and is suited for selectively removing silicon-germanium over silicon from a microelectronic device (claim 1)”.

### SUMMARY OF THE INVENTION

As a result of evaluating the treatment liquid (etchant) described in JP2019-50365A, the inventors of the present invention have found that there is room for improving the surface smoothness of silicon-germanium (SiGe) obtained after an etching treatment is performed on SiGe by using the treatment liquid.

The present invention has been accomplished in consideration of the above circumstances, and an object thereof is to provide a treatment liquid that allows a treated portion to have excellent smoothness in a case where SiGe is etched with the treatment liquid.

Another object of the present invention is to provide a treatment liquid container relating to the treatment liquid.

In order to achieve the above objects, the inventors of the present invention conducted intensive studies. As a result, the inventors have found that the objects can be achieved by the following constitutions.

[1]

A treatment liquid containing a fluoride ion source,

an oxidant, and

an additive,

in which the additive is one or more kinds of substances selected from the group consisting of polyvinyl alcohol, polystyrene sulfonic acid and a salt thereof, a nitrogen atom-containing polymer other than polyethyleneimine, cetyltrimethylammonium chloride, stearyltrimethylammonium bromide, polyoxyethylene lauryl amine, alkyl naphthalenesulfonic acid and a salt thereof, alkyl diphenyl ether disulfonic acid and a salt thereof, a phenolsulfonic acid formaldehyde condensate and a salt thereof, an aryl phenolsulfonic acid formaldehyde condensate and a salt thereof, polyoxyethylene alkyl ether sulfonic acid and a salt thereof, polyoxyethylene alkyl ether carboxylic acid and a salt thereof, polyoxyethylene alkyl ether phosphoric acid and a salt thereof, polyoxyethylene alkyl phenyl ether phosphoric acid and a salt thereof, lauryl dimethylaminoacetic acid betaine, lauryldimethylamine oxide, a silicon compound, alkylamine, aromatic amine, a nitrogen-containing heterocyclic compound, an amino acid other than cysteine, a quaternary ammonium salt having 16 or less carbon atoms, and a boron-containing compound.

[2]

The treatment liquid described in [1], in which the additive contains the nitrogen atom-containing polymer other than polyethyleneimine, and

the nitrogen atom-containing polymer other than polyethyleneimine is one or more kinds of polymers selected from the group consisting of polyvinylpyrrolidone, polyallylamine, polyvinylamine, polyacrylamide, a dimethylamineepihalohydrin-based polymer, a hexadimethrine salt, polydiallylamine, a polydimethyldiallylammonium salt, poly(4-vinylpyridine), polyornithine, polylysine, polyarginine, polyhistidine, polyvinylimidazole, and polymethyldiallylamine.

[3]

The treatment liquid described in [1] or [2], in which the additive contains at least any of the alkyl naphthalenesulfonic acid and a salt thereof, and

the alkyl naphthalenesulfonic acid is one or more kinds of compounds selected from the group consisting of propyl naphthalenesulfonic acid, triisopropyl naphthalenesulfonic acid, and dibutyl naphthalenesulfonic acid.

[4]

The treatment liquid described in any one of [1] to [3], in which the additive contains at least any of the alkyl diphenyl ether disulfonic acid and a salt thereof, and

the alkyl diphenyl ether disulfonic acid is dodecyl diphenyl ether disulfonic acid.

[5]

The treatment liquid described in any one of [1] to [4], in which the additive contains at least any of the polyoxyethylene alkyl ether sulfonic acid and a salt thereof, and

the polyoxyethylene alkyl ether sulfonic acid is one or more kinds of compounds selected from the group consisting of polyoxyethylene lauryl ether sulfonic acid, polyoxyethylene oleyl ether sulfonic acid, and polyoxyethylene octyldodecyl ether sulfonic acid.

[6]

The treatment liquid described in any one of [1] to [5], in which the additive contains at least any of the polyoxyethylene alkyl ether carboxylic acid and a salt thereof, and

the polyoxyethylene alkyl ether carboxylic acid is one or more kinds of compounds selected from the group consisting of polyoxyethylene lauryl ether carboxylic acid, polyoxyethylene dodecyl ether carboxylic acid, and polyoxyethylene tridecyl ether carboxylic acid.

[7]

The treatment liquid described in any one of [1] to [6], in which the additive contains at least any of the polyoxyethylene alkyl ether phosphoric acid and a salt thereof, and

the polyoxyethylene alkyl ether phosphoric acid is polyoxyethylene lauryl ether phosphoric acid.

[8]

The treatment liquid described in any one of [1] to [7], in which the additive contains the silicon compound, and

the silicon compound is one or more kinds of compounds selected from the group consisting of alkoxysilane, a silanol compound, oxime silane, disilazane, and siloxane.

[9]

The treatment liquid described in [8], in which the alkoxysilane is one or more kinds of compounds selected from the group consisting of tetraethoxysilane, methyltrimethoxysilane, dimethyldimethoxysilane, phenyltrimethoxysilane, methyltriethoxysilane, dimethyldiethoxysilane, phenyltriethoxysilane, n-propyltrimethoxysilane, n-propyltriethoxysilane, hexyltrimethoxysilane, hexyltriethoxysilane, octyltriethoxysilane, 1,6-bis(trimethoxysilyl)hexane, trifluoropropyltrimethoxysilane, t-butylmethoxydimethylsilane, 3-aminopropyldimethylmethoxysilane, ethoxy(trimethyl)silane, methoxy(trimethyl)silane, hexyl(dimethoxy)silane, methyldiethoxysilane, triethoxysilane, 3-aminopropyldimethylethoxysilane, and 3-(2-aminoethoxyamino)propyltrimethoxysilane.

[10]

The treatment liquid described in [8] or [9], in which the silanol compound is one or more kinds of compounds selected from the group consisting of trimethylsilanol, dimethylsilanediol, diphenylsilanediol, silanetriol, 3-aminopropylsilanetriol, methylsilanetriol, 2-methyl-2-propylsilanetriol, methyl acetate silanetriol, 2-(chloroethyl)acetate silanetriol, and 3-(hydroxypropyl)silanetriol.

[11]

The treatment liquid described in any one of [8] to [10], in which the oxime silane is one or more kinds of compounds selected from the group consisting of di(ethylaldoxime)silane, mono(ethylaldoxime)silane, tris(ethylaldoxime)silane, tetra(ethylaldoxime)silane, methyltris(methylethylketoxime)silane, methyltosyl(acetoxime)silane, methyltris(methylisobutylketoxime)silane, dimethyldi(methylethylketoxime)silane, trimethyl(methylethylketoxime)silane, tetra(methylethylketoxime)silane, tetra(methylisobutylketoxime)silane, vinyltris(methylethylketoxime)silane, methylvinyldi(methylethylketoxime)silane, methylvinyldi(cyclohexanonexime)silane, vinyltris(methylisobutylketoxime)silane, and phenyltris(methylethylketoxime)silane.

[12]

The treatment liquid described in any one of [8] to [11], in which the disilazane is hexamethyldisilazane.

[13]

The treatment liquid described in any of [8] to [12], in which the siloxane is one or more kinds of compounds selected from the group consisting of hexamethyldisiloxane, octamethylcyclotetrasiloxane, decamethylcyclopentasiloxane, and dodecamethylcyclohexasiloxane.

[14]

The treatment liquid described in any one of [1] to [13], in which the additive contains the alkylamine, and

the alkylamine is one or more kinds of compounds selected from the group consisting of ethylenediamine, diethylenetriamine, triethylenetetramine, tetraethylenepentamine, pentaethylenehexamine, tetramethylethylenediamine, hexamethylenediamine, methylamine, dimethylamine, trimethylamine, ethylamine, diethylamine, triethylamine, 2-ethylhexylamine, stearylamine, cyclohexylamine, phenethylamine, and m-xylylenediamine.

[15]

The treatment liquid described in any one of [1] to [14], in which the additive contains the aromatic amine, and

the aromatic amine is one or more kinds of compounds selected from the group consisting of aniline and toluidine.

[16]

The treatment liquid described in any one of [1] to [15], in which the additive contains the nitrogen-containing heterocyclic compound, and

the nitrogen-containing heterocyclic compound is one or more kinds of compounds selected from the group consisting of pyrrolidine, piperidine, piperazine, morpholine, pyrrole, pyrazole, imidazole, pyridine, pyrimidine, pyrazine, oxazole, thiazole, 4-dimethylaminopyridine, and laurylpyridinium chloride.

[17]

The treatment liquid described in any one of [1] to [16], in which the additive contains the amino acid other than cysteine, and

the amino acid other than cysteine is one or more kinds of amino acids selected from the group consisting of alanine, arginine, aspartic acid, aspartic acid, glutamine, glutamic acid, glycine, histidine, isoleucine, leucine, lysine, methionine, phenylalanine, proline, serine, threonine, tryptophan, tyrosine, and valine.

[18]

The treatment liquid described in any one of [1] to [17], in which the additive contains the quaternary ammonium salt having 16 or less carbon atoms, and

the quaternary ammonium salt having 16 or less carbon atoms is one or more kinds of compounds selected from the group consisting of a tetramethylammonium salt, a tetraethylammonium salt, a tetrapropylammonium salt, a tetrabutylammonium salt, a methyltripropylammonium salt, a methyltributylammonium salt, an ethyltrimethylammonium salt, a dimethyldiethylammonium salt, a benzyltrimethylammonium salt, and a (2-hydroxyethyl)trimethylammonium salt.

[19]

The treatment liquid described in any one of [1] to [18], in which the additive contains the boron-containing compound, and

the boron-containing compound is boric acid.

[20]

The treatment liquid described in [1], in which the additive is one or more kinds of substances selected from the group consisting of alkyl diphenyl ether disulfonic acid and a phenolsulfonic acid formaldehyde condensate.

[21]

The treatment liquid described in any one of [1] to [20], further containing an organic solvent.

[22]

The treatment liquid described in [21], in which organic solvent is one or more kinds of compounds selected from the group consisting of ethylene glycol, propylene glycol, butyl diglycol, 1,4-butanediol, tripropylene glycol methyl ether, propylene glycol propyl ether, diethylene glycol n-butyl ether, hexyloxypropylamine, poly(oxyethylene)diamine, dimethyl sulfoxide, tetrahydrofurfuryl alcohol, glycerol, sulfolane, ethylene glycol monomethyl ether, ethylene glycol monoethyl ether, ethylene glycol monobutyl ether, ethylene glycol dimethyl ether, ethylene glycol diethyl ether, diethylene glycol monomethyl ether, diethylene glycol monoethyl ether, diethylene glycol monopropyl ether, diethylene glycol monoisopropyl ether, diethylene glycol monoisobutyl ether, diethylene glycol monobenzyl ether, diethylene glycol dimethyl ether, diethylene glycol diethyl ether, triethylene glycol monomethyl ether, triethylene glycol dimethyl ether, polyethylene glycol monomethyl ether, diethylene glycol methyl ethyl ether, propylene glycol monomethyl ether, propylene glycol dimethyl ether, propylene glycol monobutyl ether, monopropyl ether, dipropylene glycol monomethyl ether, dipropylene glycol monoisopropyl ether, dipropylene glycol monobutyl ether, dipropylene glycol diisopropyl ether, 1-methoxy-2-butanol, 2-methoxy-1-butanol, 2-methoxy-2-methylbutanol, 1,1-dimethoxyethane, 2-(2-butoxyethoxy)ethanol, methanol, ethanol, isopropanol, and 1-butanol.

[23]

The treatment liquid described in [21] or [22], in which the organic solvent is one or more kinds of compounds selected from the group consisting of propylene glycol and sulfolane.

[24]

The treatment liquid described in any one of [1] to [23], in which the oxidant is a peroxide.

[25]

The treatment liquid described in any one of [1] to [24], in which a content of the oxidant is less than 10% by mass with respect to a total mass of the treatment liquid.

[26]

The treatment liquid described in any one of [1] to [25], in which the treatment liquid is used for an object to be treated containing SiGe to remove at least a part of SiGe contained in the object to be treated.

[27]

The treatment liquid described in any one of [1] to [26], in which the treatment liquid is used for an object to be treated containing SiGe to remove at least a part of SiGe contained in the object to be treated, and

an element ratio of Si:Ge in the SiGe is in a range of 95:5 to 50:50.

[28]

The treatment liquid described in any one of [1] to [27], in which the treatment liquid is used for an object to be treated containing a metal hard mask containing one or more kinds of substances among Cu, Co, W, AlOₓ, AlN, AlOₓN_{y}, WOₓ, Ti, TiN, ZrOₓ, HfOₓ, and TaOₓ, where x represents a number of 1 to 3 and y represents a number of 1 or 2.

[29]

A treatment liquid container having a container and the treatment liquid described in any one of [1] to [28] stored in the container,

in which the container has a degassing mechanism that adjusts internal pressure of the container.

According to the present invention, it is possible to provide a treatment liquid that allows a treated portion to have excellent smoothness in a case where SiGe is etched with the treatment liquid.

Furthermore, the present invention can also provide a treatment liquid container relating to the treatment liquid.

### BRIEF DESCRIPTION OF THE DRAWINGS

FIG. 1 is a schematic cross-sectional view of the upper portion of a treatment liquid container to which a degassing cap is applied.

FIG. 2 is a cross-sectional view showing an embodiment of an object to be treated.

FIG. 3 is an example of a cross-sectional view showing an object to be treated having been treated by the present treatment method.

### DESCRIPTION OF THE PREFERRED EMBODIMENTS

Hereinafter, the present invention will be specifically described.

The following configuration requirements will be described based on typical embodiments of the present invention in some cases, but the present invention is not limited to the embodiments.

In the present specification, the range of numerical values described using “to” means a range including the numerical values listed before and after “to” as the lower limit and the upper limit.

Furthermore, in the present invention, “ppm” means “parts-per-million (10⁻⁶)”, “ppb” means “parts-per-billion (10⁻⁹)”, and “ppt” means “parts-per-trillion (10⁻¹²)”.

In the present specification, “room temperature” is “25° C.”.

In the present specification, the pH of the treatment liquid is a value measured at room temperature (25° C.) by using F-51 (trade name) manufactured by HORIBA, Ltd.

In the present specification, in a case where there is a molecular weight distribution, unless otherwise specified, a molecular weight means a weight-average molecular weight.

In the present specification, the weight-average molecular weight of a resin (polymer) is a polystyrene-equivalent weight-average molecular weight determined by gel permeation chromatography (GPC).

The components of the treatment liquid mentioned in the present specification may be in a state of being ionized in the treatment liquid.

In the present specification, in a case where the term “salt” is mentioned, examples of a salt of a compound containing a cationic nitrogen atom (N⁺) or the like include a halide salt, such as fluoride, chloride, bromide, or iodide, of the compound, a hydroxide of the compound; a nitrate of the compound; a sulfate of the compound, and the like. These salts may form salts with two or more kinds of anions. Here, in a case where the salt is an additive, it is also preferable that the aforementioned salt be other than a fluoride.

Examples of a salt of a compound containing a sulfonic acid group, a phosphoric acid group, a carboxylic acid group, and the like include an alkali metal salt, such as a lithium salt, a sodium salt, or a potassium salt, of the compound; an alkaline earth metal salt, such as a calcium salt, of the compound; an ammonium salt of the compound, and the like. These salts may form salts with two or more kinds of cations.

In a polymer, only some of the groups capable of forming a salt may form a salt, or all of such groups may form a salt.

[Treatment Liquid]

The treatment liquid according to an embodiment of the present invention contains a fluoride ion source, an oxidant, and an additive.

The additive is one or more kinds of substances selected from the group consisting of polyvinyl alcohol, polystyrene sulfonic acid and a salt thereof, a nitrogen atom-containing polymer other than polyethyleneimine, cetyltrimethylammonium chloride, stearyltrimethylammonium bromide, polyoxyethylene lauryl amine, alkyl naphthalenesulfonic acid and a salt thereof, alkyl diphenyl ether disulfonic acid and a salt thereof, a phenolsulfonic acid formaldehyde condensate and a salt thereof, an awl phenolsulfonic acid formaldehyde condensate and a salt thereof, polyoxyethylene alkyl ether sulfonic acid, polyoxyethylene alkyl ether carboxylic acid, polyoxyethylene alkyl phosphoric acid, polyoxyethylene alkyl phenyl ether phosphoric acid, lauryl dimethylaminoacetic acid betaine, lauryldimethylamine oxide, a silicon compound, alkylamine, aromatic amine, a nitrogen-containing heterocyclic compound, an amino acid other than cysteine, a quaternary ammonium salt having 16 or less carbon atoms, and a boron-containing compound. Hereinafter, one or more kinds of additives selected from the above group will be also called “specific additive”.

The inventors of the present invention selected, as the specific additive, components showing properties effective for improving the smoothness of a treated portion. The inventors consider that incorporating the specific additive into the treatment liquid made it possible to achieve the objects of the present invention.

In addition, the treatment liquid according to the embodiment of the present invention exhibits excellent selectivity in dissolving SiGe. For example, the treatment liquid according to the embodiment of the present invention exhibits an excellent dissolving ability to SiGe while exhibiting excellent anticorrosion properties to silicon (Si).

Hereinafter, regarding the treatment liquid according to the embodiment of the present invention, the properties of allowing a treated portion to have excellent smoothness in a case where SiGe is etched with the treatment liquid, the properties of exhibiting excellent dissolving ability to SiGe, and/or the properties of exhibiting excellent anticorrosion properties to Si will be also described as “the effect of the present invention is excellent”.

Hereinafter, the components contained in the treatment liquid according to the embodiment of the present invention will be specifically described.

<Fluoride Ion Source>

The treatment liquid contains a fluoride ion source.

The fluoride ion source is a component that releases fluoride ions (ions containing fluorine atoms, such as F⁻ and/or HF₂⁻) in the treatment liquid.

Fluoride ions are considered to be able to assist in the removal of oxides of silicon and/or germanium formed under the action of an oxidant that will be described later.

Examples of the fluoride ion source include hydrofluoric acid (HF), ammonium fluoride (NH₄F), fluoroborate (such as KBF₄ or NH₄BF₄), fluoroboric acid, tetrabutylammonium tetrafluoroborate, aluminum hexafluoride, sodium fluoride, potassium fluoride, AlF₂, LiF₄, CaF₃, NaHF₆, NH₄HF₂, KHF₂, H₂SiF₆, and a compound represented by R¹NR²R³R⁴F.

In the R¹NR²R³R⁴F, R¹, R², R³, and R⁴ each independently represent a hydrogen atom or an alkyl group having 1 to 4 carbon atoms. The total number of carbon atoms contained in R¹, R², R³, and R⁴ is preferably 1 to 12. Examples of the compound represented by R¹NR²R³R⁴F include tetramethylammonium fluoride, tetraethylammonium fluoride, methyltriethylammonium fluoride, and tetrabutylammonium fluoride.

The fluoride ion source is preferably hydrofluoric acid or ammonium fluoride.

The content of the fluoride ion source is not particularly limited. In view of further improving the effect of the present invention, the content of the fluoride ion source with respect to the total mass of the treatment liquid is preferably 0.001% to 10% by mass, more preferably 0.01% to 5% by mass, and even more preferably 0.1% to 3% by mass.

One kind of fluoride ion source may be used alone, or two or more kinds of fluoride ion sources may be used. In a case where two or more kinds of fluoride ion sources are used, the total amount thereof is preferably within the above range.

<Oxidant>

The treatment liquid contains an oxidant.

The oxidant is considered to function to etch SiGe by acting on SiGe and forming an oxide (such as silicon oxide, germanium oxide, and/or silicon-germanium composite oxide).

Examples of the oxidant include a peroxide, a persulfide (for example, a monopersulfide or a dipersulfide), a percarbonate, salts of these, and acids of these.

Among these, a peroxide (compound containing one or more peroxy groups (—O—O—)) is preferable as the oxidant. The peroxide may be a peroxy acid (such as peracetic acid, perbenzoic acid, or salts of these).

Examples of other suitable oxidants include an oxidative halide (such as iodic acid, periodic acid, or salts of these), perboric acid, perborate, permanganate, a cerium compound, and a ferricyanide (such as potassium ferricyanide).

More specific examples of the oxidant include peracetic acid, hydrogen peroxide, periodic acid, potassium iodate, potassium permanganate, ammonium persulfate, ammonium molybdate, ferric nitrate, nitric acid, potassium nitrate, and a urea-hydrogen peroxide adduct.

Among these, peracetic acid or hydrogen peroxide is preferable as the oxidant.

The content of the oxidant is not particularly limited. In view of further improving the effect of the present invention, the content of the oxidant with respect to the total mass of the treatment liquid is preferably 0.5% by mass or more, more preferably 1% by mass or more, and even more preferably 5% by mass or more. The upper limit of the content of the oxidant with respect to the total mass of the treatment liquid is preferably 30% by mass or less, more preferably 20% by mass or less, even more preferably 15% by mass or less, and particularly preferably less than 10% by mass.

One kind of oxidant may be used alone, or two or more kinds of oxidants may be used. In a case where two or more kinds of oxidants are used, the total amount thereof is preferably within the above range.

<Specific Additive (Additive)>

The treatment liquid contains one or more kinds of specific additives.

The specific additive is a component selected from the group consisting of polyvinyl alcohol, polystyrene sulfonic acid and a salt thereof, a nitrogen atom-containing polymer other than polyethyleneimine, cetyltrimethylammonium chloride, stearyltrimethylammonium bromide, polyoxyethylene lauryl amine, alkyl naphthalenesulfonic acid and a salt thereof, alkyl diphenyl ether disulfonic acid and a salt thereof, a phenolsulfonic acid formaldehyde condensate and a salt thereof, an aryl phenolsulfonic acid formaldehyde condensate and a salt thereof, polyoxyethylene alkyl ether sulfonic acid, polyoxyethylene alkyl ether carboxylic acid, polyoxyethylene alkyl phosphoric acid, polyoxyethylene alkyl phenyl ether phosphoric acid, lauryl dimethylaminoacetic acid betaine, lauryldimethylamine oxide, a silicon compound, alkylamine, aromatic amine, a nitrogen-containing heterocyclic compound, an amino acid other than cysteine, a quaternary ammonium salt having 16 or less carbon atoms, and a boron-containing compound.

The fluoride ion source and oxidant described above are not included in the specific additive.

Particularly, the specific additive is preferably one or more kinds of substances selected from the group consisting of polyvinyl alcohol, polystyrene sulfonic acid and a salt thereof, a nitrogen atom-containing polymer other than polyethyleneimine, cetyltrimethylammonium chloride, stearyltrimethylammonium bromide, polyoxyethylene lauryl amine, alkyl naphthalenesulfonic acid and a salt thereof; alkyl diphenyl ether disulfonic acid and a salt thereof, a phenolsulfonic acid formaldehyde condensate and a salt thereof, an aryl phenolsulfonic acid formaldehyde condensate and a salt thereof, polyoxyethylene alkyl ether sulfonic acid and a salt thereof, polyoxyethylene alkyl ether carboxylic acid and a salt thereof, polyoxyethylene alkyl ether phosphoric acid and a salt thereof, polyoxyethylene alkyl phenyl ether phosphoric acid and a salt thereof, alkylamine, aromatic amine, a nitrogen-containing heterocyclic compound, an amino acid other than cysteine, a quaternary ammonium salt having 16 or less carbon atoms, and a boron-containing compound, and more preferably one or more kinds of substances selected from the group consisting of alkyl diphenyl ether disulfonic acid and a phenolsulfonic acid formaldehyde condensate.

The content of the specific additive is not particularly limited. In view of further improving the effect of the present invention, the content of the specific additive with respect to the total mass of the treatment liquid is preferably 0.001% to 10% by mass, more preferably 0.01% to 5% by mass, and even more preferably 0.1% to 3% by mass.

One kind of specific additive may be used alone, or two or more kinds of specific additives may be used. In a case where two or more kinds of specific additives are used, the total amount thereof is preferably within the above range.

Hereinafter, each specific additive will be described.

(Polyvinyl Alcohol)

The polyvinyl alcohol is a polymer containing a repeating unit represented by —CH₂—CH(OH)—.

In a case where the polyvinyl alcohol also contains repeating units other than —CH₂—CH(OH)—, it is preferable that the content (molar ratio) of the repeating unit represented by —CH₂—CH(OH)— be the highest among all the repeating units.

In the polyvinyl alcohol, the content of the repeating unit represented by —CH₂—CH(OH)— with respect to the total content of repeating units in the polymer is preferably 51 to 100 mol %, and more preferably 75 to 100 mol %.

The weight-average molecular weight of the polyvinyl alcohol is preferably 400 to 50,000.

(Polystyrene Sulfonic Acid and Salt Thereof)

The polystyrene sulfonic acid is a polymer containing a repeating unit based on styrene sulfonic acid.

A polystyrene sulfonic acid salt is a polymer formed in a case where some or all of sulfonic acid groups of the styrene sulfonic acid-based repeating unit in the aforementioned polystyrene sulfonic acid are replaced with a salt (an alkali metal salt such as a sodium salt, an alkaline earth metal salt, an ammonium salt, or the like).

That is, the polystyrene sulfonic acid and a salt thereof are a polymer containing a styrene sulfonic acid-based repeating unit (the generic term for a repeating unit based on styrene sulfonic acid and a repeating unit formed in a case where a sulfonic acid group of the repeating unit based on styrene sulfonic acid is replaced with a salt).

In a case where the polystyrene sulfonic acid and a salt thereof also contain a repeating unit other than the styrene sulfonic acid-based repeating unit, it is preferable that the content (molar ratio) of the styrene sulfonic acid-based repeating unit be the highest among all the repeating units.

In the polystyrene sulfonic acid and a salt thereof, the content of the styrene sulfonic acid-based repeating unit with respect to the total content of repeating units in the polymer is preferably 51 to 100 mol %, and more preferably 75 to 100 mol %.

The weight-average molecular weight of the polystyrene sulfonic acid and a salt thereof is preferably 400 to 50,000.

(Nitrogen Atom-Containing Polymer Other than Polyethyleneimine)

The nitrogen atom-containing polymer other than polyethyleneimine is preferably other than the specific additive described above.

The nitrogen atom-containing polymer other than polyethyleneimine is a polymer containing a repeating unit containing a nitrogen atom (N-containing repeating unit).

The N-containing repeating unit mentioned herein does not include —CH₂—CH₂—N<. As long as a polymer contains the N-containing repeating unit, even though the polymer contains —CH₂—CH₂—N< as a part of the entire repeating unit, this polymer corresponds to the nitrogen atom-containing polymer other than polyethyleneimine

In a case where the nitrogen atom-containing polymer other than polyethyleneimine also contains a repeating unit other than the N-containing repeating unit, it is preferable that the content (molar ratio) of the N-containing repeating unit be the highest among all the repeating units.

In the nitrogen atom-containing polymer other than polyethyleneimine, the content of the N-containing repeating unit with respect to the total content of repeating units in the polymer is preferably 51 to 100 mol %, and more preferably 75 to 100 mol %.

The weight-average molecular weight of the nitrogen atom-containing polymer other than polyethyleneimine is preferably 400 to 50,000.

Examples of monomers as sources of the N-containing repeating unit include vinylpyrrolidone, allylamine, vinylamine, acrylamide, a hexadimethrine salt (such as a halide salt, a hydroxide, a nitrate, or a sulfate), diallylamine, a dimethyldiallylammonium salt (such as a halide salt, a hydroxide salt, a nitrate, or a sulfate), 4-vinylpyridine, ornithine, lysine, arginine, histidine, vinylimidazole, and methyldiallylamine. As the N-containing repeating unit, a repeating unit consisting of dimethylamine and epihalohydrin (preferably epichlorohydrin) may also be used.

The nitrogen atom-containing polymer other than polyethyleneimine is preferably one or more kinds of polymers selected from the group consisting of polyvinylpyrrolidone, polyallylamine, polyvinylamine, polyacrylamide, a dimethylamine epihydrin-based polymer (preferably a dimethylamine-epihalohydrin copolymer, and more preferably a dimethylamine-epichlorohydrin copolymer), a hexadimethrine salt (such as a halide salt, a hydroxide, a nitrate, or a sulfate), polydiallylamine, a polydimethyldiallylammonium salt (such as a halide salt, a hydroxide salt, a nitrate, or a sulfate), poly(4-vinylpyridine), polyornithine, polylysine, polyarginine, polyhistidine, polyvinylimidazole, and polymethyldiallylamine.

(Polyoxyethylene Lauryl Amine)

The polyoxyethylene lauryl amine is preferably other than the specific additive described above.

The polyoxyethylene lauryl amine is, for example, a compound represented by “C₁₂H₂₅—N [(C₂H₄O)_{PE}H]₂”.

In “C₁₂H₂₅—N[(C₂H₄O)_{PE}H]₂”, two PEs each independently represent an integer of 1 to 100.

(Alkyl Naphthalenesulfonic Acid and Salt Thereof)

The alkyl naphthalenesulfonic acid and a salt thereof are preferably other than the specific additive described above.

The alkyl naphthalenesulfonic acid is preferably a compound represented by “(AL-)_{NL}R^{NP}—SO₃H”.

In “(AL-)_{NL}R^{NP}—SO₃H”, NL represents an integer of 1 to 7.

AL represents an alkyl group. The alkyl group may be linear or branched, or the entirety or a part of the alkyl group may form a cyclic structure. The number of carbon atoms in the alkyl group is preferably 1 to 25. In a case where the compound has a plurality of ALs, the plurality of ALs may be the same as or different from each other.

R^{NP} represents a naphthalene ring group which may have a substituent other than AL- and —SO₃H.

An alkyl naphthalenesulfonic acid salt is preferably a compound formed in a case where some or all of the sulfonic acid groups in the aforementioned alkyl naphthalenesulfonic acid are replaced with a salt (an alkali metal salt such as a sodium salt, an alkaline earth metal salt, an ammonium salt, or the like).

The alkyl naphthalenesulfonic acid and a salt thereof are preferably one or more kinds of compounds selected from the group consisting of propyl naphthalenesulfonic acid, triisopropyl naphthalenesulfonic acid, and dibutyl naphthalenesulfonic acid. Salts of these compounds are also preferable.

(Alkyl Diphenyl Ether Disulfonic Acid and Salt Thereof)

The alkyl diphenyl ether disulfonic acid and a salt thereof are preferably other than the specific additive described above.

The alkyl diphenyl ether disulfonic acid is preferably a compound represented by General Formula (C1).

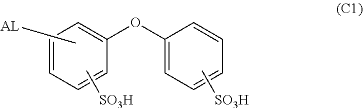

In General Formula (C1), AL represents an alkyl group. The alkyl group may be linear or branched, or the entirety or a part of the alkyl group may form a cyclic structure. The number of carbon atoms in the alkyl group is preferably 1 to 25. In a case where the compound has a plurality of ALs, the plurality of ALs may be the same as or different from each other.

An alkyl diphenyl ether disulfonic acid salt is preferably a compound formed in a case where some or all of the sulfonic acid groups in the aforementioned alkyl diphenyl ether disulfonic acid are replaced with a salt (an alkali metal salt such as a sodium salt, an alkaline earth metal salt, an ammonium salt, or the like).

The alkyl diphenyl ether disulfonic acid and a salt thereof are preferably dodecyl diphenyl ether disulfonic acid. A salt of this compound is also preferable.

(Phenolsulfonic Acid Formaldehyde Condensate and a Salt Thereof)

The phenolsulfonic acid formaldehyde condensate and a salt thereof are preferably other than the specific additive described above.

The phenolsulfonic acid formaldehyde condensate is a polymer containing a repeating unit formed by the condensation of phenolsulfonic acid and formaldehyde.

A phenolsulfonic acid formaldehyde condensate salt is a polymer formed in a case where some or all of the sulfonic acid groups of the repeating unit, which is formed by the condensation of phenolsulfonic acid and formaldehyde, in the phenolsulfonic acid formaldehyde condensate are replaced with a salt (an alkali metal salt such as a sodium salt, an alkaline earth metal salt, an ammonium salt, or the like).

That is, the phenolsulfonic acid formaldehyde condensate and a salt thereof are a polymer containing a phenolsulfonic acid formaldehyde-based repeating unit (the generic term for a repeating unit formed by the condensation of phenolsulfonic acid and formaldehyde and a repeating unit formed in a case where a sulfonic acid group in the repeating unit formed by the condensation of phenolsulfonic acid and formaldehyde is replaced with a salt).

In a case where the phenolsulfonic acid formaldehyde condensate and a salt thereof also contain a repeating unit other than the phenolsulfonic acid formaldehyde-based repeating unit, it is preferable that the content (molar ratio) of the phenolsulfonic acid formaldehyde-based repeating unit be the highest among all the repeating units.

In the phenolsulfonic acid formaldehyde condensate and a salt thereof, the content of the phenolsulfonic acid formaldehyde-based repeating unit with respect to the total content of repeating units in the polymer is preferably 51 to 100 mol %, and more preferably 75 to 100 mol %.

The weight-average molecular weight of the phenolsulfonic acid formaldehyde condensate and a salt thereof is preferably 400 to 50,000.

(Aryl Phenolsulfonic Acid Formaldehyde Condensate and Salt Thereof)

The aryl phenolsulfonic acid formaldehyde condensate and a salt thereof are preferably other than the specific additive described above.

Examples of the aryl phenolsulfonic acid formaldehyde condensate and a salt thereof include a polymer formed in a case where the phenolsulfonic acid described above for the phenolsulfonic acid formaldehyde condensate and a salt thereof is replaced with aryl phenolsulfonic acid.

Examples of the aryl group in the aryl phenolsulfonic acid include an aryl group having 6 to 14 carbon atoms.

(Polyoxyethylene Alkyl Ether Sulfonic Acid and Salt Thereof)

The polyoxyethylene alkyl ether sulfonic acid and a salt thereof are preferably other than the specific additive described above.

The polyoxyethylene alkyl ether sulfonic acid and a salt thereof are, for example, a compound represented by “AL-O—(C₂H₄O)_{PE}—SO₃H” and a salt thereof.

In “AL-O—(C₂H₄O)_{PE}—SO₃H”, PE represents an integer of 1 or more. PE is preferably an integer of 1 to 100.

AL represents an alkyl group. The alkyl group may be linear or branched, or the entirety or a part of the alkyl group may form a cyclic structure. The number of carbon atoms in the alkyl group is preferably 1 to 25.

The polyoxyethylene alkyl ether sulfonic acid and a salt thereof are preferably one or more kinds of compounds selected from the group consisting of polyoxyethylene lauryl ether sulfonic acid, polyoxyethylene oleyl ether sulfonic acid, and polyoxyethylene octyldodecyl ether sulfonic acid. Salts of these compounds are also preferable.

(Polyoxyethylene Alkyl Ether Carboxylic Acid and Salt Thereof)

The polyoxyethylene alkyl ether carboxylic acid and a salt thereof are preferably other than the specific additive described above.

The polyoxyethylene alkyl ether carboxylic acid and a salt thereof are, for example, a compound represented by “AL-O—(C₂H₄O)_{PE}—CH₂—COOH” and a salt thereof.

In “AL-O—(C₂H₄O)_{PE}—CH₂—COOH”, PE represents an integer of 1 or more. PE is preferably an integer of 1 to 100.

AL represents an alkyl group. The alkyl group may be linear or branched, or the entirety or a part of the alkyl group may form a cyclic structure. The number of carbon atoms in the alkyl group is preferably 1 to 25.

The polyoxyethylene alkyl ether carboxylic acid and a salt thereof are preferably one or more kinds of compounds selected from the group consisting of polyoxyethylene lauryl ether carboxylic acid, polyoxyethylene dodecyl ether carboxylic acid, and polyoxyethylene tridecyl ether carboxylic acid. Salts of these compounds are also preferable.

(Polyoxyethylene Alkyl Ether Phosphoric Acid and Salt Thereof)

The polyoxyethylene alkyl ether phosphoric acid is preferably other than the specific additive described above.

The polyoxyethylene alkyl ether phosphoric acid and a salt thereof are, for example, a compound represented by “AL-O—(C₂H₄O)_{PE}—PO₃H₂” or “[AL-O—(C₂H₄O)_{PE}-]₂PO₂H” and a salt thereof.

In “AL-O—(C₂H₄O)_{PE}—PO₃H₂” and “[AL-O—(C₂H₄O)_{PE}-]₂PO₂H”, PE represents an integer of 1 or more. PE is preferably an integer of 1 to 100.

AL represents an alkyl group. The alkyl group may be linear or branched, or the entirety or a part of the alkyl group may form a cyclic structure. The number of carbon atoms in the alkyl group is preferably 1 to 25.

In a case where the compound has a plurality of moieties represented by “AL-O—(C₂H₄O)_{PE}—”, the plurality of moieties represented by “AL-O—(C₂H₄O)_{PE}—” may be the same as or different from each other.

As the polyoxyethylene alkyl ether phosphoric acid and a salt thereof are preferably polyoxyethylene lauryl ether phosphoric acid. A salt of this compound is also preferable.

(Polyoxyethylene Alkyl Phenyl Ether Phosphoric Acid and Salt Thereof)

The polyoxyethylene alkyl phenyl ether phosphoric acid and a salt thereof are preferably other than the specific additive described above.

The polyoxyethylene alkyl phenyl ether phosphoric acid and a salt thereof are, for example, a compound represented by “AL-Ph-O—(C₂H₄O)_{PE}—PO₃H₂” or “[AL-Ph-O—(C₂H₄O)_{PE}-]₂PO₂H” and a salt thereof.

In “AL-Ph-O—(C₂H₄O)_{PE}—PO₃H₂” or “[AL-Ph-O—(C₂H₄O)_{PE}-]₂PO₂H”, PE represents an integer of 1 or more. PE is preferably an integer of 1 to 100.

Ph represents a benzene ring group.

AL represents an alkyl group. The alkyl group may be linear or branched, or the entirety or a part of the alkyl group may form a cyclic structure. The number of carbon atoms in the alkyl group is preferably 1 to 25.

In a case where the compound has a plurality of moieties represented by “AL-Ph-O—(C₂H₄O)_{PE}—”, the plurality of moieties represented by “AL-Ph-O—(C₂H₄O)_{PE}—” may be the same as or different from each other.

(Silicon Compound)

The silicon compound is preferably other than the specific additive described above.

The silicon compound is a compound having a silicon atom (Si).

The silicon compound is preferably one or more kinds of compounds selected from the group consisting of alkoxysilane, a silanol compound, oxime silane, disilazane, and siloxane.

Alkoxysilane

The alkoxysilane is preferably other than the specific additive described above.

The alkoxysilane is, for example, a compound having at least one group (preferably one to six groups) represented by “alkyl group-O—” directly bonded to a silicon atom.

The alkoxysilane is preferably a compound represented by “(AL²-O—)_{S1}SiR^{Si}_{S2}”.

In “(AL²-O—)_{S1}SiR^{Si}_{S2}”, S1 represents an integer of 1 to 4.

S2 represents an integer of 0 to 3.

Here, S1+S2 equals 4.

AL² represents an alkyl group. The alkyl group may be linear or branched, or the entirety or a part of the alkyl group may form a cyclic structure. The number of carbon atoms in the alkyl group is preferably 1 to 5.

R^{Si} represents a hydrogen atom or a substituent other than “AL²-O—”. Examples of the substituents include an alkyl group (preferably having 1 to 10 carbon atoms), an aryl group (preferably having 6 to 15 carbon atoms), an aminoalkyl group (preferably having 1 to 10 carbon atoms), an aminoalkoxyaminoalkyl group (preferably having 1 to 12 carbon atoms), a halogen atom, and a group consisting of a combination of these. It is also preferable that the substituents satisfy the requirement that all the substituents are an organic group having 1 to 15 carbon atoms.

In a case where the compound has a plurality of AL²'s and/or R^{Si}'s, the plurality of AL²'s and/or R^{Si}'s may be the same as or different from each other.

The alkoxysilane is preferably a compound represented by “L^{Si}[—Si(—O-AL²)_{S3}R^{Si}_{S4}]₂”.

In “L^{Si}[—Si(—O-AL²)_{S3}R^{Si}_{S4}]₂”, L^{Si} represents a single bond or a divalent linking group. The divalent linking group is preferably an alkylene group (preferably having 1 to 10 carbon atoms).

S3 represents an integer of 1 to 3.

S4 represents an integer of 0 to 2.

Here, in one moiety represented by “—Si(—O-AL²)_{S3}R^{Si}_{S4}”, S3+S4 equals 3.

AL² and R^{Si} in “L^{Si}[—Si(—O-AL²)_{S3}R^{Si}_{S4}]₂” have the same definitions as AL² and R^{Si} in “(AL²-O—)_{S1}SiR^{Si}_{S2}” respectively.

In a case where the compound has a plurality of AL²'s, S3's, and/or S4's, the plurality of AL²'s, R^{Si}'s, S3's, and/or S4's may be the same as or different from each other respectively.

The alkoxysilane is preferably one or more kinds of compounds selected from the group consisting of tetraethoxysilane, methyltrimethoxysilane, dimethyldimethoxysilane, phenyltrimethoxysilane, methyltriethoxysilane, dimethyldiethoxysilane, phenyltriethoxysilane, n-propyltrimethoxysilane, and n-propyltriethoxysilane, hexyltrimethoxysilane, hexyltriethoxysilane, octyltriethoxysilane, 1,6-bis(trimethoxysilyl)hexane, trifluoropropyltrimethoxysilane, t-butylmethoxydimethylsilane, 3-aminopropyldimethylmethoxysilane, ethoxy(trimethyl)silane, methoxy(trimethyl)silane, hexyl(dimethoxy)silane, methyldiethoxysilane, triethoxysilane, 3-aminopropyldimethylethoxysilane, and 3-(2-aminoethoxyamino)propyltrimethoxysilane.

Silanol Compound

The silanol compound is, for example, a compound having at least one (preferably one to six) hydroxyl group that is directly bonded to a silicon atom.

Here, the silanol compound does not have an alkoxy group that is directly bonded to a silicon atom.

The silanol compound is preferably a compound represented by “R^{SJ}_{S5}Si(OH)_{S6}”.

In “R^{SJ}_{S5}Si(OH)_{S6}”, S5 represents an integer of 0 to 4.

S6 represents an integer of 1 to 4.

Here, S5+S6 equals 4.

R^{SJ} represents a hydrogen atom or a substituent that is neither an alkoxy group nor a hydroxyl group. Examples of the substituent include an alkyl group (preferably having 1 to 10 carbon atoms), an alkenyl group (preferably having 2 to 10 carbon atoms), an aryl group (preferably having 6 to 15 carbon atoms), an amino group, an acetyl group, a halogen atom, and a group consisting of a combination of these. It is also preferable that the substituents satisfy the requirement that all the substituents are an organic group having 1 to 15 carbon atoms.

In a case where the compound has a plurality of R^{SJ}'s, the plurality of R^{SJ}'s may be the same as or different from each other.

The silanol compound is preferably one or more kinds of compounds selected from the group consisting of trimethylsilanol, dimethylsilanediol, diphenylsilanediol, silanetriol, 3-aminopropylsilanetriol, methylsilanetriol, 2-methyl-2-propylsilanetriol, methyl acetate silanetriol, 2-(chloroethyl)acetate silanetriol, and 3-(hydroxypropyl)silanetriol.

Oxime Silane

The oxime silane is preferably other than the specific additive described above.

The oxime silane is a compound having at least one (preferably one to six) group represented by “—O—N═CR^{OX}₂” that is directly bonded to a silicon atom. Two R^{OX}'s bonded to the same carbon atom each independently represent a hydrogen atom or an organic group. Furthermore, two R^{OX}'s bonded to the same carbon atom may be bonded to each other to form a ring. Here, at least one of the two R^{OX}'s bonded to the same carbon atom is other than a hydrogen atom.

The aforementioned organic group is preferably an alkyl group. The alkyl group may be linear or branched, or the entirety or a part of the alkyl group may form a cyclic structure. The number of carbon atoms in the alkyl group is preferably 1 to 25. In a case where two R^{OX}'s are bonded to each other to form a ring, the group to which two R^{OX}'s are bonded is preferably an alkylene group (preferably having 2 to 15 carbon atoms).

Here, the oxime silane does not have a group represented by an alkoxy group and/or a hydroxyl group that is directly bonded to a silicon atom.

The oxime silane is preferably a compound represented by “R^{SK}_{S7}Si(—O—N═CR^{OX}₂)_{S8}”.

In “R^{SK}_{S7}Si(—O—N═CR^{OX}₂)_{S8}”, S7 represents an integer of 0 to 4.

S8 represents an integer of 1 to 4.

Here, S7+S8 equals 4.

R^{SK} represents a hydrogen atom or a substituent that is none of an alkoxy group, a hydroxyl group, and a group represented by “—O—N═CR^{OX}₂”. Examples of the substituent include an alkyl group (preferably having 1 to 10 carbon atoms), an alkenyl group (preferably having 2 to 10 carbon atoms), an aryl group (preferably having 6 to 15 carbon atoms), an amino group, an acetyl group, a halogen atom, and a group consisting of a combination of these. It is also preferable that the substituents satisfy the requirement that all the substituents are an organic group having 1 to 15 carbon atoms.

R^{OX} is as described above.

In a case where the compound has a plurality of R^{SK}'s and/or R^{OX}'s, the plurality of R^{SK}'s and/or R^{OX}'s may be the same as or different from each other.

The oxime silane is preferably one or more kinds of compounds selected from the group consisting of di(ethylaldoxime)silane, mono(ethylaldoxime)silane, tris(ethylaldoxime)silane, tetra(ethylaldoxime)silane, methyltris(methylethylketoxime)silane, methyltosyl(acetoxime)silane, methyltris(methylisobutylketoxime)silane, dimethyldi(methylethylketoxime)silane, trimethyl(methylethylketoxime)silane, tetra(methylethylketoxime)silane, tetra(methylisobutylketoxime)silane, vinyltris(methylethylketoxime)silane, methylvinyldi(methylethylketoxime)silane, methylvinyldi(cyclohexanonexime)silane, vinyltris(methylisobutylketoxime)silane, and phenyltris(methylethylketoxime)silane.

Disilazane

The disilazane is preferably other than the specific additive described above.

The disilazane is, for example, a compound represented by “R^{SL}₃Si—NH—SiR^{SL}₃”.

R^{SK} represents a hydrogen atom or a substituent that is none of an alkoxy group, a hydroxyl group, and a group represented by “—O—N═CR^{OX}₂”. Examples of the substituent include an alkyl group (preferably having 1 to 10 carbon atoms), an alkenyl group (preferably having 2 to 10 carbon atoms), an aryl group (preferably having 6 to 15 carbon atoms), an amino group, an acetyl group, a halogen atom, and a group consisting of a combination of these. It is also preferable that the substituents satisfy the requirement that all the substituents are an organic group having 1 to 15 carbon atoms.

Here, the disilazane does not have an alkoxy group, a group represented by “—O—N═CR^{OX}₂”, and/or a hydroxyl group that is directly bonded to a silicon atom.

The disilazane is preferably hexamethyldisilazane.

Siloxane

The siloxane is preferably other than the specific additive described above.

The siloxane compound is, for example, a compound represented by “R^{SM}₃Si(—O—SiR^{SN}₂-)_{S9}R^{SO}”.

In “R^{SM}₃Si(—O—SiR^{SN}₃—)_{S9}R^{SO}”, S9 represents an integer of 1 or more. S9 is preferably an integer of 1 to 10.

Three R^{SM}'s, 2×S9 pieces of R^{SN}'s, and R^{SO} each independently represent a hydrogen atom or a substituent that is none of an alkoxy group, a hydroxyl group, and a group represented by “—O—N═CR^{OX}₂”.

Examples of the substituent include an alkyl group (preferably having 1 to 10 carbon atoms), an alkenyl group (preferably having 2 to 10 carbon atoms), an aryl group (preferably having 6 to 15 carbon atoms), an amino group, an acetyl group, a halogen atom, and a group consisting of a combination of these. It is also preferable that the substituents satisfy the requirement that all the substituents are an organic group having 1 to 15 carbon atoms.

One of the three R^{SM}'s and R^{SO} may be bonded to each other to form a divalent linking group. In a case where the divalent linking group is formed, —O— is preferable as the divalent linking group.

The siloxane is preferably one or more kinds of compounds selected from the group consisting of hexamethyldisiloxane, octamethylcyclotetrasiloxane, decamethylcyclopentasiloxane, and dodecamethylcyclohexasiloxane.

(Alkylamine)

The alkylamine is preferably other than the specific additive described above.

The alkylamine is a compound containing at least one partial structure represented by “alkyl group-N”. The alkyl group may have a substituent.

Here, it is preferable that the alkylamine be none of the aforementioned specific additive, the nitrogen-containing heterocyclic compound that will be described later, and the amino acid other than cysteine that will be described later.

The molecular weight of the alkylamine is preferably 15 or more and less than 400, and more preferably 15 or more and 300 or less.

The alkylamine is preferably a compound represented by “R^{N}₂N(-L^{N}-NR^{LN}—)_{XN}R^{N}”.

In “R^{N}₂N(-L^{N}-NR^{LN}—)_{XN}R^{N}”, XN represents an integer of 0 to 6.

Three R^{N}'s and XN pieces of R^{LN}'s each independently represent a hydrogen atom or an alkyl group which may have a substituent.

The alkyl group in the aforementioned alkyl group which may have a substituent may be linear or branched, or the entirety or a part of the alkyl group may form a cyclic structure. The number of carbon atoms in the alkyl group is preferably 1 to 120.

The substituent in the aforementioned alkyl group which may have a substituent is preferably an aryl group (preferably having 6 to 15 carbon atoms), an aminoalkyl group (preferably having 1 to 5 carbon atoms), or a group obtained by combining these. It is also preferable that the substituent be other than a carboxy group.

The total number of carbon atoms of the aforementioned alkyl group which may have a substituent is preferably 1 to 20.

XN pieces of L^{N}'s each independently represent an alkylene group having 1 to 8 carbon atoms.

Here, in a case where XN is 0, at least one of three R^{N}'s is the aforementioned alkyl group which may have a substituent.

The alkylamine is preferably one or more kinds of compounds selected from the group consisting of ethylenediamine, diethylenetriamine, triethylenetetramine, tetraethylenepentamine, pentaethylenehexamine, tetramethylethylenediamine, hexamethylenediamine, methylamine, dimethylamine, trimethylamine, ethylamine, diethylamine, triethylamine, 2-ethylhexylamine, stearylamine, cyclohexylamine, phenethylamine, and m-xylylenediamine.

(Aromatic amine)

The aromatic amine is preferably other than the specific additive described above.

The aromatic amine is a compound containing at least one partial structure represented by “aromatic ring group-N”. The aromatic ring group may have a substituent.

Here, it is preferable that the aromatic amine be none of the aforementioned specific additive, the nitrogen-containing heterocyclic compound that will be described later, and the amino acid other than cysteine that will be described later.

The molecular weight of the aromatic amine is preferably 15 or more and less than 400, and more preferably 15 or more and 300 or less.

The aromatic amine is preferably a compound represented by “R^{N}₂N-aromatic ring group which may have a substituent”.

In “R^{N}₂N-aromatic ring group which may have a substituent”, two R^{N}'s each independently represent a hydrogen atom or a substituent other than an alkyl group.

The substituent in the aforementioned aromatic ring group which may have a substituent is preferably an alkyl group (preferably having 1 to 20 carbon atoms), an aryl group (preferably having 6 to 15 carbon atoms), an aminoalkyl group (preferably having 1 to 5 carbon atoms), or a group obtained by combining these.

The total number of carbon atoms of the aforementioned aromatic ring group which may have a substituent is preferably 1 to 20.

The aromatic ring group in the aromatic ring group which may have a substituent preferably has 5 to 15 carbon atoms, and may contain a hetero atom as a ring member atom.

The aromatic amine is preferably one or more kinds of compounds selected from the group consisting of aniline and toluidine.

(Nitrogen-Containing Heterocyclic Compound)

The nitrogen-containing heterocyclic compound is preferably other than the specific additive described above.

The nitrogen-containing heterocyclic compound is a compound having a heterocyclic structure having at least one (preferably one to four) nitrogen atom as a ring member atom.

The nitrogen atom as a ring member atom of the heterocyclic structure may be a cationic nitrogen atom (N⁺).

The heterocyclic structure may have a heteroatom (such as an oxygen atom or a sulfur atom) as a ring member atom, in addition to the nitrogen atom.

The heterocyclic structure may be monocyclic or polycyclic. In a case where the heterocyclic structure is monocyclic, a 5- to 8-membered ring is preferable. In a case where the heterocyclic structure is polycyclic, the total number of rings is preferably 2 to 5, and it is also preferable that each ring be a 5- to 8-membered ring.

The heterocyclic structure may or may not have aromaticity. In a case where the heterocyclic structure is polycyclic, rings having aromaticity may be fused together, rings having no aromaticity may be fused together, or a ring having aromaticity and a ring having no aromaticity may be fused together.

The number of ring member atoms constituting the heterocyclic structure is preferably 3 to 20.

The heterocyclic structure may contain a substituent (such as primary to tertiary amino groups).

The nitrogen-containing heterocyclic compound may have only one heterocyclic structure described above or may have a plurality of heterocyclic structures described above.

The molecular weight of the nitrogen-containing heterocyclic compound is preferably 40 or more and less than 400, and more preferably 50 or more and 300 or less.

The nitrogen-containing heterocyclic compound is preferably one or more kinds of compounds selected from the group consisting of pyrrolidine, piperidine, piperazine, morpholine, pyrrole, pyrazole, imidazole, pyridine, pyrimidine, pyrazine, oxazole, thiazole, 4-dimethylaminopyridine, and laurylpyridinium chloride.

(Amino Acid Other than Cysteine)

The amino acid other than cysteine is preferably other than the specific additive described above.

The amino acid other than cysteine is preferably a compound containing a carboxy group and a primary or secondary amino group.

The amino acid other than cysteine is preferably one or more kinds of amino acids selected from the group consisting of alanine, arginine, asparagine, aspartic acid, glutamine, glutamic acid, glycine, histidine, isoleucine, leucine, lysine, methionine, phenylalanine, proline, serine, threonine, tryptophan, tyrosine, and valine.

(Quaternary Ammonium Salt Having 16 or Less Carbon Atoms)

The quaternary ammonium salt having 16 or less carbon atoms is preferably other than the specific additive described above.

The quaternary ammonium salt having 16 or less carbon atoms does not include a pyridinium salt.

The quaternary ammonium salt having 16 or less carbon atoms is, for example, a compound represented by “R^{T}₄N⁺.T⁻”.

In “R^{T}₄N⁺.T⁻”, four R^{T}'s each independently represent an organic group having a carbon atom as an atom directly bonded to N⁺. The organic group is preferably an alkyl group which may have a substituent or an aryl group which may have a substituent.

The alkyl group in the aforementioned alkyl group which may have a substituent may be linear or branched, or the entirety or a part of the alkyl group may form a cyclic structure. The number of carbon atoms in the alkyl group is preferably 1 to 110.

The substituent in the aforementioned alkyl group which may have a substituent is preferably a hydroxyl group or an aryl group (preferably having 6 to 10 carbon atoms).

The aryl group in the aforementioned aryl group which may have a substituent preferably has 6 to 12 carbon atoms.

The substituent in the aforementioned aryl group which may have a substituent is preferably a hydroxyl group or an alkyl group (preferably having 1 to 10 carbon atoms).

T represents a counteranion other than F. The counteranion is preferably OH⁻.

Here, the total number of carbon atoms contained in the compound represented by “R^{T}₄N⁺.T⁻” is 16 or less, and preferably 4 to 16.

The quaternary ammonium salt having 16 or less carbon atoms is preferably one or more kinds of compounds selected from the group consisting of a tetramethylammonium salt, a tetraethylammonium salt, a tetrapropylammonium salt, a tetrabutylammonium salt, a methyltripropylammonium salt, a methyltributylammonium salt, an ethyltrimethylammonium salt, a dimethyldiethylammonium salt, a benzyltrimethylammonium salt, and a (2-hydroxyethyl)trimethylammonium salt.

(Boron-Containing Compound)

The boron-containing compound is preferably other than the specific additive described above.

The boron-containing compound is a compound containing a boron atom (B).

The boron atom-containing compound is preferably a compound having “—OH” directly bonded to a boron atom.

The molecular weight of the boron-containing compound is preferably 50 or more and less than 400, and more preferably 60 or more and 300 or less.

The boron-containing compound is preferably boric acid.

<Organic Solvent>

The treatment liquid preferably contains an organic solvent.

Examples of the organic solvent include an alcohol-based solvent, a ketone-based solvent, an ester-based solvent, an ether-based solvent (for example, including (poly)alkylene glycol in which both terminals are substituted with an alkyl group or an amino group), a sulfone-based solvent, a sulfoxide-based solvent, a nitrile-based solvent, and an amide-based solvent.

Examples of the alcohol-based solvent include alkanediol (including alkylene glycol, for example), alkoxy alcohol (including glycol monoether, for example), a saturated aliphatic monohydric alcohol, an unsaturated non-aromatic monohydric alcohol, and a low-molecular-weight alcohol having a ring structure.

It is also preferable that the organic solvent be other than an acetate-based solvent.

In addition, it is preferable that the treatment liquid substantially do not contain the acetate-based solvent. For example, it is also preferable that the content of the acetate-based solvent be 0% to 1% by mass with respect to the total mass of the treatment liquid.

The organic solvent is preferably one or more kinds of compounds selected from the group consisting of ethylene glycol, propylene glycol, butyl diglycol, 1,4-butanediol, tripropylene glycol methyl ether, propylene glycol propyl ether, diethylene glycol n-butyl ether, hexyloxypropylamine, poly(oxyethylene)diamine, dimethyl sulfoxide, tetrahydrofurfuryl alcohol, glycerol, sulfolane, ethylene glycol monomethyl ether, ethylene glycol monoethyl ether, ethylene glycol monobutyl ether, ethylene glycol dimethyl ether, ethylene glycol diethyl ether, diethylene glycol monomethyl ether, diethylene glycol monoethyl ether, diethylene glycol monopropyl ether, diethylene glycol monoisopropyl ether, diethylene glycol monoisobutyl ether, diethylene glycol monobenzyl ether, diethylene glycol dimethyl ether, diethylene glycol diethyl ether, triethylene glycol monomethyl ether, triethylene glycol dimethyl ether, polyethylene glycol monomethyl ether, diethylene glycol methyl ethyl ether, propylene glycol monomethyl ether, propylene glycol dimethyl ether, propylene glycol monobutyl ether, monopropyl ether, dipropylene glycol monomethyl ether (DPM), dipropylene glycol monoisopropyl ether, dipropylene glycol monobutyl ether, dipropylene glycol diisopropyl ether, 1-methoxy-2-butanol, 2-methoxy-1-butanol, 2-methoxy-2-methylbutanol, 1,1-dimethoxyethane, 2-(2-butoxyethoxy)ethanol, methanol, ethanol, isopropanol, and 1-butanol, and more preferably one or more kinds of compounds selected from the group consisting of propylene glycol and sulfolane.

The content of the organic solvent is not particularly limited. In view of further improving the effect of the present invention, the content of the organic solvent with respect to the total mass of the treatment liquid is preferably 1% to 70% by mass, more preferably 10% to 60% by mass, and even more preferably 20% to 45% by mass.

One kind of organic solvent may be used alone, or two or more kinds of organic solvents may be used. In a case where two or more kinds of organic solvents are used, the total amount thereof is preferably within the above range.

<Water>

It is preferable that the treatment liquid contain water.

The water is not particularly limited, and examples thereof include distilled water, deionized water, and pure water.

The content of water in the treatment liquid is not particularly limited. The content of water with respect to the total mass of the treatment liquid is preferably 20% by mass or more, more preferably 30% by mass or more, and even more preferably 55% by mass or more. The upper limit of the content of water is less than 100% by mass, preferably 90% by mass or less, and more preferably 80% by mass or less.

<Manufacturing Method of Treatment Liquid>

The manufacturing method of the treatment liquid is not particularly limited, and known manufacturing methods can be used. Examples of the manufacturing method include a method of mixing together predetermined amounts of water, fluoride ion source, oxidant, specific additive, and the like. In mixing the above components, as necessary, other optional components may be mixed together.

Furthermore, in manufacturing the treatment liquid, as necessary, the treatment liquid may be purified by being filtered using a filter.

In view of further improving the effect of the present invention, the pH of the treatment liquid is preferably less than 7, and more preferably less than 4.

In order to adjust the pH, the treatment liquid may contain a pH adjuster. Examples of the pH adjuster include an acid compound (such as an inorganic or organic acid) other than the aforementioned components, and a basic compound (such as an inorganic or organic base).

<Treatment Liquid Container and Method of Providing Treatment Liquid>

The treatment liquid may be stored in a container and kept as it is until use.

The container and the treatment liquid stored in the container are collectively called treatment liquid container. The stored treatment liquid is used after being taken out of the treatment liquid container. It is also preferable that the treatment liquid be transported as a treatment liquid container and provided from the manufacturer to the user, from the storage place to the place of use, or the like.

It is also preferable that the container have a degassing mechanism for adjusting the pressure (internal pressure) in the container. The degassing mechanism is, for example, a mechanism which releases the generated gas from the inside of the container to the outside in a case where gas is generated from the treatment liquid by the increase in temperature of the treatment liquid in the container during storage of the treatment liquid container and/or by the decomposition of some components of the treatment liquid and the like, so that the internal pressure is kept within a certain range without excessively increasing.

Examples of the degassing mechanism include a check valve.

As a cap of the container, it is also preferable to adopt a degassing cap comprising a degassing mechanism, so that the container includes a degassing mechanism. That is, it is also preferable that the container of the treatment liquid container have a degassing cap comprising a degassing mechanism which adjusts the internal pressure of the container.

In view of ease of handling of the treatment liquid and the like, it is preferable that the treatment liquid be provided from the manufacturer to the user, from the storage place to the place of use, and the like by a method using such a treatment liquid container.

Examples of the degassing cap include a cap provided with a valve (preferably a check valve) that releases the internal gas of the container to the outside in a case where pressure (internal pressure) over a certain level is applied to the cap.

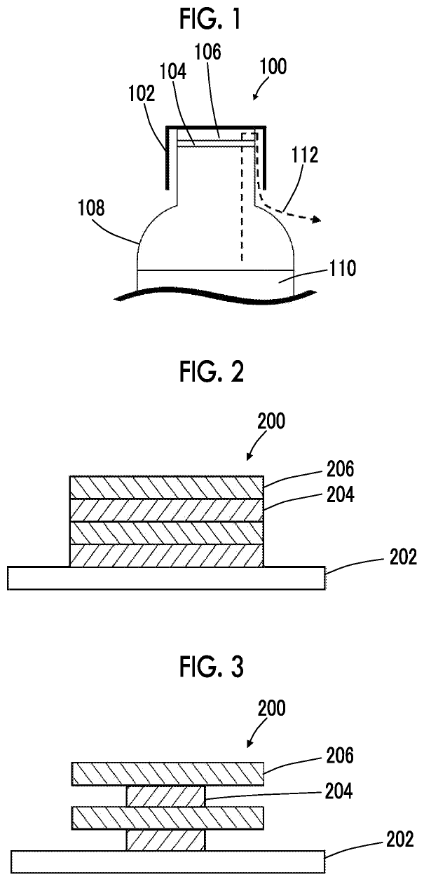

Another example of the degassing cap is illustrated in FIG. 1 which is a schematic cross-sectional view of the upper part of a treatment liquid container to which the degassing cap is applied.

A treatment liquid container 100 has a container consisting of a cap (degassing cap) composed of a cap body 102, a waterproof breathable film 104, and a breathable layer 106 and a container body 108 sealed with the cap. The treatment liquid container 100 also has a treatment liquid 110 stored in the container body 108. The dashed arrow is a virtual flow passage 112 of the gas generated from the treatment liquid 110.

The gas generated from the treatment liquid 110 passes through the waterproof breathable film 104, and then is released to the outside through the breathable layer 106 and the gap between the cap body 102 and the container body 108. In this way, the internal pressure is restrained from excessively increasing by the gas generated from the treatment liquid.

The waterproof breathable film 104 is a highly gas-permeable film that is permeable to a gas but is impermeable to a liquid.

The breathable layer 106 is a layer provided to allow the gas having passed through the waterproof breathable film 104 to rapidly move to the outside. The breathable layer 106 is formed, for example, of a porous material (such as polyethylene foam). The breathable layer 106 may not be provided.

It is also preferable that a mechanism for fixing the cap in a state where the cap is put on the container (for example, a structure that allows the cap body 102 to be screwed on and fixed to the container body 108) be formed between the cap body 102 and the container body 108, although this mechanism is not shown in FIG. 1. This structure is preferably a structure that does not hinder the release of the gas to the outside.

It is preferable to use a container (particularly, a container body) for semiconductors which has a high internal cleanliness and is unlikely to cause elution of impurities. Examples of usable containers include a “CLEAN BOTTLE” series manufactured by AICELLO CORPORATION, and “PURE BOTTLE” manufactured by KODAMA PLASTICS Co., Ltd.

It is preferable that the inner wall of the container (particularly, the container body) be formed of one or more kinds of resins selected from the group consisting of a polyethylene resin, a polypropylene resin, and a polyethylene-polypropylene resin, or formed of a resin different from these. It is also preferable that the inner wall of the container (particularly, the container body) be formed of a metal having undergone a rustproofing treatment or a metal elution preventing treatment, such as stainless steel, Hastelloy, Inconel, or Monel.

As “resin different from these” described above, a fluororesin (perfluororesin) is preferable. In a case where a container having inner wall made of a fluororesin is used, the occurrence of problems such as elution of an ethylene or propylene oligomer can be further suppressed, than in a case where a container having inner wall formed of a polyethylene resin, a polypropylene resin, or a polyethylene-polypropylene resin is used.

Examples of the container having inner wall made of a fluororesin include a FluoroPure PFA composite drum manufactured by Entegris, and the like. In addition, it is also possible to use the containers described on page 4 of JP1991-502677A (JP-H03-502677A), page 3 of WO2004/016526A, pages 9 and 16 of the WO99/46309A, and the like.

Furthermore, in addition to the fluororesin described above, quartz and an electropolished metallic material (that is, a metallic material having undergone electropolishing) are also preferably used for the inner wall of the container (particularly, the container body).

For manufacturing the electropolished metallic material, it is preferable to use a metallic material which contains at least one kind of metal selected from the group consisting of chromium and nickel, and in which the total content of chromium and nickel is more than 25% by mass with respect to the total mass of the metallic material. Examples of such a metallic material include stainless steel and a nickel-chromium alloy.

The total content of chromium and nickel in the metallic material is preferably 30% by mass or more with respect to the total mass of the metallic material.

The upper limit of the total content of chromium and nickel in the metallic material is not particularly limited, but is preferably 90% by mass or less with respect to the total mass of the metallic material.

The stainless steel is not particularly limited, and known stainless steel can be used. Particularly, an alloy with a nickel content of 8% by mass or more is preferable, and austenite-based stainless steel with a nickel content of 8% by mass or more is more preferable.

Examples of the austenite-based stainless steel include Steel Use Stainless (SUS) 304 (Ni content: 8% by mass, Cr content: 18% by mass), SUS304L (Ni content: 9% by mass, Cr content: 18% by mass), SUS316 (Ni content: 10% by mass, Cr content: 16% by mass), and SUS316L (Ni content: 12% by mass, Cr content: 16% by mass).

The nickel-chromium alloy is not particularly limited, and known nickel-chromium alloys can be used. Among these, a nickel-chromium alloy is preferable in which the nickel content is 40% to 75% by mass and the chromium content is 1% to 30% by mass.

Examples of the nickel-chromium alloy include HASTELLOY (trade name, the same is true of the following description), MONEL (trade name, the same is true of the following description), and INCONEL (trade name, the same is true of the following description). More specifically, examples thereof include HASTELLOY C-276 (Ni content: 63% by mass, Cr content: 16% by mass), HASTELLOY C (Ni content: 60% by mass, Cr content: 17% by mass), and HASTELLOY C-22 (Ni content: 61% by mass, Cr content: 22% by mass).

Furthermore, as necessary, the nickel-chromium alloy may further contain boron, silicon, tungsten, molybdenum, copper, or cobalt, in addition to the aforementioned alloy.

The method of electropolishing the metallic material is not particularly limited, and known methods can be used. For example, it is possible to use the methods described in paragraphs “0011” to “0014” in JP2015-227501A, paragraphs “0036” to “0042” in JP2008-264929A, and the like.

It is preferable that the metallic material have undergone buffing As the buffing method, known methods can be used without particular limitation. The size of abrasive grains used for finishing the buffing is not particularly limited, but is preferably #400 or less because such grains make it easy to further reduce the surface asperity of the metallic material.

The buffing is preferably performed before the electropolishing.

Furthermore, one of the multistage buffing carried out by changing the size of abrasive grains, acid pickling, magnetorheological finishing, and the like or a combination of two or more treatments selected from the above may be performed on the metallic material.

It is preferable that the inside of these containers (such as the container body and the cap) be washed before the containers are filled with the treatment liquid. For washing, it is preferable to use a liquid with a lower metal impurity content.

After being manufactured, the treatment liquid may be bottled using a container, such as a gallon bottle or a quart bottle, and transported or stored.

In order to prevent changes in the components of the treatment liquid during storage, the inside of the container may be purged with an inert gas (such as nitrogen or argon) having a purity of 99.99995% by volume or higher. Particularly, a gas with a low moisture content is preferable. Although the treatment liquid may be transported and stored at room temperature, in order to prevent deterioration, the temperature may be controlled in a range of −20° C. to 20° C.

The treatment liquid may be prepared as a kit composed of a plurality of separated raw materials of the treatment liquid.

Furthermore, the treatment liquid may be prepared as a concentrated solution. In a case where the treatment liquid is prepared as a concentrated solution, the concentration factor is appropriately determined depending on the composition, but is preferably 5× to 2,000×. That is, the concentrated solution is used after being diluted 5× to 2,000×.

[Method for Treating Object to be Treated]

<Object to be Treated>

The treatment liquid according to the embodiment of the present invention is preferably applied to a method for treating an object to be treated containing SiGe (hereinafter, the method will be also simply called “the present treatment method”).

In the present treatment method, it is preferable to remove (etch) at least a part of SiGe contained in the object to be treated.

SiGe is a material consisting of a combination of silicon (Si) and germanium (Ge), and is preferably used as a semiconductor material.

SiGe may intentionally or inevitably contain components other than silicon and germanium. In SiGe, the total content of silicon and germanium with respect to the total mass of SiGe is preferably 95% to 100% by mass, more preferably 99% to 100% by mass, and even more preferably 99.9% to 100% by mass.

In SiGe, the element ratio of silicon (Si):germanium (Ge) (ratio between atom % of Si atoms in SiGe and atom % of Ge atoms in SiGe, Si:Ge) is preferably 99:1 to 30:70, more preferably 95:5 to 50:50, and even more preferably 85:15 to 65:35.

The form of the object to be treated is not particularly limited as long as the object contains SiGe. Examples thereof include an object 200 to be treated shown in FIG. 2 containing a substrate 202 and SiGe 204 and other materials 206 that are alternately laminated on the substrate 202.

FIG. 2 shows an aspect in which the object 200 to be treated contains a plurality of SiGe 204 and a plurality of other materials 206. However, either or both of the plurality of SiGe 204 and the plurality of other materials 206 may be present as a single layer. Furthermore, the substrate 202 shown in FIG. 2 has a site where none of the SiGe 204 and other materials 206 exist. However, such a site may be covered with the SiGe 204. In FIG. 2, the SiGe 204 is disposed directly on the substrate 202. However, the SiGe 204 may be disposed via another layer.

The other materials 206 may be other than SiGe. Furthermore, the plurality of other materials 206 may be different layers. Particularly, it is preferable that the object 200 to be treated have at least a piece of other materials 206 which is silicon (Si).

The type of substrate that the object to be treated contains is not particularly limited. Examples of the substrate include various substrates such as a semiconductor wafer, a glass substrate for a photomask, a glass substrate for liquid crystal display, a glass substrate for plasma display, a substrate for field emission display (FED), a substrate for an optical disk, a substrate for a magnetic disk, and a substrate for a magneto-optical disk.

Examples of materials constituting the semiconductor substrate include silicon, a Group III-V compound such as GaAs, and any combination of these.

Especially, it is preferable that the substrate be consist of silicon (Si).

The size, thickness, shape, layer structure, and the like of the substrate are not particularly limited, and can be appropriately selected as desired.

The object to be treated may contain a metal hard mask. For example, the object 200 to be treated shown in FIG. 2 may further contain a metal hard mask.

Examples of the metal hard mask include a metal hard mask containing one or more kinds of substances among Cu, Co, W, AlOₓ, AlN, AlOₓN_{y}, WOₓ, Ti, TiN, ZrOₓ, HfOₓ, and TaOₓ (x represents a number of 1 to 3, and y represents a number of 1 or 2).

It is preferable that the metal hard mask contain one or more kinds of substances among Cu, Co, W, AlOₓ, AlN, AlOₓN_{y}, WOₓ, Ti, TiN, ZrOₓ, HfOₓ, and TaOₓ. The content of one or more kinds of such substances with respect to the total mass of the metal hard mask is preferably 30% to 100% by mass, more preferably 60% to 100% by mass, and even more preferably 95% to 100% by mass.

The forms of SiGe and/or other materials that the object to be treated contains are not particularly limited. For example, SiGe and/or other materials may be in the form of a film, wiring line, or particles.

In a case where SiGe and/or other materials are in the form of a film, the thickness thereof is not particularly limited and may be appropriately selected depending on the use. For example, the thickness is 1 to 50 nm.

SiGe and/or other materials may be disposed only on one of the main surfaces of the substrate, or may be disposed on both the main surfaces of the substrate. Furthermore, SiGe and/or other materials may be disposed on the entire main surface of the substrate, or may be disposed on a portion of the main surface of the substrate.

The object to be treated may contain various layers and/or structures as desired, in addition to SiGe and/or other materials. For example, the substrate may have metal wiring, a gate electrode, a source electrode, a drain electrode, an insulating layer, a ferromagnetic layer, and/or a non-magnetic layer, and the like.

The substrate may include the structure of an exposed integrated circuit, for example, an interconnection mechanism such as metal wiring and a dielectric material. Examples of metals and alloys used for the interconnection mechanism include aluminum, a copper-aluminum alloy, copper, titanium, tantalum, cobalt, silicon, titanium nitride, tantalum nitride, and tungsten. The substrate may include a layer of silicon oxide, silicon nitride, silicon carbide, and/or carbon-doped silicon oxide.

The method for manufacturing the object to be treated is not particularly limited. For example, the object to be treated shown in FIG. 2 may be manufactured by a method of forming an insulating film on a substrate, disposing SiGe and the like on the insulating film by a sputtering method, a chemical vapor deposition (CVD) method, a molecular beam epitaxy (MBE) method, or the like, and then performing a smoothing treatment such as CMP.

<Treatment Method>

Examples of the method for treating an object to be treated according to an embodiment of the present invention include a method of bringing an object to be treated containing at least SiGe into contact with the treatment liquid described above so that SiGe is dissolved.

The method of bringing the object to be treated into contact with the treatment liquid is not particularly limited, and examples thereof include a method of immersing the object to be treated in the treatment liquid stored in a tank, a method of spraying the treatment liquid onto the object to be treated, a method of causing the treatment liquid to flow on the object to be treated, and a combined method consisting of any of the above methods. Among these, the method of immersing the object to be treated in the treatment liquid is preferable.

In order to further enhance the washing ability of the treatment liquid, a mechanical stirring method may also be used.

Examples of the mechanical stirring method include a method of circulating the treatment liquid on an object to be treated, a method of causing the treatment liquid to flow on the object to be treated or spraying the treatment liquid onto the object to be treated, and a method of stirring the treatment liquid by using ultrasonic or megasonic waves.

The contact time between the object to be treated and the treatment liquid can be adjusted as appropriate.

The treatment time (the contact time between the treatment liquid and the object to be treated) is not particularly limited, but is preferably 0.25 to 20 minutes, and more preferably 0.5 to 15 minutes.

The temperature of the treatment liquid during the treatment is not particularly limited, but is preferably 20° C. to 75° C. and more preferably 20° C. to 60° C.

By the present treatment performed as above, mainly SiGe in the object to be treated is dissolved.

The dissolution rate of SiGe is, for example, preferably 10 Å/min or more, more preferably 40 to 300 Å/min, even more preferably 50 to 200 Å/min, and particularly preferably 70 to 150 Å/min.

In a case where the object to be treated contains other materials (for example, silicon) in addition to SiGe, the other materials may or may not be dissolved together with SiGe by the present treatment. In a case where the other materials are dissolved, the dissolution of the other materials may be intentional or inevitable.

In a case where the dissolution of the other materials is unintentional, it is preferable that the amount of the inevitably dissolved other materials be small.

A substance that inevitably dissolves a material in a small amount even though the dissolution is not intended is also described as a substance to which the material has excellent resistance as a member.

For example, the treatment liquid is preferably a substance to which silicon as has excellent resistance as a member.

In the present treatment, the dissolution rate of silicon is preferably less than 10 Å/min, more preferably 0.01 to 5 Å/min, even more preferably 0.01 to 1 Å/min, and particularly preferably 0.01 to 0.5 Å/min.

In the present treatment method, SiGe contained in the object to be treated may be partially or totally dissolved.

The object 200 to be treated shown in FIG. 3 is a form of the object 200 to be treated shown in FIG. 2 that has been treated by the present treatment method.

In the object 200 to be treated shown in FIG. 3, other materials 206 are materials (such as silicon) that are not intended to dissolve, and SiGe 204 is partially dissolved from lateral surfaces thereof and forms recess portions.

In the object 200 to be treated having the configuration shown in FIG. 2, in a case where the other materials 206 are materials that are not intended to be dissolved, and SiGe 204 is to be totally dissolved by the present treatment method, it is also preferable that the other materials 206 be supported by other materials which are not shown in the drawing.

As necessary, the present treatment method may include a rinsing step of performing a rinsing treatment on the object to be treated by using a rinsing liquid.

For example, a rinsing step may be additionally performed after the object to be treated is brought into contact with the treatment liquid.

As the rinsing liquid, for example, water, hydrofluoric acid (preferably 0.001% to 1% by mass hydrofluoric acid), hydrochloric acid (preferably 0.001% to 1% by mass hydrochloric acid), hydrogen peroxide water (preferably 0.5% to 31% by mass hydrogen peroxide water, and more preferably 3% to 15% by mass hydrogen peroxide water), a mixed solution of hydrofluoric acid and hydrogen peroxide water (FPM), a mixed solution of sulfuric acid and hydrogen peroxide water (SPM), a mixed solution of aqueous ammonia and hydrogen peroxide water (APM), a mixed solution of hydrochloric acid and hydrogen peroxide water (HPM), aqueous carbon dioxide (preferably 10 to 60 ppm by mass aqueous carbon dioxide), aqueous ozone (preferably 10 to 60 ppm by mass aqueous ozone), aqueous hydrogen (preferably 10 to 20 ppm by mass aqueous hydrogen), an aqueous citric acid solution (preferably a 0.01% to 10% by mass aqueous citric acid solution), sulfuric acid (preferably a 1% to 10% by mass aqueous sulfuric acid solution), aqueous ammonia (preferably 0.01% to 10% by mass aqueous ammonia), isopropyl alcohol (IPA), an aqueous hypochlorous acid solution (preferably a 1% to 10% by mass aqueous hypochlorous acid solution), aqua regia (preferably aqua regia obtained by mixing together “37% by mass hydrochloric acid:60% by mass nitric acid” at a volume ratio of “2.6:1.4” to “3.4:0.6”), ultrapure water, nitric acid (preferably 0.001% to 1% by mass nitric acid), perchloric acid (preferably 0.001% to 1% by mass perchloric acid), an aqueous oxalic acid solution (preferably a 0.01% to 10% by mass aqueous oxalic acid solution), acetic acid (preferably a 0.01% to 10% by mass aqueous acetic acid solution or an undiluted acetic acid solution), or an aqueous periodic acid solution (preferably a 0.5% to 10% by mass aqueous periodic acid solution, examples of the periodic acid include orthoperiodic acid and metaperiodic acid) is preferable.

The composition of APM is, for example, preferably in a range of “aqueous ammonia:hydrogen peroxide water:water=1:1:1” to “aqueous ammonia:hydrogen peroxide water:water=1:3:45” (mass ratio).

The composition of FPM is, for example, preferably in a range of “hydrofluoric acid:hydrogen peroxide water:water=1:1:1” to “hydrofluoric acid:hydrogen peroxide water:water=1:1:200” (mass ratio).

The composition of SPM is, for example, preferably in a range of “sulfuric acid:hydrogen peroxide water:water=3:1:0” to “sulfuric acid:hydrogen peroxide water:water=1:1:10” (mass ratio).

The composition of HPM is, for example, preferably in a range of “hydrochloric acid:hydrogen peroxide water:water=1:1:1” to “hydrochloric acid:hydrogen peroxide water:water=1:1:30” (mass ratio).

The preferred compositional ratio described above means a compositional ratio determined in a case where the content of aqueous ammonia is 28% by mass, the content of hydrofluoric acid is 49% by mass, the content of sulfuric acid is 98% by mass, the content of hydrochloric acid is 37% by mass, and the content of hydrogen peroxide water is 30% by mass.

Furthermore, the volume ratio is based on a volume at room temperature.

“A:B:C=x:y:z to A:B:C=X:Y:Z” used above to describe a suitable range means that it is preferable that at least one (preferably two and more preferably all) of “A:B=x:y to A:B=X:Y”, “B:C=y:z to B:C=Y:Z”, or “A:C=x:z to A:C=X:Z” be satisfied.

The hydrofluoric acid, nitric acid, perchloric acid, and hydrochloric acid mean aqueous solutions obtained by dissolving HF, HNO₃, HClO₄, and HCl in water respectively.

The aqueous ozone, aqueous carbon dioxide, and aqueous hydrogen mean aqueous solutions obtained by dissolving O₃, CO₂, and H₂ in water respectively.

As long as the purpose of the rinsing step is not impaired, these rinsing liquids may be used by being mixed together.

The rinsing liquid may also contain an organic solvent.

Examples of the specific method of the rinsing step include a method of bringing the rinsing liquid into contact with the object to be treated.

The method of bringing the rinsing liquid into contact with the object to be treated is performed by a method of immersing the substrate in the rinsing liquid stored in a tank, a method of spraying the rinsing liquid onto the substrate, a method of causing the rinsing liquid to flow on the substrate, or a combined method consisting of any of the above methods.

The treatment time (contact time between the rinsing liquid and the object to be treated) is not particularly limited, but is 5 seconds to 5 minutes for example.

The temperature of the rinsing liquid during the treatment is not particularly limited. Generally, the temperature of the rinsing liquid is, for example, preferably 16° C. to 60° C., and more preferably 18° C. to 40° C. In a case where SPM is used as the rinsing liquid, the temperature thereof is preferably 90° C. to 250° C.

As necessary, the present treatment method may include a drying step of performing a drying treatment after the rinsing step. The method of the drying treatment is not particularly limited, and examples thereof include spin drying, causing a drying gas to flow on the substrate, heating the substrate by a heating unit such as a hot plate or an infrared lamp, isopropyl alcohol (IPA) vapor drying, Marangoni drying, Rotagoni drying, and any combination of these.

The drying time varies with the specific method to be used, but is about 30 seconds to a few minutes in general.

The present treatment method may be used for washing an object to be treated.

More specifically, for example, by being applied to an object to be treated which is a substrate having undergone etching, the treatment liquid may be used for washing for removing dry etching residues on the substrate.

At this time, the dry etching residues may or may not contain SiGe.

Furthermore, the object to be treated may or may not contain SiGe in a form other than the dry etching residues.

Examples of the washing treatment method of applying the treatment liquid to an object to be treated for washing described above include a method of bringing the object to be treated into contact with the treatment liquid. Specifically, the washing treatment method may be the same as the method of bringing an object to be treated into contact with the treatment liquid that is described above regarding the aforementioned method of dissolving SiGe.

After the washing treatment, either or both of the rinsing step and the drying treatment may be performed which are described above regarding the aforementioned method of dissolving SiGe.

In addition, the washing treatment may be performed simultaneously with the aforementioned method of dissolving SiGe.

The treatment method using the treatment liquid may be performed in combination with a semiconductor device manufacturing method, before or after the steps performed in the manufacturing method. While being performed, the present treatment method may be incorporated into those other steps. Alternatively, while those other steps are being performed, the present treatment method may be incorporated into the steps and performed.

Examples of those other steps include a step of forming each structure such as metal wiring, a gate structure, a source structure, a drain structure, an insulating layer, a ferromagnetic layer and/or a non-magnetic layer (layer formation, etching, chemical mechanical polishing, modification, and the like), a step of forming resist, an exposure step and a removing step, a heat treatment step, a washing step, an inspection step, and the like.

The present treatment method may be performed in the back end process (BEOL: back end of the line) or in the front end process (FEOL: front end of the line).

In addition, the treatment liquid may be applied, for example, to NAND, dynamic random access memory (DRAM), static random access memory (SRAM), resistive random access memory (ReRAM), ferroelectric random access memory (FRAM (registered trademark)), magnetoresistive random access memory (MRAM), phase change random access memory (PRAM), or the like, or applied to a logic circuit, a processor, or the like.

### EXAMPLES

Hereinafter, the present invention will be more specifically described based on examples. The materials, the amounts and ratios of the materials used, the details of treatments, the procedures of treatments, and the like shown in the following examples can be appropriately changed as long as the gist of the present invention is maintained. Therefore, the scope of the present invention is not limited to the following examples.

[Preparation of Treatment Liquid]

The compounds (a fluoride ion source, an oxidant, an additive, and an organic solvent) and water shown in the following tables were mixed together so that the content of each compound conformed to the values shown in the tables, thereby preparing treatment liquids to be used in each test.

In the treatment liquid, all the components (remainders) other than the above compounds are water.

Unless otherwise specified, each polymer used as an additive contains only a representative repeating unit configuring the polymer of the name in the tables. For example, polyvinyl alcohol used in examples contains only a repeating unit represented by —CH₂—CH(OH)—. In addition, the phenolsulfonic acid formaldehyde condensate used in examples contains only a repeating unit formed by the condensation of phenolsulfonic acid and formaldehyde.

As each raw material, a semiconductor grade high-purity raw material was used. As necessary, a purification treatment was additionally performed on the raw material.

[Test X]

<Test and Evaluation>

A substrate on which silicon-germanium (Si:Ge=75:25 (element ratio)) was laminated at a film thickness of 100 nm and a substrate on which polysilicon was laminated at a film thickness of 100 nm were prepared. Each of these substrates was cut in a size of 2×2 cm, thereby obtaining test pieces.

Each test piece was immersed in the treatment liquid (25° C.) of each of examples and comparative examples for 10 minutes.

The film thickness of each of the films (the silicon-germanium film and the polysilicon film) before and after immersion was measured with an optical film thickness meter Ellipsometer M-2000 (manufactured by J.A. Woollam), and the dissolution rate (Å/min) was calculated. The higher the dissolving ability for silicon-germanium, the more preferable. The lower the dissolving ability for polysilicon, the more preferable.

Furthermore, the surface of the silicon-germanium film after immersion was observed using an atomic force microscope (AFM Division Icon, manufactured by Bruker) to determine the surface roughness Ra, and the surface roughness of the silicon-germanium film after treatment was evaluated.

The evaluation standard is shown below.

In any of the evaluations, the closer the grade is to A, the better the evaluation result.

(SiGe ER (dissolution rate for silicon-germanium))

A: 70 Å/min or more

B: 50 Å/min or more and less than 70 Å/min

C: 40 Å/min or more and less than 50 Å/min

D: 10 Å/min or more and less than 40 Å/min

E: less than 10 Å/min

(Si ER (dissolution rate for polysilicon))

A: less than 0.5 Å/min

B: 0.5 Å/min or more and less than 1 Å/min

C: 1 Å/min or more and less than 5 Å/min

D: 5 Å/min or more

(SiGe surface roughness (surface roughness of silicon-germanium film after treatment))

A: Ra (surface roughness) is 0.30 nm or less.

B: Ra is more than 0.30 nm and 0.40 nm or less.

C: Ra is more than 0.40 nm and 0.60 nm or less.

D: Ra is more than 0.60 nm and 1.00 nm or less.

E: Ra is more than 1.00 nm.

<Result>

Table 1 shows the formulation of the treatment liquids used in the series of test X and the test results.

In Table 1, the column of “Amount (%)” shows the content (% by mass) of each component with respect to the total amount of treatment liquid.

NH4F in the column of “Fluoride ion source” means NH₄F (ammonium fluoride).

TABLE 1

| | Fluoride | | | | | | | | | | |
|---|---|---|---|---|---|---|---|---|---|---|---|
| | ion source | | Oxidant | | Additive | | Organic solvent | | | | SiGe |
| | | Amount | | Amount | | Amount | | Amount | SiGe | Si | Surface |
| | Type | (%) | Type | (%) | Type | (%) | Type | (%) | ER | ER | roughness |
| Example 1 | HF | 0.5 | Peracetic acid | 8 | Polyvinyl alcohol | 0.5 | — | | B | C | D |
| Example 2 | HF | 0.5 | Peracetic acid | 8 | Polystyrene sulfonic acid | 0.5 | — | | B | C | D |
| Example 3 | HF | 0.5 | Peracetic acid | 8 | Polyvinylpyrrolidone | 0.5 | — | | B | C | D |
| Example 4 | HF | 0.5 | Peracetic acid | 8 | Polyallylamine | 0.5 | — | | B | C | D |
| Example 5 | HF | 0.5 | Peracetic acid | 8 | Polyvinylamine | 0.5 | — | | B | C | D |
| Example 6 | HF | 0.5 | Peracetic acid | 8 | Polyacrylamide | 0.5 | — | | B | C | D |
| Example 7 | HF | 0.5 | Peracetic acid | 8 | Dimethylamine epihalohydrin copolymer | 0.5 | — | | B | C | D |
| Example 8 | HF | 0.5 | Peracetic acid | 8 | Hexadimethrine chloride | 0.5 | — | | B | C | D |
| Example 9 | HF | 0.5 | Peracetic acid | 8 | Polydiallylamine | 0.5 | — | | B | C | D |
| Example 10 | HF | 0.5 | Peracetic acid | 8 | Polydimethyldiallylammonium chloride | 0.5 | — | | B | C | D |
| Example 11 | HF | 0.5 | Peracetic acid | 8 | Poly(4-vinylpyridine) | 0.5 | — | | B | C | D |
| Example 12 | HF | 0.5 | Peracetic acid | 8 | Polyornithine | 0.5 | — | | B | C | D |
| Example 13 | HF | 0.5 | Peracetic acid | 8 | Polylysine | 0.5 | — | | B | C | D |
| Example 14 | HF | 0.5 | Peracetic acid | 8 | Polyarginine | 0.5 | — | | B | C | D |
| Example 15 | HF | 0.5 | Peracetic acid | 8 | Polyhistidine | 0.5 | — | | B | C | D |
| Example 16 | HF | 0.5 | Peracetic acid | 8 | Polyvinylimidazole | 0.5 | — | | B | C | D |
| Example 17 | HF | 0.5 | Peracetic acid | 8 | Polymethyldiallylamine | 0.5 | — | | B | C | D |
| Example 18 | HF | 0.5 | Peracetic acid | 8 | Cetyltrimethylammonium chloride | 0.5 | — | | B | C | D |
| Example 19 | HF | 0.5 | Peracetic acid | 8 | Stearyltrimethylammonium bromide | 0.5 | — | | B | C | D |
| Example 20 | HF | 0.5 | Peracetic acid | 8 | Polyoxyethylene lauryl amine | 0.5 | — | | B | C | D |
| Example 21 | HF | 0.5 | Peracetic acid | 8 | Propyl naphthalenesulfonic acid | 0.5 | — | | B | C | D |
| Example 22 | HF | 0.5 | Peracetic acid | 8 | Triisopropyl naphthalenesulfonic acid | 0.5 | — | | B | C | D |
| Example 23 | HF | 0.5 | Peracetic acid | 8 | Dibutyl naphthalenesulfonic acid | 0.5 | — | | B | C | D |
| Example 24 | HF | 0.5 | Peracetic acid | 8 | Dodecyl diphenyl ether disulfonic acid | 0.5 | — | | A | C | D |
| Example 25 | HF | 0.5 | Peracetic acid | 8 | Phenolsulfonic acid formaldehyde | 0.5 | — | | A | C | D |
| | | | | | condensate | | | | | | |
| Example 26 | HF | 0.5 | Peracetic acid | 8 | Phenyl phenolsulfonic acid formaldehyde | 0.5 | — | | B | C | D |
| | | | | | condensate | | | | | | |
| Example 27 | HF | 0.5 | Peracetic acid | 8 | polyoxyethylene lauryl ether sulfonic acid | 0.5 | — | | B | C | D |
| Example 28 | HF | 0.5 | Peracetic acid | 8 | Polyoxyethylene oleyl ether sulfonic acid | 0.5 | — | | B | C | D |
| Example 29 | HF | 0.5 | Peracetic acid | 8 | Polyoxyethylene octyl dodecyl ether | 0.5 | — | | B | C | D |
| | | | | | sulfonic acid | | | | | | |
| Example 30 | HF | 0.5 | Peracetic acid | 8 | Polyoxyethylene lauryl ether carboxylic | 0.5 | — | | B | C | D |
| | | | | | acid | | | | | | |

TABLE 2

| | Fluoride | | | | | | | | | | |
|---|---|---|---|---|---|---|---|---|---|---|---|
| | ion source | | Oxidant | | Additive | | Organic solvent | | | | SiGe |
| | | Amount | | Amount | | Amount | | Amount | SiGe | Si | Surface |
| | Type | (%) | Type | (%) | Type | (%) | Type | (%) | ER | ER | roughness |
| Example 31 | HF | 0.5 | Peracetic acid | 8 | Polyoxyethylene dodecyl ether carboxylic | 0.5 | — | | B | C | D |
| | | | | | acid | | | | | | |
| Example 32 | HF | 0.5 | Peracetic acid | 8 | Polyoxyethylene tridecyl ether carboxylic | 0.5 | — | | B | C | D |
| | | | | | acid | | | | | | |
| Example 33 | HF | 0.5 | Peracetic acid | 8 | Polyoxyethylene alkyl phenyl ether | 0.5 | — | | B | C | D |
| | | | | | phosphoric acid | | | | | | |
| Example 34 | HF | 0.5 | Peracetic acid | 8 | Polyoxyethylene lauryl ether phosphoric | 0.5 | — | | B | C | D |
| | | | | | acid | | | | | | |
| Example 35 | HF | 0.5 | Peracetic acid | 8 | Lauryl dimethylaminoacetic acid betaine | 0.5 | — | | C | C | D |
| Example 36 | HF | 0.5 | Peracetic acid | 8 | Lauryldimethylamine oxide | 0.5 | — | | C | C | D |
| Example 37 | HF | 0.5 | Peracetic acid | 8 | Tetraethoxysilane | 1 | — | | C | C | D |
| Example 38 | HF | 0.5 | Peracetic acid | 8 | Methyltrimethoxysilane | 1 | — | | C | C | D |
| Example 39 | HF | 0.5 | Peracetic acid | 8 | Dimethyldimethoxysilane | 1 | — | | C | C | D |
| Example 40 | HF | 0.5 | Peracetic acid | 8 | Phenyltrimethoxysilane | 1 | — | | C | C | D |
| Example 41 | HF | 0.5 | Peracetic acid | 8 | Methyltriethoxysilane | 1 | — | | C | C | D |
| Example 42 | HF | 0.5 | Peracetic acid | 8 | Dimethyldiethoxysilane | 1 | — | | C | C | D |
| Example 43 | HF | 0.5 | Peracetic acid | 8 | Phenyltriethoxysilane | 1 | — | | C | C | D |
| Example 44 | HF | 0.5 | Peracetic acid | 8 | n-Propyltrimethoxysilane | 1 | — | | C | C | D |
| Example 45 | HF | 0.5 | Peracetic acid | 8 | n-Propyltriethoxysilane | 1 | — | | C | C | D |
| Example 46 | HF | 0.5 | Peracetic acid | 8 | Hexyltrimethoxysilane | 1 | — | | C | C | D |
| Example 47 | HF | 0.5 | Peracetic acid | 8 | Hexyltriethoxysilane | 1 | — | | C | C | D |
| Example 48 | HF | 0.5 | Peracetic acid | 8 | Octyltriethoxysilane | 1 | — | | C | C | D |
| Example 49 | HF | 0.5 | Peracetic acid | 8 | 1,6-Bis(trimethoxysilyl)hexane | 1 | — | | C | C | D |
| Example 50 | HF | 0.5 | Peracetic acid | 8 | Trifluoropropyltrimethoxysilane | 1 | — | | C | C | D |
| Example 51 | HF | 0.5 | Peracetic acid | 8 | t-Butylmethoxydimethylsilane | 1 | — | | C | C | D |
| Example 52 | HF | 0.5 | Peracetic acid | 8 | 3-Cyanopropyldimethylmethoxysilane | 1 | — | | C | C | D |
| Example 53 | HF | 0.5 | Peracetic acid | 8 | Ethoxy(trimethyl)silane | 1 | — | | C | C | D |
| Example 54 | HF | 0.5 | Peracetic acid | 8 | methoxytrimethylsilane | 1 | — | | C | C | D |
| Example 55 | HF | 0.5 | Peracetic acid | 8 | Hexyl(dimethoxy)silane | 1 | — | | C | C | D |
| Example 56 | HF | 0.5 | Peracetic acid | 8 | Methyldiethoxysilane | 1 | — | | C | C | D |
| Example 57 | HF | 0.5 | Peracetic acid | 8 | Triethoxysilane | 1 | — | | C | C | D |
| Example 58 | HF | 0.5 | Peracetic acid | 8 | 3-Aminopropyldimethylethoxysilane | 1 | — | | C | C | D |
| Example 59 | HF | 0.5 | Peracetic acid | 8 | 3-(2-Aminoethoxyamino)propyl- | 1 | — | | C | C | D |
| | | | | | trimethoxysilane | | | | | | |
| Example 60 | HF | 0.5 | Peracetic acid | 8 | Trimethylsilanol | 1 | — | | C | C | D |

TABLE 3

| | Fluoride | | | | | | | | | | |
|---|---|---|---|---|---|---|---|---|---|---|---|
| | ion source | | Oxidant | | Additive | | Organic solvent | | | | SiGe |
| | | Amount | | Amount | | Amount | | Amount | SiGe | Si | Surface |
| | Type | (%) | Type | (%) | Type | (%) | Type | (%) | ER | ER | roughness |
| Example 61 | HF | 0.5 | Peracetic acid | 8 | Dimethylsilanediol | 1 | — | | C | C | D |
| Example 62 | HF | 0.5 | Peracetic acid | 8 | Diphenylsilanediol | 1 | — | | C | C | D |
| Example 63 | HF | 0.5 | Peracetic acid | 8 | Silanetriol | 1 | — | | C | C | D |
| Example 64 | HF | 0.5 | Peracetic acid | 8 | 3-Aminopropylsilanetriol | 1 | — | | C | C | D |
| Example 65 | HF | 0.5 | Peracetic acid | 8 | Methylsilanetriol | 1 | — | | C | C | D |
| Example 66 | HF | 0.5 | Peracetic acid | 8 | 2-Methyl-2-propylsilanetriol | 1 | — | | C | C | D |
| Example 67 | HF | 0.5 | Peracetic acid | 8 | Methyl acetate silanetriol | 1 | — | | C | C | D |
| Example 68 | HF | 0.5 | Peracetic acid | 8 | 2-(Chloroethyl)acetate silanetriol | 1 | — | | C | C | D |
| Example 69 | HF | 0.5 | Peracetic acid | 8 | 3-(Hydroxypropyl)silanetriol | 1 | — | | C | C | D |
| Example 70 | HF | 0.5 | Peracetic acid | 8 | Di(ethylaldoxime)silane | 1 | — | | C | C | D |
| Example 71 | HF | 0.5 | Peracetic acid | 8 | Mono(ethylaldoxime)silane | 1 | — | | C | C | D |
| Example 72 | HF | 0.5 | Peracetic acid | 8 | Tris(ethylaldoxime)silane | 1 | — | | C | C | D |
| Example 73 | HF | 0.5 | Peracetic acid | 8 | Tetra(ethylaldoxime)silane | 1 | — | | C | C | D |
| Example 74 | HF | 0.5 | Peracetic acid | 8 | Methyltris(methylethylketoxime)silane | 1 | — | | C | C | D |
| Example 75 | HF | 0.5 | Peracetic acid | 8 | Methyltosyl(acetoxime)silane | 1 | — | | C | C | D |
| Example 76 | HF | 0.5 | Peracetic acid | 8 | Methyltris(methylisobutylketoxime)silane | 1 | — | | C | C | D |
| Example 77 | HF | 0.5 | Peracetic acid | 8 | Dimethyldi(methylethylketoxime)silane | 1 | — | | C | C | D |
| Example 78 | HF | 0.5 | Peracetic acid | 8 | Trimethyl(methylethylketoxime)silane | 1 | — | | C | C | D |
| Example 79 | HF | 0.5 | Peracetic acid | 8 | Tetra(methylethylketoxime)silane | 1 | — | | C | C | D |
| Example 80 | HF | 0.5 | Peracetic acid | 8 | Tetra(methylisobutylketoxime)silane | 1 | — | | C | C | D |
| Example 81 | HF | 0.5 | Peracetic acid | 8 | Vinyltris(methylethylketoxime)silane | 1 | — | | C | C | D |
| Example 82 | HF | 0.5 | Peracetic acid | 8 | Methylvinyldi(methylethylketoxime)silane | 1 | — | | C | C | D |
| Example 83 | HF | 0.5 | Peracetic acid | 8 | Methylvinyldi(cyclohexanonexime)silane | 1 | — | | C | C | D |
| Example 84 | HF | 0.5 | Peracetic acid | 8 | Vinyltris(methylisobutylketoxime)silane | 1 | — | | C | C | D |
| Example 85 | HF | 0.5 | Peracetic acid | 8 | Phenyltris(methylethylketoxime)silane | 1 | — | | C | C | D |
| Example 86 | HF | 0.5 | Peracetic acid | 8 | Hexamethyldisilazane | 1 | — | | C | C | D |
| Example 87 | HF | 0.5 | Peracetic acid | 8 | Hexamethyldisiloxane | 1 | — | | C | C | D |
| Example 88 | HF | 0.5 | Peracetic acid | 8 | Octamethylcyclotetrasiloxane | 1 | — | | C | C | D |
| Example 89 | HF | 0.5 | Peracetic acid | 8 | Decamethylcyclopentasiloxane | 1 | — | | C | C | D |
| Example 90 | HF | 0.5 | Peracetic acid | 8 | Dodecamethylcyclohexasiloxane | 1 | — | | C | C | D |

TABLE 4

| | Fluoride | | | | | | | | | | |
|---|---|---|---|---|---|---|---|---|---|---|---|
| | ion source | | Oxidant | | Additive | | Organic solvent | | | | SiGe |
| | | Amount | | Amount | | Amount | | Amount | SiGe | Si | Surface |
| | Type | (%) | Type | (%) | Type | (%) | Type | (%) | ER | ER | roughness |
| Example 91 | HF | 0.5 | Peracetic acid | 8 | Ethylenediamine | 1 | — | | B | C | D |
| Example 92 | HF | 0.5 | Peracetic acid | 8 | Diethylenetriamine | 1 | — | | B | C | D |
| Example 93 | HF | 0.5 | Peracetic acid | 8 | Triethylenetetramine | 1 | — | | B | C | D |
| Example 94 | HF | 0.5 | Peracetic acid | 8 | Tetraethylenepentamine | 1 | — | | B | C | D |
| Example 95 | HF | 0.5 | Peracetic acid | 8 | Pentaethylenehexamine | 1 | — | | B | C | D |
| Example 96 | HF | 0.5 | Peracetic acid | 8 | Tetramethylethylenediamine | 1 | — | | B | C | D |
| Example 97 | HF | 0.5 | Peracetic acid | 8 | Hexamethylenediamine | 1 | — | | B | C | D |
| Example 98 | HF | 0.5 | Peracetic acid | 8 | Methylamine | 1 | — | | B | C | D |
| Example 99 | HF | 0.5 | Peracetic acid | 8 | Dimethylamine | 1 | — | | B | C | D |
| Example 100 | HF | 0.5 | Peracetic acid | 8 | Trimethylamine | 1 | — | | B | C | D |
| Example 101 | HF | 0.5 | Peracetic acid | 8 | Ethylamine | 1 | — | | B | C | D |
| Example 102 | HF | 0.5 | Peracetic acid | 8 | Diethylamine | 1 | — | | B | C | D |
| Example 103 | HF | 0.5 | Peracetic acid | 8 | Triethylamine | 1 | — | | B | C | D |
| Example 104 | HF | 0.5 | Peracetic acid | 8 | 2-Ethylhexylamine | 1 | — | | B | C | D |
| Example 105 | HF | 0.5 | Peracetic acid | 8 | Stearylamine | 1 | — | | B | C | D |
| Example 106 | HF | 0.5 | Peracetic acid | 8 | Cyclohexylamine | 1 | — | | B | C | D |
| Example 107 | HF | 0.5 | Peracetic acid | 8 | Aniline | 1 | — | | B | C | D |
| Example 108 | HF | 0.5 | Peracetic acid | 8 | Phenethylamine | 1 | — | | B | C | D |
| Example 109 | HF | 0.5 | Peracetic acid | 8 | Toluidine | 1 | — | | B | C | D |
| Example 110 | HF | 0.5 | Peracetic acid | 8 | m-Xylylenediamine | 1 | — | | B | C | D |
| Example 111 | HF | 0.5 | Peracetic acid | 8 | Pyrrolidine | 1 | — | | B | C | D |
| Example 112 | HF | 0.5 | Peracetic acid | 8 | Piperidine | 1 | — | | B | C | D |
| Example 113 | HF | 0.5 | Peracetic acid | 8 | Piperazine | 1 | — | | B | C | D |
| Example 114 | HF | 0.5 | Peracetic acid | 8 | Morpholine | 1 | — | | B | C | D |
| Example 115 | HF | 0.5 | Peracetic acid | 8 | Pyrrole | 1 | — | | B | C | D |
| Example 116 | HF | 0.5 | Peracetic acid | 8 | Pyrazole | 1 | — | | B | C | D |
| Example 117 | HF | 0.5 | Peracetic acid | 8 | Imidazole | 1 | — | | B | C | D |
| Example 118 | HF | 0.5 | Peracetic acid | 8 | Pyridine | 1 | — | | B | C | D |
| Example 119 | HF | 0.5 | Peracetic acid | 8 | Pyrimidine | 1 | — | | B | C | D |
| Example 120 | HF | 0.5 | Peracetic acid | 8 | Pyrazine | 1 | — | | B | C | C |

TABLE 5

| | Fluoride | | | | | | | | | | |
|---|---|---|---|---|---|---|---|---|---|---|---|
| | ion source | | Oxidant | | Additive | | Organic solvent | | | | SiGe |
| | | Amount | | Amount | | Amount | | Amount | SiGe | Si | Surface |
| | Type | (%) | Type | (%) | Type | (%) | Type | (%) | ER | ER | roughness |
| Example 121 | HF | 0.5 | Peracetic acid | 8 | Oxazole | 1 | — | | B | C | D |
| Example 122 | HF | 0.5 | Peracetic acid | 8 | Thiazole | 1 | — | | B | C | D |
| Example 123 | HF | 0.5 | Peracetic acid | 8 | 4-Dimethylaminopyridine | 1 | — | | B | C | D |
| Example 124 | HF | 0.5 | Peracetic acid | 8 | Laurylpyridinium chloride | 1 | — | | B | C | D |
| Example 125 | HF | 0.5 | Peracetic acid | 8 | Alanine | 1 | — | | C | C | D |
| Example 126 | HF | 0.5 | Peracetic acid | 8 | Arginine | 1 | — | | C | C | D |
| Example 127 | HF | 0.5 | Peracetic acid | 8 | Asparagine | 1 | — | | C | C | D |
| Example 128 | HF | 0.5 | Peracetic acid | 8 | Aspartic acid | 1 | — | | C | C | D |
| Example 129 | HF | 0.5 | Peracetic acid | 8 | Glutamine | 1 | — | | C | C | D |
| Example 130 | HF | 0.5 | Peracetic acid | 8 | Glutamic acid | 1 | — | | C | C | D |
| Example 131 | HF | 0.5 | Peracetic acid | 8 | Glycine | 1 | — | | C | C | D |
| Example 132 | HF | 0.5 | Peracetic acid | 8 | Histidine | 1 | — | | C | C | D |
| Example 133 | HF | 0.5 | Peracetic acid | 8 | Isoleucine | 1 | — | | C | C | D |
| Example 134 | HF | 0.5 | Peracetic acid | 8 | Leucine | 1 | — | | C | C | D |
| Example 135 | HF | 0.5 | Peracetic acid | 8 | Lysine | 1 | — | | C | C | D |
| Example 136 | HF | 0.5 | Peracetic acid | 8 | Methionine | 1 | — | | C | C | D |
| Example 137 | HF | 0.5 | Peracetic acid | 8 | Phenylalanine | 1 | — | | C | C | D |
| Example 138 | HF | 0.5 | Peracetic acid | 8 | Proline | 1 | — | | C | C | D |
| Example 139 | HF | 0.5 | Peracetic acid | 8 | Serine | 1 | — | | C | C | D |
| Example 140 | HF | 0.5 | Peracetic acid | 8 | Threonine | 1 | — | | C | C | D |
| Example 141 | HF | 0.5 | Peracetic acid | 8 | Tryptophan | 1 | — | | C | C | D |
| Example 142 | HF | 0.5 | Peracetic acid | 8 | Tyrosine | 1 | — | | C | C | D |
| Example 143 | HF | 0.5 | Peracetic acid | 8 | Valine | 1 | — | | C | C | D |
| Example 144 | HF | 0.5 | Peracetic acid | 8 | Tetramethylammonium hydroxide | 1 | — | | B | C | D |
| Example 145 | HF | 0.5 | Peracetic acid | 8 | Tetrapropylammonium hydroxide | 1 | — | | B | C | D |
| Example 146 | HF | 0.5 | Peracetic acid | 8 | Tetrabutylammonium hydroxide | 1 | — | | B | C | D |
| Example 147 | HF | 0.5 | Peracetic acid | 8 | Methyltripropylammonium hydroxide | 1 | — | | B | C | D |
| Example 148 | HF | 0.5 | Peracetic acid | 8 | Methyltributylammonium hydroxide | 1 | — | | B | C | D |
| Example 149 | HF | 0.5 | Peracetic acid | 8 | Ethyltrimethylammonium hydroxide | 1 | — | | B | C | D |
| Example 150 | HF | 0.5 | Peracetic acid | 8 | Dimethyldiethylammonium hydroxide | 1 | — | | B | C | D |

TABLE 6

| | Fluoride | | | | |
|---|---|---|---|---|---|
| | ion source | | Oxidant | | |
| | | Amount | | Amount | Additive |
| | Type | (%) | Type | (%) | Type |
| Example 151 | HF | 0.5 | Peracetic acid | 8 | Benzyltrimethylammonium hydroxide |
| Example 152 | HF | 0.5 | Peracetic acid | 8 | (2-Hydroxyethyl)trimethylammonium hydroxide |
| Example 153 | HF | 0.5 | Peracetic acid | 8 | Boric acid |
| Example 154 | HF | 0.5 | Peracetic acid | 8 | Dodecyl diphenyl ether disulfonic acid |
| Example 155 | HF | 0.5 | Peracetic acid | 8 | Dodecyl diphenyl ether disulfonic acid |
| Example 156 | HF | 0.5 | Peracetic acid | 8 | Dodecyl diphenyl ether disulfonic acid |
| Example 157 | HF | 0.5 | Peracetic acid | 8 | Dodecyl diphenyl ether disulfonic acid |
| Example 158 | HF | 0.5 | Peracetic acid | 8 | Dodecyl diphenyl ether disulfonic acid |
| Example 159 | HF | 0.5 | Peracetic acid | 8 | Dodecyl diphenyl ether disulfonic acid |
| Example 160 | HF | 0.5 | Peracetic acid | 8 | Dodecyl diphenyl ether disulfonic acid |
| Example 161 | HF | 0.5 | Peracetic acid | 8 | Dodecyl diphenyl ether disulfonic acid |
| Example 162 | HF | 0.5 | Peracetic acid | 8 | Dodecyl diphenyl ether disulfonic acid |
| Example 163 | HF | 0.5 | Peracetic acid | 8 | Dodecyl diphenyl ether disulfonic acid |
| Example 164 | HF | 0.5 | Peracetic acid | 8 | Dodecyl diphenyl ether disulfonic acid |
| Example 165 | HF | 0.5 | Peracetic acid | 8 | Dodecyl diphenyl ether disulfonic acid |
| Example 166 | HF | 0.5 | Peracetic acid | 8 | Dodecyl diphenyl ether disulfonic acid |
| Example 167 | HF | 0.5 | Peracetic acid | 8 | Dodecyl diphenyl ether disulfonic acid |
| Example 168 | HF | 0.5 | Peracetic acid | 8 | Dodecyl diphenyl ether disulfonic acid |
| Example 169 | HF | 0.5 | Peracetic acid | 8 | Dodecyl diphenyl ether disulfonic acid |
| Example 170 | HF | 0.5 | Peracetic acid | 8 | Dodecyl diphenyl ether disulfonic acid |
| Example 171 | HF | 0.5 | Peracetic acid | 8 | Dodecyl diphenyl ether disulfonic acid |
| Example 172 | HF | 0.5 | Peracetic acid | 8 | Dodecyl diphenyl ether disulfonic acid |
| Example 173 | HF | 0.5 | Peracetic acid | 8 | Dodecyl diphenyl ether disulfonic acid |
| Example 174 | HF | 0.5 | Peracetic acid | 8 | Dodecyl diphenyl ether disulfonic acid |
| Example 175 | HF | 0.5 | Peracetic acid | 8 | Dodecyl diphenyl ether disulfonic acid |
| Example 176 | HF | 0.5 | Peracetic acid | 8 | Dodecyl diphenyl ether disulfonic acid |
| Example 177 | HF | 0.5 | Peracetic acid | 8 | Dodecyl diphenyl ether disulfonic acid |
| Example 178 | HF | 0.5 | Peracetic acid | 8 | Dodecyl diphenyl ether disulfonic acid |
| Example 179 | HF | 0.5 | Peracetic acid | 8 | Dodecyl diphenyl ether disulfonic acid |
| Example 180 | HF | 0.5 | Peracetic acid | 8 | Dodecyl diphenyl ether disulfonic acid |

| | Additive | Organic solvent | | | | SiGe |
|---|---|---|---|---|---|---|
| | Amount | | Amount | SiGe | Si | Surface |
| | (%) | Type | (%) | ER | ER | roughness |
| Example 151 | 1 | — | | B | C | D |
| Example 152 | 1 | — | | B | C | D |
| Example 153 | 1 | — | | B | C | D |
| Example 154 | 0.5 | Ethylene glycol | 30 | A | B | B |
| Example 155 | 0.5 | Propylene glycol | 30 | A | A | A |
| Example 156 | 0.5 | Butyl diglycol | 30 | A | B | B |
| Example 157 | 0.5 | 1,4-Butanediol | 30 | A | B | C |
| Example 158 | 0.5 | Tripropylene glycol methyl ether | 30 | A | B | C |
| Example 159 | 0.5 | Propylene glycol propyl ether | 30 | A | B | C |
| Example 160 | 0.5 | Diethylene glycol n-butyl ether | 30 | A | B | C |
| Example 161 | 0.5 | Hexyloxypropylamine | 30 | A | B | C |
| Example 162 | 0.5 | Poly(oxyethylene)diamine | 30 | A | B | C |
| Example 163 | 0.5 | Dimethyl sulfoxide | 30 | A | B | C |
| Example 164 | 0.5 | Tetrahydrofurfuiyl alcohol | 30 | A | B | C |
| Example 165 | 0.5 | Glycerol | 30 | A | B | C |
| Example 166 | 0.5 | Sulfolane | 30 | A | A | A |
| Example 167 | 0.5 | Ethylene glycol monomethyl ether | 30 | A | B | C |
| Example 168 | 0.5 | Ethylene glycol monoethyl ether | 30 | A | B | C |
| Example 169 | 0.5 | Ethylene glycol monobutyl ether | 30 | A | B | C |
| Example 170 | 0.5 | Ethylene glycol dimethyl ether | 30 | A | B | C |
| Example 171 | 0.5 | Ethylene glycol diethyl ether | 30 | A | B | C |
| Example 172 | 0.5 | Diethylene glycol monomethyl ether | 30 | A | B | C |
| Example 173 | 0.5 | Diethylene glycol monoethyl ether | 30 | A | B | C |
| Example 174 | 0.5 | Diethylene glycol monopropyl ether | 30 | A | B | C |
| Example 175 | 0.5 | Diethylene glycol monoisopropyl ether | 30 | A | B | C |
| Example 176 | 0.5 | Diethylene glycol monoisobutyl ether | 30 | A | B | C |
| Example 177 | 0.5 | Diethylene glycol monobenzyl ether | 30 | A | B | C |
| Example 178 | 0.5 | Diethylene glycol dimethyl ether | 30 | A | B | C |
| Example 179 | 0.5 | Diethylene glycol diethyl ether | 30 | A | B | C |
| Example 180 | 0.5 | Triethylene glycol monomethyl ether | 30 | A | B | C |

TABLE 7

| | Fluoride | | | | |
|---|---|---|---|---|---|
| | ion source | | Oxidant | | |
| | | Amount | | Amount | Additive |
| | Type | (%) | Type | (%) | Type |
| Example 181 | HF | 0.5 | Peracetic acid | 8 | Dodecyl diphenyl ether disulfonic acid |
| Example 182 | HF | 0.5 | Peracetic acid | 8 | Dodecyl diphenyl ether disulfonic acid |
| Example 183 | HF | 0.5 | Peracetic acid | 8 | Dodecyl diphenyl ether disulfonic acid |
| Example 184 | HF | 0.5 | Peracetic acid | 8 | Dodecyl diphenyl ether disulfonic acid |
| Example 185 | HF | 0.5 | Peracetic acid | 8 | Dodecyl diphenyl ether disulfonic acid |
| Example 186 | HF | 0.5 | Peracetic acid | 8 | Dodecyl diphenyl ether disulfonic acid |
| Example 187 | HF | 0.5 | Peracetic acid | 8 | Dodecyl diphenyl ether disulfonic acid |
| Example 188 | HF | 0.5 | Peracetic acid | 8 | Dodecyl diphenyl ether disulfonic acid |
| Example 189 | HF | 0.5 | Peracetic acid | 8 | Dodecyl diphenyl ether disulfonic acid |
| Example 190 | HF | 0.5 | Peracetic acid | 8 | Dodecyl diphenyl ether disulfonic acid |
| Example 191 | HF | 0.5 | Peracetic acid | 8 | Dodecyl diphenyl ether disulfonic acid |
| Example 192 | HF | 0.5 | Peracetic acid | 8 | Dodecyl diphenyl ether disulfonic acid |
| Example 193 | HF | 0.5 | Peracetic acid | 8 | Dodecyl diphenyl ether disulfonic acid |
| Example 194 | HF | 0.5 | Peracetic acid | 8 | Dodecyl diphenyl ether disulfonic acid |
| Example 195 | HF | 0.5 | Peracetic acid | 8 | Dodecyl diphenyl ether disulfonic acid |
| Example 196 | HF | 0.5 | Peracetic acid | 8 | Dodecyl diphenyl ether disulfonic acid |
| Example 197 | HF | 0.5 | Peracetic acid | 8 | Dodecyl diphenyl ether disulfonic acid |
| Example 198 | HF | 0.5 | Peracetic acid | 8 | Dodecyl diphenyl ether disulfonic acid |
| Example 199 | HF | 0.5 | Peracetic acid | 8 | Dodecyl diphenyl ether disulfonic acid |
| Example 200 | HF | 0.5 | Peracetic acid | 8 | Dodecyl diphenyl ether disulfonic acid |
| Example 201 | HF | 0.5 | Peracetic acid | 8 | Phenolsulfonic acid formaldehyde condensate |
| Example 202 | HF | 0.5 | Peracetic acid | 8 | Phenolsulfonic acid formaldehyde condensate |
| Example 203 | HF | 0.5 | Peracetic acid | 8 | Phenolsulfonic acid formaldehyde condensate |
| Example 204 | HF | 0.5 | Peracetic acid | 8 | Phenolsulfonic acid formaldehyde condensate |
| Example 205 | HF | 0.5 | Peracetic acid | 8 | Phenolsulfonic acid formaldehyde condensate |
| Example 206 | HF | 0.5 | Peracetic acid | 8 | Phenolsulfonic acid formaldehyde condensate |
| Example 207 | HF | 0.5 | Peracetic acid | 8 | Phenolsulfonic acid formaldehyde condensate |
| Example 208 | HF | 0.5 | Peracetic acid | 8 | Phenolsulfonic acid formaldehyde condensate |
| Example 209 | HF | 0.5 | Peracetic acid | 8 | Phenolsulfonic acid formaldehyde condensate |
| Example 210 | HF | 0.5 | Peracetic acid | 8 | Phenolsulfonic acid formaldehyde condensate |

| | Additive | Organic solvent | | | | SiGe |
|---|---|---|---|---|---|---|
| | Amount | | Amount | SiGe | Si | Surface |
| | (%) | Type | (%) | ER | ER | roughness |
| Example 181 | 0.5 | Triethylene glycol dimethyl ether | 30 | A | B | C |
| Example 182 | 0.5 | Polyethylene glycol monomethyl ether | 30 | A | B | C |
| Example 183 | 0.5 | Diethylene glycol methyl ethyl ether | 30 | A | B | C |
| Example 184 | 0.5 | Propylene glycol monomethyl ether | 30 | A | B | C |
| Example 185 | 0.5 | Propylene glycol dimethyl ether | 30 | A | B | C |
| Example 186 | 0.5 | Propylene glycol monobutyl ether | 30 | A | B | C |
| Example 187 | 0.5 | Monopropyl ether | 30 | A | B | C |
| Example 188 | 0.5 | Dipropylene glycol monomethyl ether | 30 | A | B | C |
| Example 189 | 0.5 | Dipropylene glycol monoisopropyl ether | 30 | A | B | C |
| Example 190 | 0.5 | Dipropylene glycol monobutyl ether | 30 | A | B | C |
| Example 191 | 0.5 | Dipropylene glycol diisopropyl ether | 30 | A | B | C |
| Example 192 | 0.5 | 1-Methoxy-2-butanol | 30 | A | B | C |
| Example 193 | 0.5 | 2-Methoxy-1-butanol | 30 | A | B | C |
| Example 194 | 0.5 | 2-Methoxy-2-methylbutanol | 30 | A | B | C |
| Example 195 | 0.5 | 1,1-Dimethoxy ethane | 30 | A | B | C |
| Example 196 | 0.5 | 2-(2-Butoxyethoxy)ethanol | 30 | A | B | C |
| Example 197 | 0.5 | Methanol | 30 | A | B | C |
| Example 198 | 0.5 | Ethanol | 30 | A | B | C |
| Example 199 | 0.5 | Isopropanol | 30 | A | B | C |
| Example 200 | 0.5 | 1-Butanol | 30 | A | B | C |
| Example 201 | 0.5 | Ethylene glycol | 30 | A | B | B |
| Example 202 | 0.5 | Propylene glycol | 30 | A | A | A |
| Example 203 | 0.5 | Butyl diglycol | 30 | A | B | B |
| Example 204 | 0.5 | 1,4-Butanediol | 30 | A | B | C |
| Example 205 | 0.5 | Tripropylene glycol methyl ether | 30 | A | B | C |
| Example 206 | 0.5 | Propylene glycol propyl ether | 30 | A | B | C |
| Example 207 | 0.5 | Diethylene glycol n-butyl ether | 30 | A | B | C |
| Example 208 | 0.5 | Hexyloxypropylamine | 30 | A | B | C |
| Example 209 | 0.5 | Poly(oxyethylene)diamine | 30 | A | B | C |
| Example 210 | 0.5 | Dimethyl sulfoxide | 30 | A | B | C |

TABLE 8

| | Fluoride | | | | |
|---|---|---|---|---|---|
| | ion source | | Oxidant | | |
| | | Amount | | Amount | Additive |
| | Type | (%) | Type | (%) | Type |
| Example 211 | HF | 0.5 | Peracetic acid | 8 | Phenolsulfonic acid formaldehyde condensate |
| Example 212 | HF | 0.5 | Peracetic acid | 8 | Phenolsulfonic acid formaldehyde condensate |
| Example 213 | HF | 0.5 | Peracetic acid | 8 | Phenolsulfonic acid formaldehyde condensate |
| Example 214 | HF | 0.5 | Peracetic acid | 8 | Phenolsulfonic acid formaldehyde condensate |
| Example 215 | HF | 0.5 | Peracetic acid | 8 | Phenolsulfonic acid formaldehyde condensate |
| Example 216 | HF | 0.5 | Peracetic acid | 8 | Phenolsulfonic acid formaldehyde condensate |
| Example 217 | HF | 0.5 | Peracetic acid | 8 | Phenolsulfonic acid formaldehyde condensate |
| Example 218 | HF | 0.5 | Peracetic acid | 8 | Phenolsulfonic acid formaldehyde condensate |
| Example 219 | HF | 0.5 | Peracetic acid | 8 | Phenolsulfonic acid formaldehyde condensate |
| Example 220 | HF | 0.5 | Peracetic acid | 8 | Phenolsulfonic acid formaldehyde condensate |
| Example 221 | HF | 0.5 | Peracetic acid | 8 | Phenolsulfonic acid formaldehyde condensate |
| Example 222 | HF | 0.5 | Peracetic acid | 8 | Phenolsulfonic acid formaldehyde condensate |
| Example 223 | HF | 0.5 | Peracetic acid | 8 | Phenolsulfonic acid formaldehyde condensate |
| Example 224 | HF | 0.5 | Peracetic acid | 8 | Phenolsulfonic acid formaldehyde condensate |
| Example 225 | HF | 0.5 | Peracetic acid | 8 | Phenolsulfonic acid formaldehyde condensate |
| Example 226 | HF | 0.5 | Peracetic acid | 8 | Phenolsulfonic acid formaldehyde condensate |
| Example 227 | HF | 0.5 | Peracetic acid | 8 | Phenolsulfonic acid formaldehyde condensate |
| Example 228 | HF | 0.5 | Peracetic acid | 8 | Phenolsulfonic acid formaldehyde condensate |
| Example 229 | HF | 0.5 | Peracetic acid | 8 | Phenolsulfonic acid formaldehyde condensate |
| Example 230 | HF | 0.5 | Peracetic acid | 8 | Phenolsulfonic acid formaldehyde condensate |
| Example 231 | HF | 0.5 | Peracetic acid | 8 | Phenolsulfonic acid formaldehyde condensate |
| Example 232 | HF | 0.5 | Peracetic acid | 8 | Phenolsulfonic acid formaldehyde condensate |
| Example 233 | HF | 0.5 | Peracetic acid | 8 | Phenolsulfonic acid formaldehyde condensate |
| Example 234 | HF | 0.5 | Peracetic acid | 8 | Phenolsulfonic acid formaldehyde condensate |
| Example 235 | HF | 0.5 | Peracetic acid | 8 | Phenolsulfonic acid formaldehyde condensate |
| Example 236 | HF | 0.5 | Peracetic acid | 8 | Phenolsulfonic acid formaldehyde condensate |
| Example 237 | HF | 0.5 | Peracetic acid | 8 | Phenolsulfonic acid formaldehyde condensate |
| Example 238 | HF | 0.5 | Peracetic acid | 8 | Phenolsulfonic acid formaldehyde condensate |
| Example 239 | HF | 0.5 | Peracetic acid | 8 | Phenolsulfonic acid formaldehyde condensate |
| Example 240 | HF | 0.5 | Peracetic acid | 8 | Phenolsulfonic acid formaldehyde condensate |

| | Additive | Organic solvent | | | | SiGe |
|---|---|---|---|---|---|---|
| | Amount | | Amount | SiGe | Si | Surface |
| | (%) | Type | (%) | ER | ER | roughness |
| Example 211 | 0.5 | Tetrahydro furfuryl alcohol | 30 | A | B | C |
| Example 212 | 0.5 | Glycerol | 30 | A | B | C |
| Example 213 | 0.5 | Sulfolane | 30 | A | A | C |
| Example 214 | 0.5 | Ethylene glycol monomethyl ether | 30 | A | B | C |
| Example 215 | 0.5 | Ethylene glycol monoethyl ether | 30 | A | B | C |
| Example 216 | 0.5 | Ethylene glycol monobutyl ether | 30 | A | B | C |
| Example 217 | 0.5 | Ethylene glycol dimethyl ether | 30 | A | B | C |
| Example 218 | 0.5 | Ethylene glycol diethyl ether | 30 | A | B | C |
| Example 219 | 0.5 | Diethylene glycol monomethyl ether | 30 | A | B | C |
| Example 220 | 0.5 | Diethylene glycol monoethyl ether | 30 | A | B | C |
| Example 221 | 0.5 | Diethylene glycol monopropyl ether | 30 | A | B | C |
| Example 222 | 0.5 | Diethylene glycol monoisopropyl ether | 30 | A | B | C |
| Example 223 | 0.5 | Diethylene glycol monoisobutyl ether | 30 | A | B | C |
| Example 224 | 0.5 | Diethylene glycol monobenzyl ether | 30 | A | B | C |
| Example 225 | 0.5 | Diethylene glycol dimethyl ether | 30 | A | B | C |
| Example 226 | 0.5 | Diethylene glycol diethyl ether | 30 | A | B | C |
| Example 227 | 0.5 | Triethylene glycol monomethyl ether | 30 | A | B | C |
| Example 228 | 0.5 | Triethylene glycol dimethyl ether | 30 | A | B | C |
| Example 229 | 0.5 | Polyethylene glycol monomethyl ether | 30 | A | B | C |
| Example 230 | 0.5 | Diethylene glycol methyl ethyl ether | 30 | A | B | C |
| Example 231 | 0.5 | Propylene glycol monomethyl ether | 30 | A | B | C |
| Example 232 | 0.5 | Propylene glycol dimethyl ether | 30 | A | B | C |
| Example 233 | 0.5 | Propylene glycol monobutyl ether | 30 | A | B | C |
| Example 234 | 0.5 | Monopropyl ether | 30 | A | B | C |
| Example 235 | 0.5 | Dipropylene glycol monomethyl ether | 30 | A | B | C |
| | | (DPM) | | | | |
| Example 236 | 0.5 | Dipropylene glycol monoisopropyl ether | 30 | A | B | C |
| Example 237 | 0.5 | Dipropylene glycol monobutyl ether | 30 | A | B | C |
| Example 238 | 0.5 | Dipropylene glycol diisopropyl ether | 30 | A | B | C |
| Example 239 | 0.5 | 1-Methoxy-2-butanol | 30 | A | B | C |
| Example 240 | 0.5 | 2-Methoxy-1-butanol | 30 | A | B | C |

TABLE 9

| | Fluoride | | | | |
|---|---|---|---|---|---|
| | ion source | | Oxidant | | |
| | | Amount | | Amount | Additive |
| | Type | (%) | Type | (%) | Type |
| Example 241 | HF | 0.5 | Peracetic acid | 8 | Phenolsulfonic acid formaldehyde condensate |
| Example 242 | HF | 0.5 | Peracetic acid | 8 | Phenolsulfonic acid formaldehyde condensate |
| Example 243 | HF | 0.5 | Peracetic acid | 8 | Phenolsulfonic acid formaldehyde condensate |
| Example 244 | HF | 0.5 | Peracetic acid | 8 | Phenolsulfonic acid formaldehyde condensate |
| Example 245 | HF | 0.5 | Peracetic acid | 8 | Phenolsulfonic acid formaldehyde condensate |
| Example 246 | HF | 0.5 | Peracetic acid | 8 | Phenolsulfonic acid formaldehyde condensate |
| Example 247 | HF | 0.5 | Peracetic acid | 8 | Phenolsulfonic acid formaldehyde condensate |
| Example 248 | HF | 0.5 | Peracetic acid | 8 | Polyvinyl alcohol |
| Example 249 | HF | 0.5 | Peracetic acid | 8 | Polystyrene sulfonic acid |
| Example 250 | HF | 0.5 | Peracetic acid | 8 | Polyvinylpyrrolidone |
| Example 251 | HF | 0.5 | Peracetic acid | 8 | Polyallylamine |
| Example 252 | HF | 0.5 | Peracetic acid | 8 | Polyvinylamine |
| Example 253 | HF | 0.5 | Peracetic acid | 8 | Polyacrylamide |
| Example 254 | HF | 0.5 | Peracetic acid | 8 | Dimethylamine epichlorohydrin copolymer |
| Example 255 | HF | 0.5 | Peracetic acid | 8 | Hexadimethrine chloride |
| Example 256 | HF | 0.5 | Peracetic acid | 8 | Polydiallylamine |
| Example 257 | HF | 0.5 | Peracetic acid | 8 | Polydimethyldiallylammonium chloride |
| Example 258 | HF | 0.5 | Peracetic acid | 8 | Poly(4-vinylpyridine) |
| Example 259 | HF | 0.5 | Peracetic acid | 8 | Polyomithine |
| Example 260 | HF | 0.5 | Peracetic acid | 8 | Polylysine |
| Example 261 | HF | 0.5 | Peracetic acid | 8 | Polyarginine |
| Example 262 | HF | 0.5 | Peracetic acid | 8 | Polyhistidine |
| Example 263 | HF | 0.5 | Peracetic acid | 8 | Polyvinylimidazole |
| Example 264 | HF | 0.5 | Peracetic acid | 8 | Polymethyldiallylamine |
| Example 265 | HF | 0.5 | Peracetic acid | 8 | Cetyltrimethylammonium chloride |
| Example 266 | HF | 0.5 | Peracetic acid | 8 | Stearyltrimethylammonium bromide |
| Example 267 | HF | 0.5 | Peracetic acid | 8 | Polyoxyethylene lauryl amine |
| Example 268 | HF | 0.5 | Peracetic acid | 8 | Propyl naphthalenesulfonic acid |
| Example 269 | HF | 0.5 | Peracetic acid | 8 | Triisopropyl naphthalenesulfonic acid |
| Example 270 | HF | 0.5 | Peracetic acid | 8 | Dibutyl naphthalenesulfonic acid |

| | Additive | Organic solvent | | | | SiGe |
|---|---|---|---|---|---|---|
| | Amount | | Amount | SiGe | Si | Surface |
| | (%) | Type | (%) | ER | ER | roughness |
| Example 241 | 0.5 | 2-Methoxy-2-methylbutanol | 30 | A | B | C |
| Example 242 | 0.5 | 1,1-Dimethoxyethane | 30 | A | B | C |
| Example 243 | 0.5 | 2-(2-Butoxyethoxy)ethanol | 30 | A | B | C |
| Example 244 | 0.5 | Methanol | 30 | A | B | C |
| Example 245 | 0.5 | Ethanol | 30 | A | B | C |
| Example 246 | 0.5 | Isopropanol | 30 | A | B | C |
| Example 247 | 0.5 | 1-Butanol | 30 | A | B | C |
| Example 248 | 0.5 | Propylene glycol | 30 | B | A | B |
| Example 249 | 0.5 | Propylene glycol | 30 | B | A | B |
| Example 250 | 0.5 | Propylene glycol | 30 | B | A | B |
| Example 251 | 0.5 | Propylene glycol | 30 | B | A | B |
| Example 252 | 0.5 | Propylene glycol | 30 | B | A | B |
| Example 253 | 0.5 | Propylene glycol | 30 | B | A | B |
| Example 254 | 0.5 | Propylene glycol | 30 | B | A | B |
| Example 255 | 0.5 | Propylene glycol | 30 | B | A | B |
| Example 256 | 0.5 | Propylene glycol | 30 | B | A | B |
| Example 257 | 0.5 | Propylene glycol | 30 | B | A | B |
| Example 258 | 0.5 | Propylene glycol | 30 | B | A | B |
| Example 259 | 0.5 | Propylene glycol | 30 | B | A | B |
| Example 260 | 0.5 | Propylene glycol | 30 | B | A | B |
| Example 261 | 0.5 | Propylene glycol | 30 | B | A | B |
| Example 262 | 0.5 | Propylene glycol | 30 | B | A | B |
| Example 263 | 0.5 | Propylene glycol | 30 | B | A | B |
| Example 264 | 0.5 | Propylene glycol | 30 | B | A | B |
| Example 265 | 0.5 | Propylene glycol | 30 | B | A | B |
| Example 266 | 0.5 | Propylene glycol | 30 | B | A | B |
| Example 267 | 0.5 | Propylene glycol | 30 | B | A | B |
| Example 268 | 0.5 | Propylene glycol | 30 | B | A | B |
| Example 269 | 0.5 | Propylene glycol | 30 | B | A | B |
| Example 270 | 0.5 | Propylene glycol | 30 | B | A | B |

TABLE 10

| | Fluoride | | | | |
|---|---|---|---|---|---|
| | ion source | | Oxidant | | |
| | | Amount | | Amount | Additive |
| | Type | (%) | Type | (%) | Type |
| Example 271 | HF | 0.5 | Peracetic acid | 8 | Phenyl phenolsulfonic acid formaldehyde condensate |
| Example 272 | HF | 0.5 | Peracetic acid | 8 | polyoxyethylene lauryl ether sulfonic acid |
| Example 273 | HF | 0.5 | Peracetic acid | 8 | Polyoxyethylene oleyl ether sulfonic acid |
| Example 274 | HF | 0.5 | Peracetic acid | 8 | Polyoxyethylene octyl dodecyl ether sulfonic acid |
| Example 275 | HF | 0.5 | Peracetic acid | 8 | Polyoxyethylene lauryl ether carboxylic acid |
| Example 276 | HF | 0.5 | Peracetic acid | 8 | Polyoxyethylene dodecyl ether carboxylic acid |
| Example 277 | HF | 0.5 | Peracetic acid | 8 | Polyoxyethylene tridecyl ether carboxylic acid |
| Example 278 | HF | 0.5 | Peracetic acid | 8 | Polyoxyethylene alkyl phenyl ether phosphoric acid |
| Example 279 | HF | 0.5 | Peracetic acid | 8 | Polyoxyethylene lauryl ether phosphoric acid |
| Example 280 | HF | 0.5 | Peracetic acid | 8 | Lauryl dimethylaminoacetic acid betaine |
| Example 281 | HF | 0.5 | Peracetic acid | 8 | Lauryldimethylamine oxide |
| Example 282 | HF | 0.5 | Peracetic acid | 8 | Tetraethoxysilane |
| Example 283 | HF | 0.5 | Peracetic acid | 8 | Methyltrimethoxysilane |
| Example 284 | HF | 0.5 | Peracetic acid | 8 | Dimethyldimethoxysilane |
| Example 285 | HF | 0.5 | Peracetic acid | 8 | Phenyltrimethoxysilane |
| Example 286 | HF | 0.5 | Peracetic acid | 8 | Methyltriethoxysilane |
| Example 287 | HF | 0.5 | Peracetic acid | 8 | Dimethyldiethoxysilane |
| Example 288 | HF | 0.5 | Peracetic acid | 8 | Phenyltriethoxysilane |
| Example 289 | HF | 0.5 | Peracetic acid | 8 | n-Propyltrimethoxysilane |
| Example 290 | HF | 0.5 | Peracetic acid | 8 | n-Propyltriethoxysilane |
| Example 291 | HF | 0.5 | Peracetic acid | 8 | Hexyltrimethoxysilane |
| Example 292 | HF | 0.5 | Peracetic acid | 8 | Hexyltriethoxysilane |
| Example 293 | HF | 0.5 | Peracetic acid | 8 | Octyltriethoxysilane |
| Example 294 | HF | 0.5 | Peracetic acid | 8 | 1,6-Bis(trimethoxysilyl)hexane |
| Example 295 | HF | 0.5 | Peracetic acid | 8 | Trifluoropropyltrimethoxysilane |
| Example 296 | HF | 0.5 | Peracetic acid | 8 | t-Butylmethoxydimethylsilane |
| Example 297 | HF | 0.5 | Peracetic acid | 8 | 3-Cyanopropyldimethylmethoxysilane |
| Example 298 | HF | 0.5 | Peracetic acid | 8 | Ethoxy(trimethyl)silane |
| Example 299 | HF | 0.5 | Peracetic acid | 8 | methoxytrimethylsilane |
| Example 300 | HF | 0.5 | Peracetic acid | 8 | Hexyl(dimethoxy)silane |

| | Additive | Organic solvent | | | | SiGe |
|---|---|---|---|---|---|---|
| | Amount | | Amount | SiGe | Si | Surface |
| | (%) | Type | (%) | ER | ER | roughness |
| Example 271 | 0.5 | Propylene glycol | 30 | B | A | B |
| Example 272 | 0.5 | Propylene glycol | 30 | B | A | B |
| Example 273 | 0.5 | Propylene glycol | 30 | B | A | B |
| Example 274 | 0.5 | Propylene glycol | 30 | B | A | B |
| Example 275 | 0.5 | Propylene glycol | 30 | B | A | B |
| Example 276 | 0.5 | Propylene glycol | 30 | B | A | B |
| Example 277 | 0.5 | Propylene glycol | 30 | B | A | B |
| Example 278 | 0.5 | Propylene glycol | 30 | B | A | B |
| Example 279 | 0.5 | Propylene glycol | 30 | B | A | B |
| Example 280 | 0.5 | Propylene glycol | 30 | C | A | C |
| Example 281 | 0.5 | Propylene glycol | 30 | C | A | C |
| Example 282 | 1 | Propylene glycol | 30 | C | A | c |
| Example 283 | 1 | Propylene glycol | 30 | C | A | C |
| Example 284 | 1 | Propylene glycol | 30 | C | A | C |
| Example 285 | 1 | Propylene glycol | 30 | C | A | C |
| Example 286 | 1 | Propylene glycol | 30 | C | A | C |
| Example 287 | 1 | Propylene glycol | 30 | C | A | C |
| Example 288 | 1 | Propylene glycol | 30 | C | A | C |
| Example 289 | 1 | Propylene glycol | 30 | C | A | C |
| Example 290 | 1 | Propylene glycol | 30 | C | A | C |
| Example 291 | 1 | Propylene glycol | 30 | C | A | C |
| Example 292 | 1 | Propylene glycol | 30 | C | A | C |
| Example 293 | 1 | Propylene glycol | 30 | C | A | C |
| Example 294 | 1 | Propylene glycol | 30 | C | A | C |
| Example 295 | 1 | Propylene glycol | 30 | C | A | C |
| Example 296 | 1 | Propylene glycol | 30 | C | A | C |
| Example 297 | 1 | Propylene glycol | 30 | C | A | C |
| Example 298 | 1 | Propylene glycol | 30 | C | A | C |
| Example 299 | 1 | Propylene glycol | 30 | C | A | C |
| Example 300 | 1 | Propylene glycol | 30 | C | A | C |

TABLE 11

| | Fluoride | | | | |
|---|---|---|---|---|---|
| | ion source | | Oxidant | | |
| | | Amount | | Amount | Additive |
| | Type | (%) | Type | (%) | Type |
| Example 301 | HF | 0.5 | Peracetic acid | 8 | Methyldiethoxysilane |
| Example 302 | HF | 0.5 | Peracetic acid | 8 | Triethoxysilane |
| Example 303 | HF | 0.5 | Peracetic acid | 8 | 3-Aminopropyldimethylethoxysilane |
| Example 304 | HF | 0.5 | Peracetic acid | 8 | 3-(2-Aminoethoxyamino)propyltrimethoxysilane |
| Example 305 | HF | 0.5 | Peracetic acid | 8 | Trimethylsilanol |
| Example 306 | HF | 0.5 | Peracetic acid | 8 | Dimethylsilanediol |
| Example 307 | HF | 0.5 | Peracetic acid | 8 | Diphenylsilanediol |
| Example 308 | HF | 0.5 | Peracetic acid | 8 | Silanetriol |
| Example 309 | HF | 0.5 | Peracetic acid | 8 | 3-Aminopropylsilanetriol |
| Example 310 | HF | 0.5 | Peracetic acid | 8 | Methylsilanetriol |
| Example 311 | HF | 0.5 | Peracetic acid | 8 | 2-Methyl-2-propylsilanetriol |
| Example 312 | HF | 0.5 | Peracetic acid | 8 | Methyl acetate silanetriol |
| Example 313 | HF | 0.5 | Peracetic acid | 8 | 2-(Chloroethyl)acetate silanetriol |
| Example 314 | HF | 0.5 | Peracetic acid | 8 | 3-(Hydroxypropyl)silanetriol |
| Example 315 | HF | 0.5 | Peracetic acid | 8 | Di(ethylaldoxime)silane |
| Example 316 | HF | 0.5 | Peracetic acid | 8 | Mono(ethylaldoxime)silane |
| Example 317 | HF | 0.5 | Peracetic acid | 8 | Tris(ethylaldoxime)silane |
| Example 318 | HF | 0.5 | Peracetic acid | 8 | Tetra(ethylaldoxime)silane |
| Example 319 | HF | 0.5 | Peracetic acid | 8 | Methyltris(methylethylketoxime)silane |
| Example 320 | HF | 0.5 | Peracetic acid | 8 | Methyltosyl(acetoxime)silane |
| Example 321 | HF | 0.5 | Peracetic acid | 8 | Methyltris(methylisobutylketoxime)silane |
| Example 322 | HF | 0.5 | Peracetic acid | 8 | Dimethyldi(methylethylketoxime)silane |
| Example 323 | HF | 0.5 | Peracetic acid | 8 | Trimethyl(methylethylketoxime)silane |
| Example 324 | HF | 0.5 | Peracetic acid | 8 | Tetra(methylethylketoxime)silane |
| Example 325 | HF | 0.5 | Peracetic acid | 8 | Tetra(methylisobutylketoxime)silane |
| Example 326 | HF | 0.5 | Peracetic acid | 8 | Vinyltris(methylethylketoxime)silane |
| Example 327 | HF | 0.5 | Peracetic acid | 8 | Methylvinyldi(methylethylketoxime)silane |
| Example 328 | HF | 0.5 | Peracetic acid | 8 | Methylvinyldi(cyclohexanonexime)silane |
| Example 329 | HF | 0.5 | Peracetic acid | 8 | Vinyltris(methylisobutylketoxime)silane |
| Example 330 | HF | 0.5 | Peracetic acid | 8 | Phenyltris(methylethylketoxime)silane |

| | Additive | Organic solvent | | | | SiGe |
|---|---|---|---|---|---|---|
| | Amount | | Amount | SiGe | Si | Surface |
| | (%) | Type | (%) | ER | ER | roughness |
| Example 301 | 1 | Propylene glycol | 30 | C | A | C |
| Example 302 | 1 | Propylene glycol | 30 | C | A | C |
| Example 303 | 1 | Propylene glycol | 30 | C | A | C |
| Example 304 | 1 | Propylene glycol | 30 | C | A | C |
| Example 305 | 1 | Propylene glycol | 30 | C | A | C |
| Example 306 | 1 | Propylene glycol | 30 | C | A | C |
| Example 307 | 1 | Propylene glycol | 30 | C | A | C |
| Example 308 | 1 | Propylene glycol | 30 | C | A | C |
| Example 309 | 1 | Propylene glycol | 30 | C | A | C |
| Example 310 | 1 | Propylene glycol | 30 | C | A | C |
| Example 311 | 1 | Propylene glycol | 30 | C | A | C |
| Example 312 | 1 | Propylene glycol | 30 | C | A | C |
| Example 313 | 1 | Propylene glycol | 30 | C | A | C |
| Example 314 | 1 | Propylene glycol | 30 | C | A | C |
| Example 315 | 1 | Propylene glycol | 30 | C | A | C |
| Example 316 | 1 | Propylene glycol | 30 | C | A | C |
| Example 317 | 1 | Propylene glycol | 30 | C | A | C |
| Example 318 | 1 | Propylene glycol | 30 | C | A | C |
| Example 319 | 1 | Propylene glycol | 30 | C | A | C |
| Example 320 | 1 | Propylene glycol | 30 | C | A | C |
| Example 321 | 1 | Propylene glycol | 30 | C | A | C |
| Example 322 | 1 | Propylene glycol | 30 | C | A | C |
| Example 323 | 1 | Propylene glycol | 30 | C | A | C |
| Example 324 | 1 | Propylene glycol | 30 | C | A | C |
| Example 325 | 1 | Propylene glycol | 30 | C | A | C |
| Example 326 | 1 | Propylene glycol | 30 | C | A | C |
| Example 327 | 1 | Propylene glycol | 30 | C | A | C |
| Example 328 | 1 | Propylene glycol | 30 | C | A | C |
| Example 329 | 1 | Propylene glycol | 30 | C | A | C |
| Example 330 | 1 | Propylene glycol | 30 | C | A | C |

TABLE 12

| | Fluoride | | | | | | | | | | |
|---|---|---|---|---|---|---|---|---|---|---|---|
| | ion source | | Oxidant | | Additive | | Organic solvent | | | | SiGe |
| | | Amount | | Amount | | Amount | | Amount | SiGe | Si | Surface |
| | Type | (%) | Type | (%) | Type | (%) | Type | (%) | ER | ER | roughness |
| Example 331 | HF | 0.5 | Peracetic acid | 8 | Hexamethyldisilazane | 1 | Propylene glycol | 30 | C | A | C |
| Example 332 | HF | 0.5 | Peracetic acid | 8 | Hexamethyldisiloxane | 1 | Propylene glycol | 30 | C | A | C |
| Example 333 | HF | 0.5 | Peracetic acid | 8 | Octamethylcyclotetra- | 1 | Propylene glycol | 30 | C | A | C |
| | | | | | siloxane | | | | | | |
| Example 334 | HF | 0.5 | Peracetic acid | 8 | Decamethylcyclopenta- | 1 | Propylene glycol | 30 | C | A | C |
| | | | | | siloxane | | | | | | |
| Example 335 | HF | 0.5 | Peracetic acid | 8 | Dodecamethylcyclohexa- | 1 | Propylene glycol | 30 | C | A | C |
| | | | | | siloxane | | | | | | |
| Example 336 | HF | 0.5 | Peracetic acid | 8 | Ethylenediamine | 1 | Propylene glycol | 30 | B | A | B |
| Example 337 | HF | 0.5 | Peracetic acid | 8 | Diethylenetriamine | 1 | Propylene glycol | 30 | B | A | B |
| Example 338 | HF | 0.5 | Peracetic acid | 8 | Triethylenetetramine | 1 | Propylene glycol | 30 | B | A | B |
| Example 339 | HF | 0.5 | Peracetic acid | 8 | Tetraethylenepentamine | 1 | Propylene glycol | 30 | B | A | B |
| Example 340 | HF | 0.5 | Peracetic acid | 8 | Pentaethylenehexamine | 1 | Propylene glycol | 30 | B | A | B |
| Example 341 | HF | 0.5 | Peracetic acid | 8 | Tetramethylethylenediamine | 1 | Propylene glycol | 30 | B | A | B |
| Example 342 | HF | 0.5 | Peracetic acid | 8 | Hexamethylenediamine | 1 | Propylene glycol | 30 | B | A | B |
| Example 343 | HF | 0.5 | Peracetic acid | 8 | Methylamine | 1 | Propylene glycol | 30 | B | A | B |
| Example 344 | HF | 0.5 | Peracetic acid | 8 | Dimethylamine | 1 | Propylene glycol | 30 | B | A | B |
| Example 345 | HF | 0.5 | Peracetic acid | 8 | Trimethylamine | 1 | Propylene glycol | 30 | B | A | B |
| Example 346 | HF | 0.5 | Peracetic acid | 8 | Ethylamine | 1 | Propylene glycol | 30 | B | A | B |
| Example 347 | HF | 0.5 | Peracetic acid | 8 | Diethylamine | 1 | Propylene glycol | 30 | B | A | B |
| Example 348 | HF | 0.5 | Peracetic acid | 8 | Tri ethylamine | 1 | Propylene glycol | 30 | B | A | B |
| Example 349 | HF | 0.5 | Peracetic acid | 8 | 2-Ethylhexylamine | 1 | Propylene glycol | 30 | B | A | B |
| Example 350 | HF | 0.5 | Peracetic acid | 8 | Stearylamine | 1 | Propylene glycol | 30 | B | A | B |
| Example 351 | HF | 0.5 | Peracetic acid | 8 | Cyclohexylamine | 1 | Propylene glycol | 30 | B | A | B |
| Example 352 | HF | 0.5 | Peracetic acid | 8 | Aniline | 1 | Propylene glycol | 30 | B | A | B |
| Example 353 | HF | 0.5 | Peracetic acid | 8 | Phenethylamine | 1 | Propylene glycol | 30 | B | A | B |
| Example 354 | HF | 0.5 | Peracetic acid | 8 | Toluidine | 1 | Propylene glycol | 30 | B | A | B |
| Example 355 | HF | 0.5 | Peracetic acid | 8 | m-Xylylenediamine | 1 | Propylene glycol | 30 | B | A | B |
| Example 356 | HF | 0.5 | Peracetic acid | 8 | Pyrrolidine | 1 | Propylene glycol | 30 | B | A | B |
| Example 357 | HF | 0.5 | Peracetic acid | 8 | Piperidine | 1 | Propylene glycol | 30 | B | A | B |
| Example 358 | HF | 0.5 | Peracetic acid | 8 | Piperazine | 1 | Propylene glycol | 30 | B | A | B |
| Example 359 | HF | 0.5 | Peracetic acid | 8 | Morpholine | 1 | Propylene glycol | 30 | B | A | B |
| Example 360 | HF | 0.5 | Peracetic acid | 8 | Pyrrole | 1 | Propylene glycol | 30 | B | A | B |

TABLE 13

| | Fluoride | | | | | | | | | | |
|---|---|---|---|---|---|---|---|---|---|---|---|
| | ion source | | Oxidant | | Additive | | Organic solvent | | | | SiGe |
| | | Amount | | Amount | | Amount | | Amount | SiGe | Si | Surface |
| | Type | (%) | Type | (%) | Type | (%) | Type | (%) | ER | ER | roughness |
| Example 361 | HF | 0.5 | Peracetic acid | 8 | Pyrazole | 1 | Propylene glycol | 30 | B | A | B |
| Example 362 | HF | 0.5 | Peracetic acid | 8 | Imidazole | 1 | Propylene glycol | 30 | B | A | B |
| Example 363 | HF | 0.5 | Peracetic acid | 8 | Pyridine | 1 | Propylene glycol | 30 | B | A | B |
| Example 364 | HF | 0.5 | Peracetic acid | 8 | Pyrimidine | 1 | Propylene glycol | 30 | B | A | B |
| Example 365 | HF | 0.5 | Peracetic acid | 8 | Pyrazine | 1 | Propylene glycol | 30 | B | A | B |
| Example 366 | HF | 0.5 | Peracetic acid | 8 | Oxazole | 1 | Propylene glycol | 30 | B | A | B |
| Example 367 | HF | 0.5 | Peracetic acid | 8 | Thiazole | 1 | Propylene glycol | 30 | B | A | B |
| Example 368 | HF | 0.5 | Peracetic acid | 8 | 4-Dimethylaminopyridine | 1 | Propylene glycol | 30 | B | A | B |
| Example 369 | HF | 0.5 | Peracetic acid | 8 | Laurylpyridinium chloride | 1 | Propylene glycol | 30 | B | A | B |
| Example 370 | HF | 0.5 | Peracetic acid | 8 | Alanine | 1 | Propylene glycol | 30 | C | A | C |
| Example 371 | HF | 0.5 | Peracetic acid | 8 | Arginine | 1 | Propylene glycol | 30 | C | A | C |
| Example 372 | HF | 0.5 | Peracetic acid | 8 | Asparagine | 1 | Propylene glycol | 30 | C | A | C |
| Example 373 | HF | 0.5 | Peracetic acid | 8 | Aspartic acid | 1 | Propylene glycol | 30 | C | A | C |
| Example 374 | HF | 0.5 | Peracetic acid | 8 | Glutamine | 1 | Propylene glycol | 30 | C | A | C |
| Example 375 | HF | 0.5 | Peracetic acid | 8 | Glutamic acid | 1 | Propylene glycol | 30 | C | A | C |
| Example 376 | HF | 0.5 | Peracetic acid | 8 | Glycine | 1 | Propylene glycol | 30 | C | A | C |
| Example 377 | HF | 0.5 | Peracetic acid | 8 | Histidine | 1 | Propylene glycol | 30 | C | A | C |
| Example 378 | HF | 0.5 | Peracetic acid | 8 | Isoleucine | 1 | Propylene glycol | 30 | C | A | C |
| Example 379 | HF | 0.5 | Peracetic acid | 8 | Leucine | 1 | Propylene glycol | 30 | C | A | C |
| Example 380 | HF | 0.5 | Peracetic acid | 8 | Lysine | 1 | Propylene glycol | 30 | C | A | C |
| Example 381 | HF | 0.5 | Peracetic acid | 8 | Methionine | 1 | Propylene glycol | 30 | C | A | C |
| Example 382 | HF | 0.5 | Peracetic acid | 8 | Phenylalanine | 1 | Propylene glycol | 30 | C | A | C |
| Example 383 | HF | 0.5 | Peracetic acid | 8 | Proline | 1 | Propylene glycol | 30 | C | A | C |
| Example 384 | HF | 0.5 | Peracetic acid | 8 | Serine | 1 | Propylene glycol | 30 | C | A | C |
| Example 385 | HF | 0.5 | Peracetic acid | 8 | Threonine | 1 | Propylene glycol | 30 | C | A | C |
| Example 386 | HF | 0.5 | Peracetic acid | 8 | Tryptophan | 1 | Propylene glycol | 30 | C | A | C |
| Example 387 | HF | 0.5 | Peracetic acid | 8 | Tyrosine | 1 | Propylene glycol | 30 | C | A | C |
| Example 388 | HF | 0.5 | Peracetic acid | 8 | Valine | 1 | Propylene glycol | 30 | C | A | C |
| Example 389 | HF | 0.5 | Peracetic acid | 8 | Tetramethylammonium | 1 | Propylene glycol | 30 | B | A | B |
| | | | | | hydroxide | | | | | | |
| Example 390 | HF | 0.5 | Peracetic acid | 8 | Tetrapropylammonium | 1 | Propylene glycol | 30 | B | A | B |
| | | | | | hydroxide | | | | | | |

TABLE 14

| | Fluoride | | | | |
|---|---|---|---|---|---|
| | ion source | | Oxidant | | |
| | | Amount | | Amount | Additive |
| | Type | (%) | Type | (%) | Type |
| Example 391 | HF | 0.5 | Peracetic acid | 8 | Tetrabutylammonium hydroxide |
| Example 392 | HF | 0.5 | Peracetic acid | 8 | Methyltripropylammonium hydroxide |
| Example 393 | HF | 0.5 | Peracetic acid | 8 | Methyltributylammonium hydroxide |
| Example 394 | HF | 0.5 | Peracetic acid | 8 | Ethyltrimethylammonium hydroxide |
| Example 395 | HF | 0.5 | Peracetic acid | 8 | Dimethyldiethylammonium hydroxide |
| Example 396 | HF | 0.5 | Peracetic acid | 8 | Benzyltrimethylammonium hydroxide |
| Example 397 | HF | 0.5 | Peracetic acid | 8 | (2-Hydroxyethyl)trimethylammonium hydroxide |
| Example 398 | HF | 0.5 | Peracetic acid | 8 | Boric acid |
| Example 399 | HF | 0.5 | Peracetic acid | 8 | Polyvinyl alcohol |
| Example 400 | HF | 0.5 | Peracetic acid | 8 | Polystyrene sulfonic acid |
| Example 401 | HF | 0.5 | Peracetic acid | 8 | Polyvinylpyrrolidone |
| Example 402 | HF | 0.5 | Peracetic acid | 8 | Polyallylamine |
| Example 403 | HF | 0.5 | Peracetic acid | 8 | Polyvinylamine |
| Example 404 | HF | 0.5 | Peracetic acid | 8 | Polyacrylamide |
| Example 405 | HF | 0.5 | Peracetic acid | 8 | Dimethylamine-epichlorohydrin copolymer |
| Example 406 | HF | 0.5 | Peracetic acid | 8 | Hexadimethrine chloride |
| Example 407 | HF | 0.5 | Peracetic acid | 8 | Polydiallylamine |
| Example 408 | HF | 0.5 | Peracetic acid | 8 | Polydimethyldiallylammonium chloride |
| Example 409 | HF | 0.5 | Peracetic acid | 8 | Poly(4-vinylpyridine) |
| Example 410 | HF | 0.5 | Peracetic acid | 8 | Polyomithine |
| Example 411 | HF | 0.5 | Peracetic acid | 8 | Polylysine |
| Example 412 | HF | 0.5 | Peracetic acid | 8 | Polyarginine |
| Example 413 | HF | 0.5 | Peracetic acid | 8 | Polyhistidine |
| Example 414 | HF | 0.5 | Peracetic acid | 8 | Polyvinylimidazole |
| Example 415 | HF | 0.5 | Peracetic acid | 8 | Polymethyldiallylamine |
| Example 416 | HF | 0.5 | Peracetic acid | 8 | Cetyltrimethylammonium chloride |
| Example 417 | HF | 0.5 | Peracetic acid | 8 | Stearyltrimethylammonium bromide |
| Example 418 | HF | 0.5 | Peracetic acid | 8 | Polyoxyethylene lauryl amine |
| Example 419 | HF | 0.5 | Peracetic acid | 8 | Propyl naphthalenesulfonic acid |
| Example 420 | HF | 0.5 | Peracetic acid | 8 | Triisopropyl naphthalenesulfonic acid |

| | Additive | Organic solvent | | | | SiGe |
|---|---|---|---|---|---|---|
| | Amount | | Amount | SiGe | Si | Surface |
| | (%) | Type | (%) | ER | ER | roughness |
| Example 391 | 1 | Propylene glycol | 30 | B | A | B |
| Example 392 | 1 | Propylene glycol | 30 | B | A | B |
| Example 393 | 1 | Propylene glycol | 30 | B | A | B |
| Example 394 | 1 | Propylene glycol | 30 | B | A | B |
| Example 395 | 1 | Propylene glycol | 30 | B | A | B |
| Example 396 | 1 | Propylene glycol | 30 | B | A | B |
| Example 397 | 1 | Propylene glycol | 30 | B | A | B |
| Example 398 | 1 | Propylene glycol | 30 | B | A | B |
| Example 399 | 0.5 | Sulfolane | 30 | B | A | B |
| Example 400 | 0.5 | Sulfolane | 30 | B | A | B |
| Example 401 | 0.5 | Sulfolane | 30 | B | A | B |
| Example 402 | 0.5 | Sulfolane | 30 | B | A | B |
| Example 403 | 0.5 | Sulfolane | 30 | B | A | B |
| Example 404 | 0.5 | Sulfolane | 30 | B | A | B |
| Example 405 | 0.5 | Sulfolane | 30 | B | A | B |
| Example 406 | 0.5 | Sulfolane | 30 | B | A | B |
| Example 407 | 0.5 | Sulfolane | 30 | B | A | B |
| Example 408 | 0.5 | Sulfolane | 30 | B | A | B |
| Example 409 | 0.5 | Sulfolane | 30 | B | A | B |
| Example 410 | 0.5 | Sulfolane | 30 | B | A | B |
| Example 411 | 0.5 | Sulfolane | 30 | B | A | B |
| Example 412 | 0.5 | Sulfolane | 30 | B | A | B |
| Example 413 | 0.5 | Sulfolane | 30 | B | A | B |
| Example 414 | 0.5 | Sulfolane | 30 | B | A | B |
| Example 415 | 0.5 | Sulfolane | 30 | B | A | B |
| Example 416 | 0.5 | Sulfolane | 30 | B | A | B |
| Example 417 | 0.5 | Sulfolane | 30 | B | A | B |
| Example 418 | 0.5 | Sulfolane | 30 | B | A | B |
| Example 419 | 0.5 | Sulfolane | 30 | B | A | B |
| Example 420 | 0.5 | Sulfolane | 30 | B | A | B |

TABLE 15

| | Fluoride | | | | |
|---|---|---|---|---|---|
| | ion source | | Oxidant | | |
| | | Amount | | Amount | Additive |
| | Type | (%) | Type | (%) | Type |
| Example 421 | HF | 0.5 | Peracetic acid | 8 | Dibutyl naphthalenesulfonic acid |
| Example 422 | HF | 0.5 | Peracetic acid | 8 | Phenyl phenolsulfonic acid formaldehyde condensate |
| Example 423 | HF | 0.5 | Peracetic acid | 8 | polyoxyethylene lauryl ether sulfonic acid |
| Example 424 | HF | 0.5 | Peracetic acid | 8 | Polyoxyethylene oleyl ether sulfonic acid |
| Example 425 | HF | 0.5 | Peracetic acid | 8 | Polyoxyethylene octyl dodecyl ether sulfonic acid |
| Example 426 | HF | 0.5 | Peracetic acid | 8 | Polyoxyethylene lauryl ether carboxylic acid |
| Example 427 | HF | 0.5 | Peracetic acid | 8 | Polyoxyethylene dodecyl ether carboxylic acid |
| Example 428 | HF | 0.5 | Peracetic acid | 8 | Polyoxyethylene tridecyl ether carboxylic acid |
| Example 429 | HF | 0.5 | Peracetic acid | 8 | Polyoxyethylene alkyl phenyl ether phosphoric acid |
| Example 430 | HF | 0.5 | Peracetic acid | 8 | Polyoxyethylene lauryl ether phosphoric acid |
| Example 431 | HF | 0.5 | Peracetic acid | 8 | Lauryl dimethylaminoacetic acid betaine |
| Example 432 | HF | 0.5 | Peracetic acid | 8 | Lauryldimethylamine oxide |
| Example 433 | HF | 0.5 | Peracetic acid | 8 | Tetraethoxysilane |
| Example 434 | HF | 0.5 | Peracetic acid | 8 | Methyltrimethoxysilane |
| Example 435 | HF | 0.5 | Peracetic acid | 8 | Dimethyldimethoxysilane |
| Example 436 | HF | 0.5 | Peracetic acid | 8 | Phenyltrimethoxysilane |
| Example 437 | HF | 0.5 | Peracetic acid | 8 | Methyltriethoxysilane |
| Example 438 | HF | 0.5 | Peracetic acid | 8 | Dimethyldiethoxysilane |
| Example 439 | HF | 0.5 | Peracetic acid | 8 | Phenyltriethoxysilane |
| Example 440 | HF | 0.5 | Peracetic acid | 8 | n-Propyltrimethoxysilane |
| Example 441 | HF | 0.5 | Peracetic acid | 8 | n-Propyltriethoxysilane |
| Example 442 | HF | 0.5 | Peracetic acid | 8 | Hexyltrimethoxysilane |
| Example 443 | HF | 0.5 | Peracetic acid | 8 | Hexyltriethoxysilane |
| Example 444 | HF | 0.5 | Peracetic acid | 8 | Octyltriethoxysilane |
| Example 445 | HF | 0.5 | Peracetic acid | 8 | 1,6-Bis(trimethoxysilyl)hexane |
| Example 446 | HF | 0.5 | Peracetic acid | 8 | Trifluoropropyltrimethoxysilane |
| Example 447 | HF | 0.5 | Peracetic acid | 8 | t-Butylmethoxydimethylsilane |
| Example 448 | HF | 0.5 | Peracetic acid | 8 | 3-Cyanopropyldimethylmethoxysilane |
| Example 449 | HF | 0.5 | Peracetic acid | 8 | Ethoxy(trimethyl)silane |
| Example 450 | HF | 0.5 | Peracetic acid | 8 | Methoxytrimethylsilane |

| | Additive | Organic solvent | | | | SiGe |
|---|---|---|---|---|---|---|
| | Amount | | Amount | SiGe | Si | Surface |
| | (%) | Type | (%) | ER | ER | roughness |
| Example 421 | 0.5 | Sulfolane | 30 | B | A | B |
| Example 422 | 0.5 | Sulfolane | 30 | B | A | B |
| Example 423 | 0.5 | Sulfolane | 30 | B | A | B |
| Example 424 | 0.5 | Sulfolane | 30 | B | A | B |
| Example 425 | 0.5 | Sulfolane | 30 | B | A | B |
| Example 426 | 0.5 | Sulfolane | 30 | B | A | B |
| Example 427 | 0.5 | Sulfolane | 30 | B | A | B |
| Example 428 | 0.5 | Sulfolane | 30 | B | A | B |
| Example 429 | 0.5 | Sulfolane | 30 | B | A | B |
| Example 430 | 0.5 | Sulfolane | 30 | B | A | B |
| Example 431 | 0.5 | Sulfolane | 30 | C | A | C |
| Example 432 | 0.5 | Sulfolane | 30 | C | A | C |
| Example 433 | 1 | Sulfolane | 30 | C | A | C |
| Example 434 | 1 | Sulfolane | 30 | C | A | C |
| Example 435 | 1 | Sulfolane | 30 | C | A | C |
| Example 436 | 1 | Sulfolane | 30 | C | A | C |
| Example 437 | 1 | Sulfolane | 30 | C | A | C |
| Example 438 | 1 | Sulfolane | 30 | C | A | C |
| Example 439 | 1 | Sulfolane | 30 | C | A | C |
| Example 440 | 1 | Sulfolane | 30 | C | A | C |
| Example 441 | 1 | Sulfolane | 30 | C | A | C |
| Example 442 | 1 | Sulfolane | 30 | C | A | C |
| Example 443 | 1 | Sulfolane | 30 | C | A | C |
| Example 444 | 1 | Sulfolane | 30 | C | A | C |
| Example 445 | 1 | Sulfolane | 30 | C | A | C |
| Example 446 | 1 | Sulfolane | 30 | C | A | C |
| Example 447 | 1 | Sulfolane | 30 | C | A | C |
| Example 448 | 1 | Sulfolane | 30 | C | A | C |
| Example 449 | 1 | Sulfolane | 30 | C | A | C |
| Example 450 | 1 | Sulfolane | 30 | C | A | C |

TABLE 16

| | Fluoride | | | | |
|---|---|---|---|---|---|
| | ion source | | Oxidant | | |
| | | Amount | | Amount | Additive |
| | Type | (%) | Type | (%) | Type |
| Example 451 | HF | 0.5 | Peracetic acid | 8 | Hexyl(dimethoxy)silane |
| Example 452 | HF | 0.5 | Peracetic acid | 8 | Methyldiethoxysilane |
| Example 453 | HF | 0.5 | Peracetic acid | 8 | Triethoxysilane |
| Example 454 | HF | 0.5 | Peracetic acid | 8 | 3-Aminopropyldimethylethoxysilane |
| Example 455 | HF | 0.5 | Peracetic acid | 8 | 3-(2-Aminoethoxyamino)propyltrimethoxysilane |
| Example 456 | HF | 0.5 | Peracetic acid | 8 | Trimethylsilanol |
| Example 457 | HF | 0.5 | Peracetic acid | 8 | Dimethylsilanediol |
| Example 458 | HF | 0.5 | Peracetic acid | 8 | Diphenylsilanediol |
| Example 459 | HF | 0.5 | Peracetic acid | 8 | Silanetriol |
| Example 460 | HF | 0.5 | Peracetic acid | 8 | 3-Aminopropylsilanetriol |
| Example 461 | HF | 0.5 | Peracetic acid | 8 | Methylsilanetriol |
| Example 462 | HF | 0.5 | Peracetic acid | 8 | 2-Methyl-2-propylsilanetriol |
| Example 463 | HF | 0.5 | Peracetic acid | 8 | Methyl acetate silanetriol |
| Example 464 | HF | 0.5 | Peracetic acid | 8 | 2-(Chloroethyl)acetate silanetriol |
| Example 465 | HF | 0.5 | Peracetic acid | 8 | 3-(Hydroxypropyl)silanetriol |
| Example 466 | HF | 0.5 | Peracetic acid | 8 | Di(ethylaldoxime)silane |
| Example 467 | HF | 0.5 | Peracetic acid | 8 | Mono(ethylaldoxime)silane |
| Example 468 | HF | 0.5 | Peracetic acid | 8 | Tris(ethylaldoxime)silane |
| Example 469 | HF | 0.5 | Peracetic acid | 8 | Tetra(ethylaldoxime)silane |
| Example 470 | HF | 0.5 | Peracetic acid | 8 | Methyltris(methylethylketoxime)silane |
| Example 471 | HF | 0.5 | Peracetic acid | 8 | Methyltosyl(acetoxime)silane |
| Example 472 | HF | 0.5 | Peracetic acid | 8 | Methyltris(methylisobutylketoxime)silane |
| Example 473 | HF | 0.5 | Peracetic acid | 8 | Dimethyldi(methylethylketoxime)silane |
| Example 474 | HF | 0.5 | Peracetic acid | 8 | Trimethyl(methylethylketoxime)silane |
| Example 475 | HF | 0.5 | Peracetic acid | 8 | Tetra(methylethylketoxime)silane |
| Example 476 | HF | 0.5 | Peracetic acid | 8 | Tetra(methylisobutylketoxime)silane |
| Example 477 | HF | 0.5 | Peracetic acid | 8 | Vinyltris(methylethylketoxime)silane |
| Example 478 | HF | 0.5 | Peracetic acid | 8 | Methylvinyldi(methylethylketoxime)silane |
| Example 479 | HF | 0.5 | Peracetic acid | 8 | Methylvinyldi(cyclohexanonexime)silane |
| Exanmle 480 | HF | 0.5 | Peracetic acid | 8 | Vinyltris(methylisobutylketoxime)silane |

| | Additive | Organic solvent | | | | SiGe |
|---|---|---|---|---|---|---|
| | Amount | | Amount | SiGe | Si | Surface |
| | (%) | Type | (%) | ER | ER | roughness |
| Example 451 | 1 | Sulfolane | 30 | C | A | C |
| Example 452 | 1 | Sulfolane | 30 | C | A | C |
| Example 453 | 1 | Sulfolane | 30 | C | A | C |
| Example 454 | 1 | Sulfolane | 30 | C | A | C |
| Example 455 | 1 | Sulfolane | 30 | C | A | C |
| Example 456 | 1 | Sulfolane | 30 | C | A | C |
| Example 457 | 1 | Sulfolane | 30 | C | A | C |
| Example 458 | 1 | Sulfolane | 30 | C | A | C |
| Example 459 | 1 | Sulfolane | 30 | C | A | C |
| Example 460 | 1 | Sulfolane | 30 | C | A | C |
| Example 461 | 1 | Sulfolane | 30 | C | A | C |
| Example 462 | 1 | Sulfolane | 30 | C | A | C |
| Example 463 | 1 | Sulfolane | 30 | C | A | C |
| Example 464 | 1 | Sulfolane | 30 | C | A | C |
| Example 465 | 1 | Sulfolane | 30 | C | A | C |
| Example 466 | 1 | Sulfolane | 30 | C | A | C |
| Example 467 | 1 | Sulfolane | 30 | C | A | C |
| Example 468 | 1 | Sulfolane | 30 | C | A | C |
| Example 469 | 1 | Sulfolane | 30 | C | A | C |
| Example 470 | 1 | Sulfolane | 30 | C | A | C |
| Example 471 | 1 | Sulfolane | 30 | C | A | C |
| Example 472 | 1 | Sulfolane | 30 | C | A | C |
| Example 473 | 1 | Sulfolane | 30 | C | A | C |
| Example 474 | 1 | Sulfolane | 30 | C | A | C |
| Example 475 | 1 | Sulfolane | 30 | C | A | C |
| Example 476 | 1 | Sulfolane | 30 | C | A | C |
| Example 477 | 1 | Sulfolane | 30 | C | A | C |
| Example 478 | 1 | Sulfolane | 30 | C | A | C |
| Example 479 | 1 | Sulfolane | 30 | C | A | C |
| Exanmle 480 | 1 | Sulfolane | 30 | C | A | C |

TABLE 17

| | Fluoride | | | | | | | | | | |
|---|---|---|---|---|---|---|---|---|---|---|---|
| | ion source | | Oxidant | | Additive | | Organic solvent | | | | SiGe |
| | | Amount | | Amount | | Amount | | Amount | SiGe | Si | Surface |
| | Type | (%) | Type | (%) | Type | (%) | Type | (%) | ER | ER | roughness |
| Example 481 | HF | 0.5 | Peracetic acid | 8 | Phenyltris(methylethyl- | 1 | Sulfolane | 30 | C | A | C |
| | | | | | ketoxime)silane | | | | | | |
| Example 482 | HF | 0.5 | Peracetic acid | 8 | Hexamethyldisilazane | 1 | Sulfolane | 30 | C | A | C |
| Example 483 | HF | 0.5 | Peracetic acid | 8 | Hexamethyldisiloxane | 1 | Sulfolane | 30 | C | A | C |
| Example 484 | HF | 0.5 | Peracetic acid | 8 | Octamethylcyclotetrasiloxane | 1 | Sulfolane | 30 | C | A | C |
| Example 485 | HF | 0.5 | Peracetic acid | 8 | Decamethylcyclopentasiloxane | 1 | Sulfolane | 30 | C | A | C |
| Example 486 | HF | 0.5 | Peracetic acid | 8 | Dodecamethylcyclohexasiloxane | 1 | Sulfolane | 30 | C | A | C |
| Example 487 | HF | 0.5 | Peracetic acid | 8 | Ethylenediamine | 1 | Sulfolane | 30 | B | A | B |
| Example 488 | HF | 0.5 | Peracetic acid | 8 | Diethylenetri amine | 1 | Sulfolane | 30 | B | A | B |
| Example 489 | HF | 0.5 | Peracetic acid | 8 | Triethylenetetramine | 1 | Sulfolane | 30 | B | A | B |
| Example 490 | HF | 0.5 | Peracetic acid | 8 | Tetraethylenepentamine | 1 | Sulfolane | 30 | B | A | B |
| Example 491 | HF | 0.5 | Peracetic acid | 8 | Pentaethylenehexamine | 1 | Sulfolane | 30 | B | A | B |
| Example 492 | HF | 0.5 | Peracetic acid | 8 | Tetramethylethylenedi amine | 1 | Sulfolane | 30 | B | A | B |
| Example 493 | HF | 0.5 | Peracetic acid | 8 | Hexamethylenediamine | 1 | Sulfolane | 30 | B | A | B |
| Example 494 | HF | 0.5 | Peracetic acid | 8 | Methylamine | 1 | Sulfolane | 30 | B | A | B |
| Example 495 | HF | 0.5 | Peracetic acid | 8 | Dimethylamine | 1 | Sulfolane | 30 | B | A | B |
| Example 496 | HF | 0.5 | Peracetic acid | 8 | Trimethylamine | 1 | Sulfolane | 30 | B | A | B |
| Example 497 | HF | 0.5 | Peracetic acid | 8 | Ethylamine | 1 | Sulfolane | 30 | B | A | B |
| Example 498 | HF | 0.5 | Peracetic acid | 8 | Diethylamine | 1 | Sulfolane | 30 | B | A | B |
| Example 499 | HF | 0.5 | Peracetic acid | 8 | Triethylamine | 1 | Sulfolane | 30 | B | A | B |
| Example 500 | HF | 0.5 | Peracetic acid | 8 | 2-Ethylhexylamine | 1 | Sulfolane | 30 | B | A | B |
| Example 501 | HF | 0.5 | Peracetic acid | 8 | Stearylamine | 1 | Sulfolane | 30 | B | A | B |
| Example 502 | HF | 0.5 | Peracetic acid | 8 | Cyclohexylamine | 1 | Sulfolane | 30 | B | A | B |
| Example 503 | HF | 0.5 | Peracetic acid | 8 | Aniline | 1 | Sulfolane | 30 | B | A | B |
| Example 504 | HF | 0.5 | Peracetic acid | 8 | Phenethylamine | 1 | Sulfolane | 30 | B | A | B |
| Example 505 | HF | 0.5 | Peracetic acid | 8 | Toluidine | 1 | Sulfolane | 30 | B | A | B |
| Example 506 | HF | 0.5 | Peracetic acid | 8 | m-Xylylenediamine | 1 | Sulfolane | 30 | B | A | B |
| Example 507 | HF | 0.5 | Peracetic acid | 8 | Pyrrolidine | 1 | Sulfolane | 30 | B | A | B |
| Example 508 | HF | 0.5 | Peracetic acid | 8 | Piperidine | 1 | Sulfolane | 30 | B | A | B |
| Example 509 | HF | 0.5 | Peracetic acid | 8 | Piperazine | 1 | Sulfolane | 30 | B | A | B |
| Example 510 | HF | 0.5 | Peracetic acid | 8 | Morpholine | 1 | Sulfolane | 30 | B | A | B |

TABLE 18

| | Fluoride | | | | | | | | | | |
|---|---|---|---|---|---|---|---|---|---|---|---|
| | ion source | | Oxidant | | Additive | | Organic solvent | | | | SiGe |
| | | Amount | | Amount | | Amount | | Amount | SiGe | Si | Surface |
| | Type | (%) | Type | (%) | Type | (%) | Type | (%) | ER | ER | roughness |
| Example 511 | HF | 0.5 | Peracetic acid | 8 | Pyrrole | 1 | Sulfolane | 30 | B | A | B |
| Example 512 | HF | 0.5 | Peracetic acid | 8 | Pyrazole | 1 | Sulfolane | 30 | B | A | B |
| Example 513 | HF | 0.5 | Peracetic acid | 8 | Imidazole | 1 | Sulfolane | 30 | B | A | B |
| Example 514 | HF | 0.5 | Peracetic acid | 8 | Pyridine | 1 | Sulfolane | 30 | B | A | B |
| Example 515 | HF | 0.5 | Peracetic acid | 8 | Pyrimidine | 1 | Sulfolane | 30 | B | A | B |
| Example 516 | HF | 0.5 | Peracetic acid | 8 | Pyrazine | 1 | Sulfolane | 30 | B | A | B |
| Example 517 | HF | 0.5 | Peracetic acid | 8 | Oxazole | 1 | Sulfolane | 30 | B | A | B |
| Example 518 | HF | 0.5 | Peracetic acid | 8 | Thiazole | 1 | Sulfolane | 30 | B | A | B |
| Example 519 | HF | 0.5 | Peracetic acid | 8 | 4-Dimethylaminopyridine | 1 | Sulfolane | 30 | B | A | B |
| Example 520 | HF | 0.5 | Peracetic acid | 8 | Laurylpyridinium chloride | 1 | Sulfolane | 30 | B | A | B |
| Example 521 | HF | 0.5 | Peracetic acid | 8 | Alanine | 1 | Sulfolane | 30 | C | A | C |
| Example 522 | HF | 0.5 | Peracetic acid | 8 | Arginine | 1 | Sulfolane | 30 | C | A | C |
| Example 523 | HF | 0.5 | Peracetic acid | 8 | Asparagine | 1 | Sulfolane | 30 | C | A | C |
| Example 524 | HF | 0.5 | Peracetic acid | 8 | Aspartic acid | 1 | Sulfolane | 30 | C | A | C |
| Example 525 | HF | 0.5 | Peracetic acid | 8 | Glutamine | 1 | Sulfolane | 30 | C | A | C |
| Example 526 | HF | 0.5 | Peracetic acid | 8 | Glutamic acid | 1 | Sulfolane | 30 | C | A | C |
| Example 527 | HF | 0.5 | Peracetic acid | 8 | Glycine | 1 | Sulfolane | 30 | C | A | C |
| Example 528 | HF | 0.5 | Peracetic acid | 8 | Histidine | 1 | Sulfolane | 30 | C | A | C |
| Example 529 | HF | 0.5 | Peracetic acid | 8 | Isoleucine | 1 | Sulfolane | 30 | C | A | C |
| Example 530 | HF | 0.5 | Peracetic acid | 8 | Leucine | 1 | Sulfolane | 30 | C | A | C |
| Example 531 | HF | 0.5 | Peracetic acid | 8 | Lysine | 1 | Sulfolane | 30 | C | A | C |
| Example 532 | HF | 0.5 | Peracetic acid | 8 | Methionine | 1 | Sulfolane | 30 | C | A | C |
| Example 533 | HF | 0.5 | Peracetic acid | 8 | Phenylalanine | 1 | Sulfolane | 30 | C | A | C |
| Example 534 | HF | 0.5 | Peracetic acid | 8 | Proline | 1 | Sulfolane | 30 | C | A | C |
| Example 535 | HF | 0.5 | Peracetic acid | 8 | Serine | 1 | Sulfolane | 30 | C | A | C |
| Example 536 | HF | 0.5 | Peracetic acid | 8 | Threonine | 1 | Sulfolane | 30 | C | A | C |
| Example 537 | HF | 0.5 | Peracetic acid | 8 | Tryptophan | 1 | Sulfolane | 30 | C | A | C |
| Example 538 | HF | 0.5 | Peracetic acid | 8 | Tyrosine | 1 | Sulfolane | 30 | C | A | C |
| Example 539 | HF | 0.5 | Peracetic acid | 8 | Valine | 1 | Sulfolane | 30 | C | A | C |
| Example 540 | HF | 0.5 | Peracetic acid | 8 | Tetramethylammonium hydroxide | 1 | Sulfolane | 30 | B | A | B |

TABLE 19

| | Fluoride | | | | |
|---|---|---|---|---|---|
| | ion source | | Oxidant | | |
| | | Amount | | Amount | Additive |
| | Type | (%) | Type | (%) | Type |
| Example 541 | HF | 0.5 | Peracetic acid | 8 | Tetrapropylammonium hydroxide |
| Example 542 | HF | 0.5 | Peracetic acid | 8 | Tetrabutylammonium hydroxide |
| Example 543 | HF | 0.5 | Peracetic acid | 8 | Methyltripropylammonium hydroxide |
| Example 544 | HF | 0.5 | Peracetic acid | 8 | Methyltributylammonium hydroxide |
| Example 545 | HF | 0.5 | Peracetic acid | 8 | Ethyltrimethylammonium hydroxide |
| Example 546 | HF | 0.5 | Peracetic acid | 8 | Dimethyldiethylammonium hydroxide |
| Example 547 | HF | 0.5 | Peracetic acid | 8 | Benzyltrimethylammonium hydroxide |
| Example 548 | HF | 0.5 | Peracetic acid | 8 | (2-Hydroxyethyl)trimethylammonium hydroxide |
| Example 549 | HF | 0.5 | Peracetic acid | 8 | Boric acid |
| Example 550 | HF | 1 | Peracetic acid | 8 | Dodecyl diphenyl ether disulfonic acid |
| Example 551 | HF | 1 | Peracetic acid | 8 | Dodecyl diphenyl ether disulfonic acid |
| Example 552 | HF | 1 | Peracetic acid | 8 | Phenolsulfonic acid formaldehyde condensate |
| Example 553 | HF | 1 | Peracetic acid | 8 | Phenolsulfonic acid formaldehyde condensate |
| Example 554 | HF | 0.5 | Peracetic acid | 4 | Dodecyl diphenyl ether disulfonic acid |
| Example 555 | HF | 0.5 | Peracetic acid | 4 | Dodecyl diphenyl ether disulfonic acid |
| Example 556 | HF | 0.5 | Peracetic acid | 4 | Phenolsulfonic acid formaldehyde condensate |
| Example 557 | HF | 0.5 | Peracetic acid | 4 | Phenolsulfonic acid formaldehyde condensate |
| Example 558 | NH4F | 0.5 | Peracetic acid | 8 | Dodecyl diphenyl ether disulfonic acid |
| Example 559 | NH4F | 0.5 | Peracetic acid | 8 | Dodecyl diphenyl ether disulfonic acid |
| Example 560 | NH4F | 0.5 | Peracetic acid | 8 | Phenolsulfonic acid formaldehyde condensate |
| Example 561 | NH4F | 0.5 | Peracetic acid | 8 | Phenolsulfonic acid formaldehyde condensate |
| Example 562 | HF | 0.5 | Hydrogen peroxide | 8 | Dodecyl diphenyl ether disulfonic acid |
| Example 563 | HF | 0.5 | Hydrogen peroxide | 8 | Dodecyl diphenyl ether disulfonic acid |
| Example 564 | HF | 0.5 | Hydrogen peroxide | 8 | Phenolsulfonic acid formaldehyde condensate |
| Example 565 | HF | 0.5 | Hydrogen peroxide | 8 | Phenolsulfonic acid formaldehyde condensate |
| Example 566 | HF | 0.5 | Peracetic acid | 8 | Dodecyl diphenyl ether disulfonic acid |
| Example 567 | HF | 0.5 | Peracetic acid | 8 | Dodecyl diphenyl ether disulfonic acid |
| Example 568 | HF | 0.5 | Peracetic acid | 8 | Phenolsulfonic acid formaldehyde condensate |
| Example 569 | HF | 0.5 | Peracetic acid | 8 | Phenolsulfonic acid formaldehyde condensate |
| Example 570 | HF | 0.5 | Peracetic acid | 8 | Dodecyl diphenyl ether disulfonic acid |

| | Additive | Organic solvent | | | | SiGe |
|---|---|---|---|---|---|---|
| | Amount | | Amount | SiGe | Si | Surface |
| | (%) | Type | (%) | ER | ER | roughness |
| Example 541 | 1 | Sulfolane | 30 | B | A | B |
| Example 542 | 1 | Sulfolane | 30 | B | A | B |
| Example 543 | 1 | Sulfolane | 30 | B | A | B |
| Example 544 | 1 | Sulfolane | 30 | B | A | B |
| Example 545 | 1 | Sulfolane | 30 | B | A | B |
| Example 546 | 1 | Sulfolane | 30 | B | A | B |
| Example 547 | 1 | Sulfolane | 30 | B | A | B |
| Example 548 | 1 | Sulfolane | 30 | B | A | B |
| Example 549 | 1 | Sulfolane | 30 | B | A | B |
| Example 550 | 0.5 | Propylene glycol | 30 | A | A | A |
| Example 551 | 0.5 | Sulfolane | 30 | A | A | A |
| Example 552 | 0.5 | Propylene glycol | 30 | A | A | A |
| Example 553 | 0.5 | Sulfolane | 30 | A | A | A |
| Example 554 | 0.5 | Propylene glycol | 30 | B | A | A |
| Example 555 | 0.5 | Sulfolane | 30 | B | A | A |
| Example 556 | 0.5 | Propylene glycol | 30 | B | A | A |
| Example 557 | 0.5 | Sulfolane | 30 | B | A | A |
| Example 558 | 0.5 | Propylene glycol | 30 | A | A | A |
| Example 559 | 0.5 | Sulfolane | 30 | A | A | A |
| Example 560 | 0.5 | Propylene glycol | 30 | A | A | A |
| Example 561 | 0.5 | Sulfolane | 30 | A | A | A |
| Example 562 | 0.5 | Propylene glycol | 30 | A | A | A |
| Example 563 | 0.5 | Sulfolane | 30 | A | A | A |
| Example 564 | 0.5 | Propylene glycol | 30 | A | A | A |
| Example 565 | 0.5 | Sulfolane | 30 | A | A | A |
| Example 566 | 1 | Propylene glycol | 30 | A | A | A |
| Example 567 | 1 | Sulfolane | 30 | A | A | A |
| Example 568 | 1 | Propylene glycol | 30 | A | A | A |
| Example 569 | 1 | Sulfolane | 30 | A | A | A |
| Example 570 | 0.5 | Propylene glycol | 50 | B | A | A |

TABLE 20

| | Fluoride | | | | |
|---|---|---|---|---|---|
| | ion source | | Oxidant | | |
| | | Amount | | Amount | Additive |
| | Type | (%) | Type | (%) | Type |
| Example 571 | HF | 0.5 | Peracetic acid | 8 | Dodecyl diphenyl ether disulfonic acid |
| Example 572 | HF | 0.5 | Peracetic acid | 8 | Phenolsulfonic acid formaldehyde condensate |
| Example 573 | HF | 0.5 | Peracetic acid | 8 | Phenolsulfonic acid formaldehyde condensate |
| Example 574 | HF, | 0.5 | Peracetic acid | 8 | Dodecyl diphenyl ether disulfonic acid |
| | NH4F | 0.5 | | | |
| Example 575 | HF, | 0.5 | Peracetic acid | 8 | Dodecyl diphenyl ether disulfonic acid |
| | NH4F | 0.5 | | | |
| Example 576 | HF, | 0.5 | Peracetic acid | 8 | Phenolsulfonic acid formaldehyde condensate |
| | NH4F | 0.5 | | | |
| Example 577 | HF, | 0.5 | Peracetic acid | 8 | Phenolsulfonic acid formaldehyde condensate |
| | NH4F | 0.5 | | | |
| Example 578 | HF | 0.5 | Peracetic acid | 8 | Dodecyl diphenyl ether disulfonic acid, |
| | | | | | Phenolsulfonic acid formaldehyde condensate |
| Example 579 | HF | 0.5 | Peracetic acid | 8 | Dodecyl diphenyl ether disulfonic acid, |
| | | | | | Phenolsulfonic acid formaldehyde condensate |
| Example 580 | HF | 0.5 | Peracetic acid | 8 | Dodecyl diphenyl ether disulfonic acid |
| Example 581 | HF | 0.5 | Peracetic acid | 8 | Phenolsulfonic acid formaldehyde condensate |
| Comparative Example 1 | — | — | Peracetic acid | 8 | — |
| Comparative Example 2 | HF | 0.5 | — | — | — |
| Comparative Example 3 | HF | 0.5 | Peracetic acid | 8 | — |
| Comparative Example 4 | HF | 0.5 | Peracetic acid | 8 | Dodecylbenzenesulfonic acid |
| Comparative Example 5 | HF | 0.5 | Peracetic acid | 8 | Polyethyleneimine |
| Comparative Example 6 | HF | 0.5 | Peracetic acid | 8 | Cysteine |

| | Additive | Organic solvent | | | | SiGe |
|---|---|---|---|---|---|---|
| | Amount | | Amount | SiGe | Si | Surface |
| | (%) | Type | (%) | ER | ER | roughness |
| Example 571 | 0.5 | Sulfolane | 50 | B | A | A |
| Example 572 | 0.5 | Propylene glycol | 50 | B | A | A |
| Example 573 | 0.5 | Sulfolane | 50 | B | A | A |
| Example 574 | 0.5 | Propylene glycol | 30 | A | A | A |
| Example 575 | 0.5 | Sulfolane | 30 | A | A | A |
| Example 576 | 0.5 | Propylene glycol | 30 | A | A | A |
| Example 577 | 0.5 | Sulfolane | 30 | A | A | A |
| Example 578 | 0.5 | Propylene glycol | 30 | A | A | A |
| | 0.5 | | | | | |
| Example 579 | 0.5 | Sulfolane | 30 | A | A | A |
| | 0.5 | | | | | |
| Example 580 | 0.5 | Propylene glycol, | 30 | B | A | A |
| | | Sulfolane | 30 | | | |
| Example 581 | 0.5 | Propylene glycol, | 30 | B | A | A |
| | | Sulfolane | 30 | | | |
| Comparative Example 1 | | — | | E | A | E |
| Comparative Example 2 | | — | | E | C | E |
| Comparative Example 3 | | — | | D | C | E |
| Comparative Example 4 | 0.5 | — | | D | C | E |
| Comparative Example 5 | 0.5 | — | | D | C | E |
| Comparative Example 6 | 0.5 | — | | D | C | E |

From the results shown in the tables, it has been confirmed that with the treatment liquid according to the embodiment of the present invention, the objects of the present invention can be achieved.

Furthermore, it has been confirmed that in view of further improving the effect of the present invention, the specific additive is preferably one or more kinds of substances selected from the group consisting of polyvinyl alcohol, polystyrene sulfonic acid and a salt thereof, a nitrogen atom-containing polymer other than polyethyleneimine, cetyltrimethylammonium chloride, stearyltrimethylammonium bromide, polyoxyethylene lauryl amine, alkyl naphthalenesulfonic acid and a salt thereof, alkyl diphenyl ether disulfonic acid and a salt thereof, a phenolsulfonic acid formaldehyde condensate and a salt thereof, an aryl phenolsulfonic acid formaldehyde condensate and a salt thereof, polyoxyethylene alkyl ether sulfonic acid, polyoxyethylene alkyl ether carboxylic acid, polyoxyethylene alkyl phosphoric acid, polyoxyethylene alkyl phenyl ether phosphoric acid, alkylamine, a nitrogen-containing heterocyclic compound, an amino acid other than cysteine, a quaternary ammonium salt having 16 or less carbon atoms, and a boron-containing compound, and more preferably one or more kinds of substances selected from the group consisting of alkyl diphenyl ether disulfonic acid and a phenolsulfonic acid formaldehyde condensate (refer to the comparison of results of Examples 155 and 248 to 398, and the like).

It has been confirmed that in view of further improving the effect of the present invention, the treatment liquid preferably contains an organic solvent (refer to the comparison of the results of Example 24 and the results of Examples 154 to 200, and the like).

Particularly, it has been confirmed that the organic solvent is preferably one or more kinds of compounds selected from the group consisting of ethylene glycol, propylene glycol, butyl diglycol, and sulfolane, and more preferably one or more kinds of compounds selected from the group consisting of propylene glycol and sulfolane (refer to the comparison of results of Examples 154 to 200, and the like).

It has been confirmed that, in view of further improving the effect of the present invention, the content of the oxidant is preferably 5% to 15% by mass with respect to the total mass of the treatment liquid (refer to the comparison between the results of Examples 155 and the results of Example 554, and the like).

It has been confirmed that, in view of further improving the effect of the present invention, the content of the organic solvent is preferably 20% to 45% by mass with respect to the total mass of the treatment liquid (refer to the comparison between the results of Examples 155 and the results of Example 570, and the like).

[Test Y]

The dissolution rate for silicon-germanium and the surface roughness of the treated silicon-germanium film were evaluated in the same manner as in Test X, except that the treatment liquid of Example 202 in Test X was used as a treatment liquid, and the ratio between silicon and germanium (Si:Ge (element ratio)) in silicon-germanium was changed.

The results are shown in the following table.

In the table, the column of “SiGe ratio” shows the ratio between silicon and germanium (Si:Ge (element ratio)) in the silicon-germanium film used for the test.

TABLE 21

| | SiGe | SiGe ER | SiGe |
|---|---|---|---|
| | Wafter ratio | (A/min) | Surface roughness |
| Example B1 | 95:5 | B | B |
| Example B2 | 75:25 | A | A |
| Example B3 | 50:50 | A | B |
| Example B4 | 98:2 | C | B |
| Example B5 | 45:55 | A | D |

From the results shown in the table, it has been confirmed that, in view of further improving the effect of the present invention, the ratio between silicon and germanium (Si:Ge (element ratio)) in SiGe treated with the treatment liquid is preferably 95:5 to 50:50 and more preferably 85:15 to 65:35.

[Test Z]

Two high-density polyethylene (HDPE) bottles having a volume of 20 L were prepared, and each of these bottles was filled with 15 L of the treatment liquid of Example 202 in Test X. The degassing cap shown in FIG. 1 capable of being screwed on and fixed to a bottle was put on one of the two bottles. A cap that does not comprise a degassing mechanism and is capable of being screwed on and fixed to a bottle was put on the other bottle.

The two obtained bottles were left to stand at room temperature (25° C.) for 30 days, and then the appearance of each bottle was observed. As a result, no change was observed in the appearance of the bottle with the degassing cap. On the other hand, the bottle with the cap that does not comprise a degassing mechanism was found to be inflated.

From these results, it has been confirmed that it is preferable to store and/or provide the treatment liquid in the form of a treatment liquid container in which the treatment liquid is stored in a container having a degassing cap.

### EXPLANATION OF REFERENCES

100: treatment liquid container
102: cap body
104: waterproof breathable film
106: breathable layer
108: bottle body
110: treatment liquid
112: flow channel
200: object to be treated
202: substrate
204: SiGe
206: other materials

What is claimed is:

1. A treatment liquid comprising:
a fluoride ion source;
an oxidant; and
an additive,
wherein the additive is one or more kinds of substances selected from the group consisting of polyvinyl alcohol, polystyrene sulfonic acid and a salt thereof, a nitrogen atom-containing polymer other than polyethyleneimine, cetyltrimethylammonium chloride, stearyltrimethylammonium bromide, polyoxyethylene lauryl amine, alkyl naphthalenesulfonic acid and a salt thereof, alkyl diphenyl ether disulfonic acid and a salt thereof, a phenolsulfonic acid formaldehyde condensate and a salt thereof, an aryl phenolsulfonic acid formaldehyde condensate and a salt thereof, polyoxyethylene alkyl ether sulfonic acid and a salt thereof, polyoxyethylene alkyl ether carboxylic acid and a salt thereof; polyoxyethylene alkyl ether phosphoric acid and a salt thereof; polyoxyethylene alkyl phenyl ether phosphoric acid and a salt thereof, lauryl dimethylaminoacetic acid betaine, lauryldimethylamine oxide, a silicon compound, alkylamine, aromatic amine, a nitrogen-containing heterocyclic compound, an amino acid other than cysteine, a quaternary ammonium salt having 16 or less carbon atoms, and a boron-containing compound.

2. The treatment liquid according to claim 1,
wherein the additive contains the nitrogen atom-containing polymer other than polyethyleneimine, and
the nitrogen atom-containing polymer other than polyethyleneimine is one or more kinds of polymers selected from the group consisting of polyvinylpyrrolidone, polyallylamine, polyvinylamine, polyacrylamide, a dimethylamineepihalohydrin-based polymer, a hexadimethrine salt, polydiallylamine, a polydimethyldiallylammonium salt, poly(4-vinylpyridine), polyornithine, polylysine, polyarginine, polyhistidine, polyvinylimidazole, and polymethyldiallylamine.

3. The treatment liquid according to claim 1,
wherein the additive contains at least any of the alkyl naphthalenesulfonic acid and a salt thereof; and
the alkyl naphthalenesulfonic acid is one or more kinds of compounds selected from the group consisting of propyl naphthalenesulfonic acid, triisopropyl naphthalenesulfonic acid, and dibutyl naphthalenesulfonic acid.

4. The treatment liquid according to claim 1,
wherein the additive contains at least any of the alkyl diphenyl ether disulfonic acid and a salt thereof, and
the alkyl diphenyl ether disulfonic acid is dodecyl diphenyl ether disulfonic acid.

5. The treatment liquid according to claim 1,
wherein the additive contains at least any of the polyoxyethylene alkyl ether sulfonic acid and a salt thereof, and
the polyoxyethylene alkyl ether sulfonic acid is one or more kinds of compounds selected from the group consisting of polyoxyethylene lauryl ether sulfonic acid, polyoxyethylene oleyl ether sulfonic acid, and polyoxyethylene octyldodecyl ether sulfonic acid.

6. The treatment liquid according to claim 1,
wherein the additive contains at least any of the polyoxyethylene alkyl ether carboxylic acid and a salt thereof, and
the polyoxyethylene alkyl ether carboxylic acid is one or more kinds of compounds selected from the group consisting of polyoxyethylene lauryl ether carboxylic acid, polyoxyethylene dodecyl ether carboxylic acid, and polyoxyethylene tridecyl ether carboxylic acid.

7. The treatment liquid according to claim 1,
wherein the additive contains at least any of the polyoxyethylene alkyl ether phosphoric acid and a salt thereof, and
the polyoxyethylene alkyl ether phosphoric acid is polyoxyethylene lauryl ether phosphoric acid.

8. The treatment liquid according to claim 1,
wherein the additive contains the silicon compound, and
the silicon compound is one or more kinds of compounds selected from the group consisting of alkoxysilane, a silanol compound, oxime silane, disilazane, and siloxane.

9. The treatment liquid according to claim 8,
wherein the alkoxysilane is one or more kinds of compounds selected from the group consisting of tetraethoxysilane, methyltrimethoxysilane, dimethyldimethoxysilane, phenyltrimethoxysilane, methyltriethoxysilane, dimethyldiethoxysilane, phenyltriethoxysilane, n-propyltrimethoxysilane, n-propyltriethoxysilane, hexyltrimethoxysilane, hexyltriethoxysilane, octyltriethoxysilane, 1,6-bis(trimethoxysilyl)hexane, trifluoropropyltrimethoxysilane, t-butylmethoxydimethylsilane, 3-aminopropyldimethylmethoxysilane, ethoxy(trimethyl)silane, methoxy(trimethyl)silane, hexyl(dimethoxy)silane, methyldiethoxysilane, triethoxysilane, 3-aminopropyldimethylethoxysilane, and 3-(2-aminoethoxyamino)propyltrimethoxysilane.

10. The treatment liquid according to claim 8,
wherein the silanol compound is one or more kinds of compounds selected from the group consisting of trimethylsilanol, dimethylsilanediol, diphenylsilanediol, silanetriol, 3-aminopropylsilanetriol, methylsilanetriol, 2-methyl-2-propylsilanetriol, methyl acetate silanetriol, 2-(chloroethyl)acetate silanetriol, and 3-(hydroxypropyl)silanetriol.

11. The treatment liquid according to claim 8,
wherein the oxime silane is one or more kinds of compounds selected from the group consisting of di(ethylaldoxime)silane, mono(ethylaldoxime)silane, tris(ethylaldoxime)silane, tetra(ethylaldoxime)silane, methyltris(methylethylketoxime)silane, methyltosyl(acetoxime)silane, methyltris(methylisobutylketoxime)silane, dimethyldi(methylethylketoxime)silane, trimethyl(methylethylketoxime)silane, tetra(methylethylketoxime)silane, tetra(methylisobutylketoxime)silane, vinyltris(methylethylketoxime)silane, methylvinyldi(methylethylketoxime)silane, methylvinyldi(cyclohexanonexime)silane, vinyltris(methylisobutylketoxime)silane, and phenyltris(methylethylketoxime)silane.

12. The treatment liquid according to claim 8,
wherein the disilazane is hexamethyldisilazane.

13. The treatment liquid according to claim 8,
wherein the siloxane is one or more kinds of compounds selected from the group consisting of hexamethyldisiloxane, octamethylcyclotetrasiloxane, decamethylcyclopentasiloxane, and dodecamethylcyclohexasiloxane.

14. The treatment liquid according to claim 1,
wherein the additive contains the alkylamine, and
the alkylamine is one or more kinds of compounds selected from the group consisting of ethylenediamine, diethylenetriamine, triethylenetetramine, tetraethylenepentamine, pentaethylenehexamine, tetramethylethylenediamine, hexamethylenediamine, methylamine, dimethylamine, trimethylamine, ethylamine, diethylamine, triethylamine, 2-ethylhexylamine, stearylamine, cyclohexylamine, phenethylamine, and m-xylylenediamine.

15. The treatment liquid according to claim 1,
wherein the additive contains the aromatic amine, and
the aromatic amine is one or more kinds of compounds selected from the group consisting of aniline and toluidine.

16. The treatment liquid according to claim 1,
wherein the additive contains the nitrogen-containing heterocyclic compound, and the nitrogen-containing heterocyclic compound is one or more kinds of compounds selected from the group consisting of pyrrolidine, piperidine, piperazine, morpholine, pyrrole, pyrazole, imidazole, pyridine, pyrimidine, pyrazine, oxazole, thiazole, 4-dimethylaminopyridine, and laurylpyridinium chloride.

17. The treatment liquid according to claim 1,
wherein the additive contains the amino acid other than cysteine, and
the amino acid other than cysteine is one or more kinds of amino acids selected from the group consisting of alanine, arginine, asparagine, aspartic acid, glutamine, glutamic acid, glycine, histidine, isoleucine, leucine, lysine, methionine, phenylalanine, proline, serine, threonine, tryptophan, tyrosine, and valine.

18. The treatment liquid according to claim 1,
wherein the additive contains the quaternary ammonium salt having 16 or less carbon atoms, and
the quaternary ammonium salt having 16 or less carbon atoms is one or more kinds of compounds selected from the group consisting of a tetramethylammonium salt, a tetraethylammonium salt, a tetrapropylammonium salt, a tetrabutylammonium salt, a methyltripropylammonium salt, a methyltributylammonium salt, an ethyltrimethylammonium salt, a dimethyldiethylammonium salt, a benzyltrimethylammonium salt, and a (2-hydroxyethyl)trimethylammonium salt.

19. The treatment liquid according to claim 1,
wherein the additive contains the boron-containing compound, and
the boron-containing compound is boric acid.

20. The treatment liquid according to claim 1,
wherein the additive is one or more kinds of substances selected from the group consisting of alkyl diphenyl ether disulfonic acid and a phenolsulfonic acid formaldehyde condensate.

21. The treatment liquid according to claim 1, further comprising:
an organic solvent.

22. The treatment liquid according to claim 21,
wherein the organic solvent is one or more kinds of compounds selected from the group consisting of ethylene glycol, propylene glycol, butyl diglycol, 1,4-butanediol, tripropylene glycol methyl ether, propylene glycol propyl ether, diethylene glycol n-butyl ether, hexyloxypropylamine, poly(oxyethylene)diamine, dimethyl sulfoxide, tetrahydrofurfuryl alcohol, glycerol, sulfolane, ethylene glycol monomethyl ether, ethylene glycol monoethyl ether, ethylene glycol monobutyl ether, ethylene glycol dimethyl ether, ethylene glycol diethyl ether, diethylene glycol monomethyl ether, diethylene glycol monoethyl ether, diethylene glycol monopropyl ether, diethylene glycol monoisopropyl ether, diethylene glycol monoisobutyl ether, diethylene glycol monobenzyl ether, diethylene glycol dimethyl ether, diethylene glycol diethyl ether, triethylene glycol monomethyl ether, triethylene glycol dimethyl ether, polyethylene glycol monomethyl ether, diethylene glycol methyl ethyl ether, propylene glycol monomethyl ether, propylene glycol dimethyl ether, propylene glycol monobutyl ether, monopropyl ether, dipropylene glycol monomethyl ether, dipropylene glycol monoisopropyl ether, dipropylene glycol monobutyl ether, dipropylene glycol diisopropyl ether, 1-methoxy-2-butanol, 2-methoxy-1-butanol, 2-methoxy-2-methylbutanol, 1,1-dimethoxyethane, 2-(2-butoxyethoxy)ethanol, methanol, ethanol, isopropanol, and 1-butanol.

23. The treatment liquid according to claim 21,
wherein the organic solvent is one or more kinds of compounds selected from the group consisting of propylene glycol and sulfolane.

24. The treatment liquid according to claim 1,
wherein the oxidant is a peroxide.

25. The treatment liquid according to claim 1,
wherein a content of the oxidant is less than 10% by mass with respect to a total mass of the treatment liquid.

26. The treatment liquid according to claim 1,
wherein the treatment liquid is used for an object to be treated containing SiGe to remove at least a part of SiGe contained in the object to be treated.

27. The treatment liquid according to claim 1,
wherein the treatment liquid is used for an object to be treated containing SiGe to remove at least a part of SiGe contained in the object to be treated, and an element ratio of Si:Ge in the SiGe is in a range of 95:5 to 50:50.

28. The treatment liquid according to claim 1,
wherein the treatment liquid is used for an object to be treated containing a metal hard mask containing one or more kinds of substances among Cu, Co, W, AlOₓ, AlN, AlOₓN_{y}, WOₓ, Ti, TiN, ZrOₓ, HfOₓ and TaOₓ, where x represents a number of 1 to 3 and y represents a number of 1 or 2.

29. A treatment liquid container comprising:
a container; and
the treatment liquid according to claim 1 stored in the container,
wherein the container has a degassing mechanism that adjusts internal pressure of the container.
